(19) United States
(12) Patent Application Publication
(10) Pub. No.: US 2026/0075773 A1
(43) Pub. Date: Mar. 12, 2026

(54) LIQUID-COOLED DATA CENTER

(71) Applicant: Canaan Creative Co., Ltd., Beijing (CN)

(72) Inventors: Xiaogang Sun, Beijing (CN); Shishuang He, Beijing (CN); Xiaoye Zhao, Beijing (CN); Guanchao Zhao, Beijing (CN); Zonghai Chen, Beijing (CN); Nan Li, Beijing (CN); He Ying, Beijing (CN); Nangeng Zhang, Beijing (CN)

(21) Appl. No.: 19/391,880

(22) Filed: Nov. 17, 2025

Related U.S. Application Data
(63) Continuation-in-part of application No. PCT/CN2024/080613, filed on Mar. 7, 2024.

(30) Foreign Application Priority Data
May 17, 2023 (CN) 202321202078.2
May 19, 2023 (CN) 202321238877.5

(51) Int. Cl. H05K 7/20

(52) U.S. Cl. CPC H05K 7/2079

(57) ABSTRACT

A liquid-cooled data center is disclosed, comprising: a liquid-cooled device; and a cold source device, which is connected to the liquid-cooled device and is used for cooling the liquid-cooled device. By means of the technique of the present application, cooling requirements of a plurality of computing devices at a data center are met, so as to facilitate an improvement in the circulation efficiency of a cooling working medium circularly flowing between a liquid-cooled device and a cold source device, thereby improving the cooling efficiency.

### CROSS-REFERENCE TO RELATED APPLICATIONS

The present application is a bypass continuation-in-part application of International Patent Application PCT/CN2024/080613, filed on Mar. 7, 2024 with the China Patent Office, which claims priority under 35 U.S.C. § 119 to: Chinese Patent Application No. 202321202078.2 filed with the China Patent Office on May 17, 2023, and titled “LIQUID-COOLED DATA CENTER”, and also to Chinese Patent Application No. 202321238877.5 filed with the China Patent Office on May 19, 2023, and titled “LIQUID-COOLED DATA CENTER,” the contents of each of which are incorporated herein by reference in their entirety.

### TECHNICAL FIELD

The present application relates to the technical field of data centers, and in particular to a liquid-cooled data center, a device framework, a data center, and a container data center. The present application further relates to an enclosure structure, a cold source container, and a pipeline structure.

The present application further relates to the technical field of computing devices, and in particular to a cooling apparatus, a heat exchange device, a container heat exchange device, and a computing device.

### BACKGROUND

With the increase in computing workloads and the improvement of manufacturing processes for electronic components such as chips in recent years, the power density of electronic devices has been continuously rising, and traditional air-cooling methods have become increasingly unable to meet the heat dissipation requirements of the electronic devices. As a heat dissipation method, immersion liquid cooling has advantages such as high heat transfer efficiency, minimal impact of dust on electronic devices, high utilization value of waste heat, and high site utilization, which can significantly improve the heat dissipation efficiency and effect of computing devices.

### SUMMARY

Embodiments of the present application provide a liquid-cooled data center.

As one aspect of the embodiments of the present application, an embodiment of the present application provides a liquid-cooled data center, including: a liquid-cooled device; and a cold source device connected to the liquid-cooled device for cooling the liquid-cooled device.

In an implementation, the liquid-cooled data center further includes a connecting pipeline that connects the liquid-cooled device and the cold source device.

In an implementation, the liquid-cooled data center further includes an enclosure for deploying the liquid-cooled device and/or the cold source device.

In an implementation, the liquid-cooled data center further includes a computing device deployed in the liquid-cooled device.

In an implementation, the liquid-cooled data center further includes an enclosure for deploying the liquid-cooled device and/or the cold source device; and a connecting pipeline that connects the liquid-cooled device and the cold source device deployed within the enclosure.

In an implementation, the liquid-cooled data center further includes a connecting pipeline connected between the liquid-cooled device and the cold source device to form a cooling circulation pipeline.

In an implementation, the liquid-cooled data center further includes an enclosure for deploying the liquid-cooled device and/or the cold source device, so as to integrate the liquid-cooled device and/or the cold source device into the enclosure. In an implementation, the liquid-cooled device includes at least one cooling apparatus for cooling a server module as loaded, and the cold source device is used for exchanging heat with a cooling working medium in the at least one cooling apparatus.

In an implementation, the cold source device includes a first cold source device and a second cold source device, wherein the first cold source device and/or the second cold source device are connected to the at least one cooling apparatus.

In an implementation, the liquid-cooled device includes a first cooling apparatus and a second cooling apparatus, wherein the first cold source device is connected to the first cooling apparatus, and the second cold source device is connected to the second cooling apparatus; or, the first cold source device and the second cold source device are connected to the first cooling apparatus, and the first cold source device or the second cold source device is connected to the second cooling apparatus.

In an implementation, the liquid-cooled device includes a plurality of cooling apparatuses, and the cold source device includes a plurality of cold source devices; wherein at least one of the plurality of cooling apparatuses is connected to at least two of the plurality of cold source devices.

In an implementation, a first circulation flow path for circulation flow of the cooling working medium is provided between the first cold source device and the first cooling apparatus, a second circulation flow path for circulation flow of the cooling working medium is provided between the second cold source device and the second cooling apparatus, and a third circulation flow path for circulation flow of the cooling working medium is provided among the first cold source device, the second cold source device and a third cooling apparatus.

In an implementation, the cold source device includes a heat exchange assembly; and the first cold source device and the second cold source device both include a first heat exchange assembly and a second heat exchange assembly, wherein the first heat exchange assembly of the first cold source device is used for cooling the cooling working medium in the first cooling apparatus, the first heat exchange assembly of the second cold source device is used for cooling the cooling working medium in the second cooling apparatus, and the second heat exchange assemblies of the first cold source device and the second cold source device are used for jointly cooling the cooling working medium in the third cooling apparatus.

In an implementation, the first cold source device further includes a first heat exchanger for performing heat exchange between a liquid medium output from the first heat exchange assembly of the first cold source device and the cooling working medium in the first circulation flow path; the second cold source device further includes a second heat exchanger for performing heat exchange between a liquid medium output from the first heat exchange assembly of the second cold source device and the cooling working medium in the second circulation flow path; and the second heat exchange assemblies of the first cold source device and the second cold source device are respectively in communication with the third circulation flow path.

In an implementation, the first heat exchange assembly and second heat exchange assembly of the first cold source device cool the cooling working medium through a liquid medium, and the first heat exchange assembly and second heat exchange assembly of the second cold source device cool the cooling working medium through a gaseous medium.

In an implementation, the heat exchange assembly of the cold source device includes: a pipeline module including an input pipeline for inputting a cooling working medium to be cooled, an output pipeline for outputting the cooled cooling working medium, and a connecting pipeline connected between the input pipeline and the output pipeline; a first heat exchange module, an input end and an output end of the first heat exchange module being respectively in communication with the connecting pipeline for cooling the cooling working medium through a gaseous medium; and a second heat exchange module, an input end and an output end of the second heat exchange module being respectively in communication with the connecting pipeline for cooling the cooling working medium through a liquid medium; wherein the connecting pipeline is provided with a valve assembly for causing the cooling working medium to flow through at least one of the first heat exchange module and the second heat exchange module.

In an implementation, the connecting pipeline includes an intermediate pipeline, a first liquid inlet pipeline, a first liquid outlet pipeline, a second liquid inlet pipeline, and a second liquid outlet pipeline; wherein an input end and an output end of the intermediate pipeline are respectively connected to the input pipelines and the output pipelines, the first liquid inlet pipeline is connected between the input end of the first heat exchange module and the intermediate pipeline, the first liquid outlet pipeline is connected between the output end of the first heat exchange module and the intermediate pipeline, the second liquid inlet pipeline is connected between the input end of the second heat exchange module and the intermediate pipeline, and the second liquid outlet pipeline is connected between the output end of the second heat exchange module and the intermediate pipeline.

In an implementation, the valve assembly includes: a first valve assembly including a first liquid inlet valve provided in the first liquid inlet pipeline, a first liquid outlet valve provided in the first liquid outlet pipeline, and a first on-off valve provided in the intermediate pipeline; and a second valve assembly including a second liquid inlet valve provided in the second liquid inlet pipeline, a second liquid outlet valve provided in the second liquid outlet pipeline, and a second on-off valve provided in the intermediate pipeline.

In an implementation, the first heat exchange module includes a heat exchange coil for flow of the cooling working medium, so that heat exchange takes place between the cooling working medium and the gaseous medium.

In an implementation, the second heat exchange module includes a condenser, an expansion valve, a liquid storage tank, a heat exchange unit, a compressor, and a circulation pipeline, the circulation pipeline is used for circulation flow of the liquid medium among the condenser, the expansion valve, the liquid storage tank, the heat exchange unit, and the compressor, and heat exchange between the liquid medium and the cooling working medium is taken place at the heat exchange unit.

In an implementation, the liquid-cooled data center further includes a gaseous medium cooling module for cooling the gaseous medium and guiding the cooled gaseous medium to the first heat exchange module.

In an implementation, the gaseous medium cooling module includes a wet curtain having flow guide holes that make inside and outside of the cold source device in communication, a wet curtain spray pipe for spraying cooling water to the wet curtain, and a wet curtain water tray provided below the wet curtain to receive the cooling water.

In an implementation, the liquid-cooled data center further includes a control apparatus for controlling open and closed states of the valve assembly according to an outdoor ambient temperature to allow the cooling working medium to flow through at least one of the first heat exchange module and the second heat exchange module, and controlling a working state of the gaseous medium cooling module.

In an implementation, the control apparatus is configured to: control the valve assembly to allow the cooling working medium to flow through the first heat exchange module if the outdoor ambient temperature meets a first preset temperature range; control the valve assembly to allow the cooling working medium to flow through the first heat exchange module and control the gaseous medium cooling module to start if the outdoor ambient temperature meets a second preset temperature range; and control the valve assembly to allow the cooling working medium to flow sequentially through the first heat exchange module and the second heat exchange module and control the gaseous medium cooling module to start if the outdoor ambient temperature meets a third preset temperature range.

In an implementation, the cooling apparatus includes: a housing defining a cooling chamber inside; a flow guide pipe provided in the cooling chamber, a pipe wall of the flow guide pipe provided with a plurality of liquid outlet holes for inputting the cooling working medium to the cooling chamber; and a flow guide plate provided in the cooling chamber and located above the flow guide pipe, the flow guide plate provided with a plurality of flow guide through-holes making upper and lower sides of the flow guide plate in communication; wherein the cooling chamber accommodates a plurality of server modules located above the flow guide plate, the flow guide plate has a plurality of flow guide regions corresponding to the plurality of server modules, and a flow-through area and/or arrangement density of the flow guide through-holes in a flow guide region is positively correlated with the computing capacity of a corresponding server module.

In an implementation, the flow guide plate includes a plurality of flow guide sub-plates that define the flow guide regions.

In an implementation, the plurality of server modules are arranged in a first direction perpendicular to a vertical direction, and the plurality of flow guide regions are arranged in the first direction, with the plurality of flow guide regions in a one-to-one correspondence with the plurality of server modules.

In an implementation, the flow guide pipe has a plurality of flow guide segments corresponding to the plurality of flow guide regions, with a flow-through area and/or arrangement density of the liquid outlet holes included in a flow guide segment positively correlated with the computing capacity of a corresponding server module.

In an implementation, the plurality of flow guide regions are arranged in a first direction perpendicular to a vertical direction, and the plurality of flow guide segments are arranged in the first direction, with the plurality of flow guide segments in a one-to-one correspondence with the plurality of flow guide regions.

In an implementation, the liquid-cooled data center further includes a plurality of baffles provided in the cooling chamber and located below the flow guide plate, the plurality of baffles being disposed corresponding to the plurality of flow guide segments of the flow guide pipe, and the baffles being located in a liquid outlet direction of the liquid outlet holes included in the corresponding flow guide segments.

In an implementation, an included angle between a plane where the baffles are located and a flow guide direction of the flow guide pipe is from 30° to 60°.

In an implementation, the baffle is provided with a flow guide via-hole for making two sub-liquid inlet chambers adjacent to the baffle in communication.

In an implementation, the liquid-cooled data center further includes a partition plate provided in the inside of the housing along the vertical direction to partition the inside of the housing into a cooling chamber and a liquid outlet chamber, which are in communication at upper portions thereof.

In an implementation, the partition plate includes a first plate body fixedly connected to the housing, and a second plate body slidable in the vertical direction relative to the first plate body, an upper side edge of the second plate body being located above an upper side edge of the first plate body.

In an implementation, a cross-sectional shape of the flow guide pipe is circular, square, or triangular; and/or, a shape of the liquid outlet hole is circular, square, or triangular.

In an implementation, the plurality of server modules are arranged adjacently in a first direction perpendicular to a vertical direction, each including at least two columns of servers arranged adjacently in a second direction perpendicular to the first direction, each column of servers including at least one server arranged along the first direction; and the flow guide pipe is disposed axially parallel to the first direction.

In an implementation, each server module includes N columns of servers arranged in a second direction, where N is a positive integer greater than or equal to 2; the number of flow guide pipes is N−1; wherein any two adjacent columns of servers correspond to one flow guide pipe.

In an implementation, in the second direction, the flow guide pipe is centered relative to two columns of servers corresponding thereto.

In an implementation, the liquid-cooled data center further includes an enclosure, with at least one liquid-cooled device integrally deployed inside the enclosure; or, at least one liquid-cooled device and at least one cold source device integrally deployed inside the enclosure.

In an implementation, the enclosure includes a first container body and a second container body, with at least one liquid-cooled device integrally deployed inside the first container body and at least one cold source device integrally deployed inside the second container body.

In an implementation, the first container body and the second container body are detachably connected.

In an implementation, the first container body and the second container body are detachably connected in the horizontal direction.

In an implementation, an interlocking structure is provided between adjoining top walls and/or side walls of the first container body and the second container body.

In an implementation, the first container body and the second container body are detachably connected in the vertical direction.

In an implementation, an upper side of the first container body is provided with a first mounting fit member, and a lower side of the second container body is provided with a second mounting fit member, the first mounting fit member and the second mounting fit member being connected by interlocking.

In an implementation, the first mounting fit member and the second mounting fit member are fixedly connected by fasteners.

In an implementation, a ladder is provided between bottom and top ends of the second container body.

In an implementation, the first container body defines an enclosed cavity, and the second container body employs a framework structure to define an open cavity.

In an implementation, the first container body is provided with a pipeline window for allowing a cooling pipeline to pass through to connect the cold source device in the second container body with the liquid-cooled device in the first container body.

In an implementation, the liquid-cooled data center further includes a power distribution module for providing electrical power to the liquid-cooled device and/or the cold source device, and a power module for providing power to the cooling working medium in the circulation flow path between the liquid-cooled device and the cold source device, wherein the power distribution module and the power module are integrally deployed inside the first container body.

In an implementation, the power distribution module and the power module are respectively disposed close to two opposite sides within the first container body.

In an implementation, the liquid-cooled data center further includes a computing device including a server module, the liquid-cooled device being integrated with the server module.

The above summary is only for the purpose of illustration, and is not intended to make limitations in any way. In addition to the schematic aspects, implementations, and features described above, further aspects, implementations, and features of the present application will be easily understood by referring to the drawings and the following detailed description.

### BRIEF DESCRIPTION OF THE DRAWINGS

In the drawings, unless otherwise specified, the same reference numerals throughout the plurality of drawings represent the same or similar components or elements. These drawings are not necessarily drawn to scale. It should be understood that these drawings only depict some implementations disclosed in the present application and should not be regarded as limitations on the scope of the present application.

FIG. 1 shows a schematic diagram of a cooling system according to a first aspect of the present application;

FIG. 2 shows a schematic structural diagram of the cooling system according to the first aspect of the present application;

FIG. 3 shows a cross-sectional view of the cooling system according to the first aspect of the present application;

FIG. 4 shows a schematic diagram of the working principle of a cold source device of the cooling system according to the first aspect of the present application;

FIG. 5 shows a schematic structural diagram of the cold source device of the cooling system according to the first aspect of the present application;

FIG. 6 shows a schematic structural diagram of a cooling apparatus of the cooling system according to the first aspect of the present application;

FIG. 7 shows a schematic diagram of a flow guide pipe of the cooling apparatus of the cooling system according to the first aspect of the present application mounted in the housing;

FIG. 8 shows a schematic structural diagram of a flow guide plate of the cooling apparatus of the cooling system according to the first aspect of the present application;

FIG. 9 shows a perspective view of the cooling apparatus of the cooling system according to the first aspect of the present application;

FIG. 10 shows a top view of the cooling apparatus of the cooling system according to the first aspect of the present application;

FIG. 11 shows a schematic structural diagram of a cooling apparatus according to a second aspect of the present application;

FIG. 12 shows a schematic diagram of a liquid supply pipe of the cooling apparatus according to the second aspect of the present application as mounted in the housing;

FIG. 13 shows a schematic structural diagram of a flow guide plate of the cooling apparatus according to the second aspect of the present application;

FIG. 14 shows a perspective view of the cooling apparatus according to the second aspect of the present application;

FIG. 15 shows a top view of the cooling apparatus according to the second aspect of the present application;

FIG. 16 shows a side view of the cooling apparatus according to the second aspect of the present application;

FIG. 17 shows a schematic view of the partial structure from FIG. 16;

FIG. 18 shows a schematic diagram of a baffle of the cooling apparatus according to the second aspect of the present application as mounted;

FIG. 19 shows a schematic view of the partial structure from FIG. 18;

FIG. 20 shows a schematic diagram of a container data center according to an embodiment of the second aspect of the present application;

FIG. 21 shows a schematic diagram of a container data center according to another embodiment of the second aspect of the present application;

FIG. 22 shows a schematic diagram of the working principle of a heat exchange device according to a third aspect of the present application;

FIG. 23 shows a schematic structural diagram of the heat exchange device according to the third aspect of the present application;

FIG. 24 shows a schematic structural diagram of a container heat exchange device according to the third aspect of the present application;

FIG. 25 shows a schematic structural diagram of a data center according to the third aspect of the present application;

FIG. 26 shows a schematic structural diagram of a device framework according to a fourth aspect of the present application;

FIG. 27 shows a front view of the device framework according to the fourth aspect of the present application;

FIG. 28 shows a side view of the device framework according to the fourth aspect of the present application;

FIG. 29 shows a schematic structural diagram of an embodiment of the data center according to the fourth aspect of the present application;

FIG. 30 shows a schematic structural diagram of another embodiment of the data center according to the fourth aspect of the present application;

FIG. 31 shows a schematic diagram of an internal structure of a data center according to a fifth aspect of the present application;

FIG. 32 shows a schematic diagram of another internal structure of the data center according to the fifth aspect of the present application;

FIG. 33 shows a schematic diagram of a three-dimensional structure of the data center according to the fifth aspect of the present application;

FIG. 34 shows a schematic diagram of still another internal structure of the data center according to the fifth aspect of the present application;

FIG. 35 shows a schematic structural diagram of inside of a computing device enclosure of the data center according to the fifth aspect of the present application;

FIG. 36 shows a schematic diagram of an evaporation module of the data center according to the fifth aspect of the present application as mounted within the computing device enclosure;

FIG. 37 shows a schematic diagram of evaporation modules of the data center according to the fifth aspect of the present application as mounted within the computing device enclosure;

FIG. 38 shows a schematic structural diagram of the computing device enclosure of the data center according to the fifth aspect of the present application;

FIG. 39 shows another schematic structural diagram of the computing device enclosure of the data center according to the fifth aspect of the present application;

FIG. 40 shows a schematic diagram of a data center structure according to a sixth aspect of the present application;

FIG. 41 shows a schematic diagram of a computing device enclosure according to the sixth aspect of the present application;

FIG. 42 shows a top sectional view of the computing device enclosure according to the sixth aspect of the present application;

FIG. 43 shows a side sectional view of the computing device enclosure according to the sixth aspect of the present application;

FIG. 44 shows a cross-sectional view of the computing device enclosure according to the sixth aspect of the present application;

FIG. 45 shows a schematic diagram of a second bracket of the computing device enclosure according to the sixth aspect of the present application;

FIG. 46 shows a schematic diagram of a bottom support frame of the computing device enclosure according to the sixth aspect of the present application;

FIG. 47 shows a schematic diagram of a cold source enclosure according to the sixth aspect of the present application;

FIG. 48 shows a partial schematic structural diagram of a structural reinforcement of the cold source enclosure according to the sixth aspect of the present application;

FIG. 49 shows a partial schematic structural diagram of a bottom structural reinforcing longitudinal beam and a support plate of the cold source enclosure according to the sixth aspect of the present application;

FIG. 50 shows a schematic diagram of a pipeline structure according to a seventh aspect of the present application;

FIG. 51 shows a schematic diagram of a first device row according to the seventh aspect of the present application; and

FIG. 52 shows a schematic diagram of a second device row according to the seventh aspect of the present application.

### DETAILED DESCRIPTION

Only some exemplary embodiments are briefly described below. Just as those skilled in the art may appreciate, the described embodiments may be modified in various ways without departing from the spirit or scope of the present application. Therefore, the drawings and description are considered to be essentially exemplary, not limitative.

In related technologies, data centers employing immersion liquid cooling as the heat dissipation method typically include computer devices, cooling devices, and cold source devices. However, due to lack of systematic and specialized design or overall structural design, they are mostly temporary solutions. That is, the devices are set up independently of each other, resulting in poor overall integration of the data centers, making it impossible to achieve modularized delivery as a whole, and causing the defects of low energy utilization efficiency and space utilization efficiency.

According to the technical solution of the present application, by providing the first cold source device and the second cold source device to cool the cooling working medium in the plurality of cooling apparatuses, the first cold source device can cool the cooling working medium in the first cooling apparatus and the third cooling apparatus, and the second cold source device can cool the cooling working medium in the second cooling apparatus and the third cooling apparatus. Thus, on the one hand, the cooling needs of a plurality of computing devices in the data center are met, which is conducive to improving the circulation efficiency of the circulation flow of the cooling working medium among the plurality of computing devices. On the other hand, the number of the third cooling apparatus may be correspondingly configured according to the cooling redundancy of the first and second cold source devices, thereby achieving modular expansion of the third cooling apparatus and then achieving modular configuration of the computing devices in the data center, which is conducive to iterative updates of the computing devices. Furthermore, this helps to improve the integration of the data center, as well as energy and space utilization rates.

Second, by providing the first and second heat exchange modules having different heat exchange forms, and by controlling the open and closed states of the valve assembly on the connecting pipeline, at least three different heat exchange modes of the cold source device can be achieved, so that the heat exchange modes can be switched according to actual heat exchange needs (e.g., according to different outdoor ambient temperatures or different running conditions of the computing device), achieving different degrees of cooling of the cooling working medium. This can not only improve the stability of cooling the computing device, but also help to achieve energy conservation and emission reduction, and enhance environmental benefits.

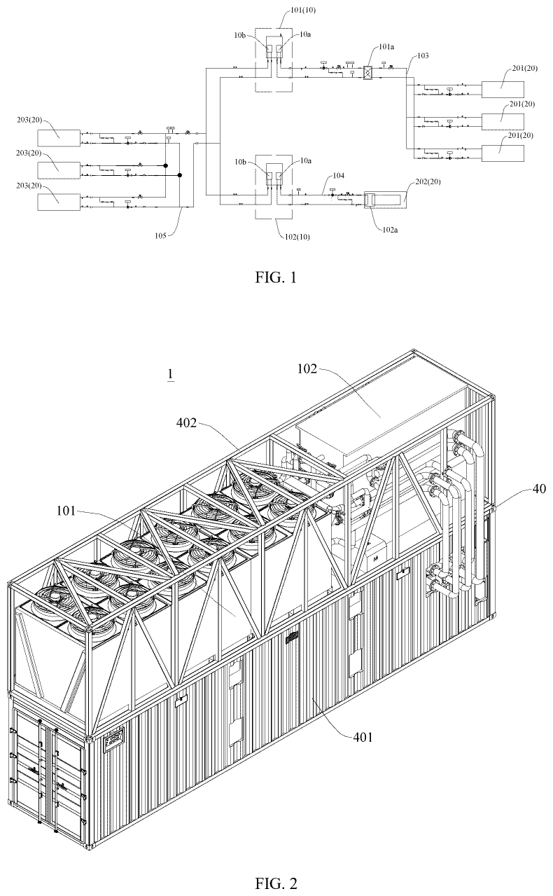

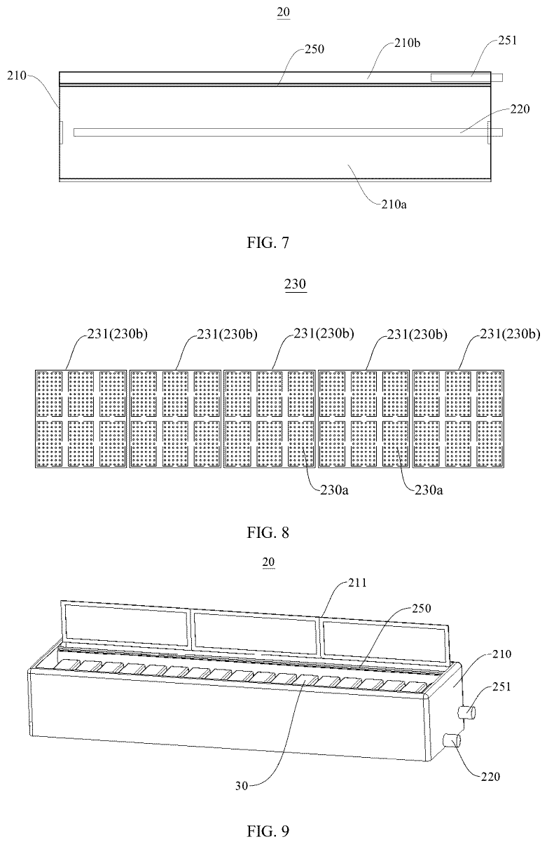

As a first aspect of the embodiments of the present application, a liquid-cooled data center 1 according to an embodiment of the present application will be described below with reference to FIGS. 1 to 10.

As shown in FIG. 1, the liquid-cooled data center 1 according to the embodiment of the present application includes a liquid-cooled device; and a cold source device 10 connected to the liquid-cooled device for cooling the liquid-cooled device.

In the embodiment of the present application, the cold source device 10 can achieve heat exchange with the liquid-cooled device, so that the liquid-cooled device cools a server module of a computing device in the liquid-cooled data center through a cold source.

In the embodiment of the present application, the liquid-cooled data center 1 further includes a connecting pipeline that connects the liquid-cooled device and the cold source device, through which circulation and cooling of a cooling working medium between the liquid-cooled device and the cold source device is achieved. For example, the cooling working medium in the liquid-cooled device absorbs heat and becomes a high-temperature cooling working medium, which flows into the cold source device through the connecting pipeline. The cold source device cools the high-temperature cooling working medium to obtain a low-temperature cooling working medium, which further flows back to the liquid-cooled device through the connecting pipeline.

In an embodiment of the present application, the liquid-cooled data center 1 further includes an enclosure for deploying the liquid-cooled device and/or the cold source device. Through the enclosure, the integrated deployment of the liquid-cooled device and/or the cold source device is achieved. For example, the enclosure may be of standard container dimensions, which, once integrated, can facilitate overall transportation of the data center.

In the embodiment of the present application, the liquid-cooled data center 1 further includes a computing device deployed in the liquid-cooled device. By integrating the computing device in the liquid-cooled device, integrated delivery of the liquid-cooled data center is achieved, eliminating the need for on-site assembly and resulting in higher commissioning efficiency.

In the embodiment of the present application, the cold source device 10 may be any one of a dry cooler, a cooling tower, a compressor system, and a fan system, which is not specifically limited here in the embodiment of the present application.

By providing the cold source device 10 and the liquid-cooled device, the liquid-cooled data center 1 according to the embodiment of the present application can provide cooling for the server module of the liquid-cooled data center, thereby ensuring the working stability and reliability of the liquid-cooled data center.

In an implementation, the liquid-cooled device includes at least one cooling apparatus 20 for cooling a server module 30 as loaded, and the cold source device 10 is used for exchanging heat with a cooling working medium in the at least one cooling apparatus.

In the embodiment of the present application, the liquid-cooled data center 1 further includes a plurality of computing devices including a plurality of server modules 30, the liquid-cooled device being integrated with the server modules 30.

In the embodiment of the present application, the liquid-cooled device includes a cooling apparatus 20 for cooling the server module 30 of the computing device, and the cooling apparatus 20 may be an immersion liquid cooling method, that is, by immersing the server module 30 in the cooling working medium to directly exchange heat with the cooling working medium, the purpose of heat dissipation and cooling of the server module 30 is achieved. The cold source device 10 is connected with the cooling apparatus 20 through a circulation flow path, so that the cooling working medium flows in a circulating manner between the cooling apparatus 20 and the cold source device 10. The cold source device 10 is used for cooling the high-temperature cooling working medium output from the cooling apparatus 20 and to transport the cooled low-temperature cooling working medium back to the cooling apparatus 20.

To ensure that the server module 30 immersed in the cooling working medium can work properly, the cooling working medium must be insulating and have certain anti-corrosion properties to avoid damage to the encapsulation of the server module 30, and the cooling working medium also needs to meet the conditions of being non-flammable, non-toxic, and easy to clean. Exemplarily, the cooling working medium may be electronic fluorinated fluid, silicone oil, mineral oil, trichlorobiphenyl synthetic oil, and the like.

In other examples of the present application, the cooling working medium may also be cooling oil.

In one example, the cooling working medium may specifically be a GTL (Gas to Liquid) base oil. The GTL base oil is a base oil synthesized by taking hydrocarbons as raw materials, which has a high saturated hydrocarbon content, is basically free of nitrogen, sulfur, and aromatics, and consists of 100% isoalkanes, exhibiting excellent oxidation stability and low-temperature performance, low volatility, and an extremely high viscosity index. Thus, by employing the GTL base oil as the cooling working medium, the stability of the cooling working medium at low temperatures can be improved, thereby enhancing the working reliability of the cooling apparatus.

In another example, the cooling working medium may also be transformer oil. The transformer oil is a fractionation product of petroleum, and its main components are alkanes, cycloalkanes, aromatic unsaturated hydrocarbons, and other compounds. Commonly referred to as “Fangpeng oil”, it is a light-yellow transparent liquid with a relative density of 0.895 and a freezing point below −45° C. The transformer oil is a mineral oil obtained from natural petroleum through distillation and refining, which is a mixture of pure, stable, low-viscosity, good-insulating, and good-cooling liquid natural hydrocarbons obtained by acid and alkali refining of lubricating oil fractions from petroleum. By employing the transformer oil as the cooling working medium, the stability of the cooling working medium at low temperatures can also be improved, and it also has good insulation properties, which can improve the reliability of the computing devices during operation.

The above are merely examples, and the present application does not limit the specific material of the cooling working medium.

In addition, in some embodiments, the server module 30 is waterproof, in which case the cooling working medium may also be water. For example, a housing of the server module 30 is waterproof, and the electronic components conduct heat to the housing, while the water carries the heat away from the housing.

Depending on whether there is a phase change in a cooling working medium, immersion liquid cooling may be further divided into two types, namely single-phase immersion liquid cooling and phase change immersion liquid cooling. In the single-phase immersion liquid cooling method, the server module 30 is directly immersed in a cooling working medium, heat generated by the server module 30 is conducted to the cooling working medium, then the high-temperature cooling working medium after absorbing the heat is transported to a heat exchanger by a circulation pump, and the high-temperature cooling working medium is cooled in the heat exchanger and then flows back to the housing. In this process, the cooling working medium remains in a liquid state all the time. In the phase change immersion liquid cooling, the server module 30 is directly immersed in a dielectric cooling working medium in the housing, heat generated by the server module 30 is conducted to the cooling working medium, causing part of the cooling working medium to change from liquid to gas, and the gaseous cooling working medium condenses on the condenser in the housing and then changes back to liquid. In this process, the heat transfer efficiency of the cooling working medium can be increased exponentially through the phase change in the cooling working medium. The liquid-cooled data center 1 in the embodiment may specifically employ the single-phase immersion liquid cooling method or the phase change immersion liquid cooling method, which is not specifically limited in the embodiments of the present application.

In the embodiment of the present application, a cooling pipeline is provided between the cold source device 10 and the cooling apparatus 20 for circulation flow of the cooling working medium. The cooling apparatus 20 transports the cooling working medium to be cooled to the cold source device 10 through the cooling pipeline, and the cold source device 10 may cool the cooling working medium with a gaseous medium or a liquid medium and transport the cooled cooling working medium to the cooling apparatus 20 through the cooling pipeline, so as to implement circulation.

In an implementation, the cold source device 10 includes a first cold source device and a second cold source device, wherein the first cold source device and/or the second cold source device are connected to at least one cooling apparatus.

Exemplarily, the first cold source device and the second cold source device may be devices of different forms. For example, one of the first and second cold source devices may be a cooling tower, and the other may be a dry cooler.

In one example, a plurality of cooling apparatuses 20 are provided, which are divided into a first set and a second set. The first cold source device is correspondingly connected with the first set of cooling apparatuses, and the second cold source device is correspondingly connected with the second set of cooling apparatuses. That is, the first and second cold source devices are used for providing cold sources to different sets of cooling apparatuses 20 respectively.

In another example, a plurality of cooling apparatuses 20 are provided, which are divided into a first set, a second set, and a third set. The first cold source device is connected with the first set of cooling apparatuses to provide a cold source to the first set of cooling apparatuses. The second cold source device is connected with the second set of cooling apparatuses to provide a cold source to the second set of cooling apparatuses. The first and second cold source devices are respectively connected with the third set of cooling apparatuses to jointly provide cold sources to the third set of cooling apparatuses.

In still another example, the first and second cold source devices are connected with all the cooling apparatuses 20, respectively. That is, the first and second cold source devices jointly provide cold sources to all the cooling apparatuses 20.

In an implementation, the liquid-cooled device includes a first cooling apparatus and a second cooling apparatus, wherein the first cold source device is connected to the first cooling apparatus, and the second cold source device is connected to the second cooling apparatus; or, the first cold source device and the second cold source device are connected to the first cooling apparatus, and the first cold source device or the second cold source device is connected to the second cooling apparatus.

In the embodiment of the present application, the first and second cooling apparatuses may be cooling apparatuses of different sizes or specifications. More specifically, objects to be cooled of the first and second cooling apparatuses may be different numbers of server modules, that is, the first and second cooling apparatuses have different cooling capabilities.

In one example, the first cold source device is connected to the first cooling apparatus to provide a cold source to the cooling working medium in the first cooling apparatus. The second cold source device is connected to the second cooling apparatus to provide a cold source to the cooling working medium in the second cooling apparatus.

In another example, the first and second cold source devices are jointly connected with the first cooling apparatus to jointly provide a cold source to the cooling working medium in the first cooling apparatus. The first or second cold source device is connected with the second cooling apparatus to provide a cold source to the cooling working medium in the second cooling apparatus.

In an implementation, the liquid-cooled device includes a plurality of cooling apparatuses, and the cold source device includes a plurality of cold source devices; wherein at least one of the plurality of cooling apparatuses is connected to at least two of the plurality of cold source devices.

In the embodiment of the present application, a plurality of cooling apparatuses 20 may be provided, which are disposed corresponding to a plurality of computing devices in the data center one by one, each computing device including a plurality of server modules. The plurality of cooling apparatuses 20 may be of the same structure or different structures. By way of example, the plurality of cooling apparatuses 20 may include a first cooling apparatus 201, a second cooling apparatus 202 and a third cooling apparatus 203. The first cooling apparatus 201 and the second cooling apparatus 202 may be the same, and the first cooling apparatus 201 and the third cooling apparatus 203, as well as the second cooling apparatus 202 and the third cooling apparatus 203, may be not the same. The number of server modules and/or computational capacity contained in the computing devices corresponding to different cooling apparatuses 20 may vary.

Optionally, the plurality of cold source devices 10 include a first cold source device 101 and a second cold source device 102, and the plurality of cooling apparatuses include a first cooling apparatus 201, a second cooling apparatus 202, and a third cooling apparatus 203. A first circulation flow path 103 for circulation flow of the cooling working medium is provided between the first cold source device 101 and the first cooling apparatus 201, a second circulation flow path 104 for circulation flow of the cooling working medium is provided between the second cold source device 102 and the second cooling apparatus 202, and a third circulation flow path 105 for circulation flow of the cooling working medium is provided among the first cold source device 101, the second cold source device 102 and the third cooling apparatus 203.

Exemplarily, the structure and heat exchange method of the first cold source device 101 and the second cold source device 102 may be the same or different. In one example, the first cold source device 101 may employ a liquid medium to cool the cooling working medium; for example, the first cold source device 101 may specifically be a condenser. The second cold source device 102 may employ a gaseous medium to cool the cooling working medium; for example, the second cold source device 102 may specifically be a dry cooler. In another example, both the first cold source device 101 and the second cold source device 102 may employ both liquid and gaseous media to jointly cool the cooling working medium; for example, both the first cold source device 101 and the second cold source device 102 may be integrated with a compressor system that employs a liquid medium to cool the cooling working medium and a dry cooler that employs a gaseous medium to cool the cooling working medium.

In addition, it should be noted that the number of the first cooling apparatus 201, the second cooling apparatus 202 and the third cooling apparatus 203 may each be one or more.

In a specific example, as shown in FIG. 1, the number of first cooling apparatuses 201 may be three, the number of second cooling apparatuses 202 may be one, and the number of third cooling apparatuses 203 may be three. The first cold source device 101 is in communication with the three first cooling apparatuses 201 through the first circulation flow path 103, and the first cold source device 101 is in communication with the three third cooling apparatuses 203 through the third circulation flow path 105, so that the first cold source device 101 can simultaneously cool the cooling working medium in the three first cooling apparatuses 201 and the cooling working medium in the three third cooling apparatuses 203. The second cold source device 102 is in communication with the one second cooling apparatus 202 through the second circulation flow path 104, and the second cold source device 102 is in communication with the three third cooling apparatuses 203 through the third circulation flow path 105, so that the second cold source device 102 can simultaneously cool the cooling working medium in the one second cooling apparatus 202 and the cooling working medium in the three third cooling apparatuses 203. The first circulation flow path 103, the second circulation flow path 104, and the third circulation flow path 105 each include a liquid inlet sub-flow path for allowing the cooling working medium to flow from the cold source device 10 to the cooling apparatus 20, and a liquid return sub-flow path for allowing the cooling working medium to flow from the cooling apparatus 20 back to the cold source device 10.

In addition, a series of structures such as a flow meter, a pressure sensor, a temperature sensor, a valve body, and a filter may be provided on the circulation flow paths, which are not specifically limited in the embodiments of the present application, and may be correspondingly disposed by those skilled in the art according to actual needs.

In the embodiment of the present application, the cooling performance and refrigeration capacity of the first cold source device 101 may be correspondingly set according to the cooling requirements of the cooling working medium in the first cooling apparatus 201. Similarly, the cooling performance and refrigeration capacity of the second cold source device 102 may be correspondingly set according to the cooling requirements of the cooling working medium in the second cooling apparatus 202. More specifically, the refrigeration capacity of the first cold source device 101 should be greater than the cooling demand of the first cooling apparatus 201, and the refrigeration capacity of the second cold source device 102 should be greater than the cooling demand of the second cooling apparatus 202.

It should be noted that the cooling working medium in the third cooling apparatus 203 is cooled jointly by utilizing the cooling redundancy of the first cold source device 101 and the second cold source device 102. Therefore, the cooling performance of the first cold source device 101 should meet the requirement that the refrigeration capacity is greater than the cooling demand of the first cold source device 101, and the cooling performance of the second cold source device 102 should meet the requirement that the refrigeration capacity is greater than the cooling demand of the second cold source device 102. Based on this, the number of third cooling apparatuses 203 may be correspondingly set according to the cooling redundancy of the first cold source device 101 and the second cold source device 102, as well as the cooling demand of a single third cooling apparatus 203.

In the liquid-cooled data center 1 according to the embodiment of the present application, by providing the first cold source device 101 and the second cold source device 102 to cool the cooling working medium in the plurality of cooling apparatuses 20, the first cold source device 101 can cool the cooling working medium in the first cooling apparatus 201 and the third cooling apparatus 203, and the second cold source device 102 can cool the cooling working medium in the second cooling apparatus 202 and the third cooling apparatus 203. Thus, on the one hand, the cooling needs of a plurality of computing devices in the data center are met, which is conducive to improving the circulation efficiency of the circulation flow of the cooling working medium among the plurality of computing devices. On the other hand, the number of the third cooling apparatus 203 may be correspondingly configured according to the cooling redundancy of the first cold source device 101 and the second cold source device 102, thereby achieving modular expansion of the third cooling apparatus 203 and then achieving modular configuration of the computing devices in the data center, which is conducive to iterative updates of the computing devices. In addition, this also helps to improve the integration of the data center, thereby improving the energy and space utilization rates of the data center.

In an implementation, the cold source device 10 includes a heat exchange assembly. As shown in FIG. 1, the first cold source device 101 and the second cold source device 102 both include a first heat exchange assembly 10a and a second heat exchange assembly 10b, with the first heat exchange assembly 10a of the first cold source device 101 used for cooling the cooling working medium in the first cooling apparatus 201, the first heat exchange assembly 10a of the second cold source device 102 used for cooling the cooling working medium in the second cooling apparatus 202, and the second heat exchange assemblies 10b of the first cold source device 101 and the second cold source device 102 used for jointly cooling the cooling working medium in the third cooling apparatus 203.

In the embodiment of the present application, the cold source device 10 includes at least two heat exchange assemblies independent of each other, each for separately exchanging heat with and cooling the cooling working medium. The first heat exchange assembly 10a and the second heat exchange assembly 10b of the first cold source device 101 are used for cooling the cooling working medium in the first cooling apparatus 201 and the third cooling apparatus 203, respectively, and the first heat exchange assembly 10a and the second heat exchange assembly 10b of the second cold source device 102 are used for cooling the cooling working medium in the second cooling apparatus 202 and the third cooling apparatus 203, respectively.

It should be noted that the structure and heat exchange method of the heat exchange assemblies of the first cold source device 101 and the second cold source device 102 may be the same or different, and the structure and heat exchange method of the first heat exchange assembly 10a and the second heat exchange assembly 10b of the first cold source device 101 or the second cold source device 102 may be the same or different. By way of example, the heat exchange assemblies of the first cold source device 101 and the second cold source device 102 have different structures and heat exchange methods. The heat exchange assembly of the first cold source device 101 may employ a liquid medium to cool the cooling working medium, and the structures of the first heat exchange assembly 10a and the second heat exchange assembly 10b of the first cold source device 101 are also the same; or the heat exchange assembly of the second cold source device 102 may adopt a gaseous medium to cool the cooling working medium, and the structures of the first heat exchange assembly 10a and the second heat exchange assembly 10b of the second cold source device 102 are also the same.

Optionally, as shown in FIG. 1, the first cold source device 101 further includes a first heat exchanger 101a for performing heat exchange between a liquid medium output from the first heat exchange assembly 10a of the first cold source device 101 and the cooling working medium in the first circulation flow path 103; the second cold source device 102 further includes a second heat exchanger 102a for performing heat exchange between a liquid medium output from the first heat exchange assembly 10a of the second cold source device 102 and the cooling working medium in the second circulation flow path 104; and the second heat exchange assemblies 10b of the first cold source device 101 and the second cold source device 102 are respectively in communication with the third circulation flow path 105.

Exemplarily, both the first heat exchanger 101a and the second heat exchanger 102a may be plate heat exchangers. The first cold source device 101 further includes a first cooling flow path, and the first cooling flow path and the first circulation flow path 103 flow through the first heat exchanger 101a respectively. The first heat exchange assembly 10a is used for cooling a refrigerant, which flows through the first heat exchanger 101a through the cooling flow path, so that the refrigerant exchanges heat with the cooling working medium in the first circulation flow path 103 at the first heat exchanger 101a, so as to achieve the purpose of cooling the cooling working medium in the first cooling apparatus 201. The second cold source device 102 further includes a second cooling flow path, and the second cooling flow path and the second circulation flow path 104 flow through the second heat exchanger 102a respectively. The second heat exchange assembly 10b is used for cooling a refrigerant, which flows through the second heat exchanger 102a through the cooling flow path, so that the refrigerant exchanges heat with the cooling working medium in the second circulation flow path 104 at the second heat exchanger 102a, so as to achieve the purpose of cooling the cooling working medium in the first cooling apparatus 201. The second heat exchange assembly 10b of the first cold source device 101 and the second heat exchange assembly 10b of the second cold source device 102 are in communication with the third circulation flow path 105, respectively. The cooling working medium in the third cooling apparatus 203 directly enters the second heat exchange assemblies 10b of the first cold source device 101 and the second cold source device 102 through the third circulation flow path 105, so that the second heat exchange assemblies 10b of the first cold source device 101 and the second cold source device 102 directly perform heat exchange and cooling on the cooling working medium in the third cooling apparatus 203.

Optionally, the first heat exchange assembly and the second heat exchange assembly 10b of the first cold source device 101 cool the cooling working medium through a liquid medium, and the first heat exchange assembly 10a and the second heat exchange assembly 10b of the second cold source device 102 cool the cooling working medium through a gaseous medium.

Exemplarily, the heat exchange assembly of the first cold source device 101 may be a condenser, and the liquid medium may be cooling water. The first heat exchange assembly 10a and the second heat exchange assembly 10b of the first cold source device 101 each include a first heat exchange coil, which is used for enabling flow-through of the cooling working medium in the first cooling apparatus 201 and flow-through of the cooling working medium in the third cooling apparatus 203 respectively. By means of spraying the cooling water to the first heat exchange coil, heat exchange takes place between the cooling water and the cooling working medium in the first heat exchange coil. Exemplarily, the heat exchange assembly of the second cold source device 102 may be a dry cooler, and the gaseous medium may be external air. The first heat exchange assembly 10a and the second heat exchange assembly 10b of the second cold source device 102 each include a second heat exchange coil, which is used for enabling flow-through of the cooling working medium in the second cooling apparatus 202 and flow-through of the cooling working medium in the third cooling apparatus 203 respectively. By means of guiding the air to the second heat exchange coil, heat exchange takes place between the air and the cooling working medium in the second heat exchange coil.

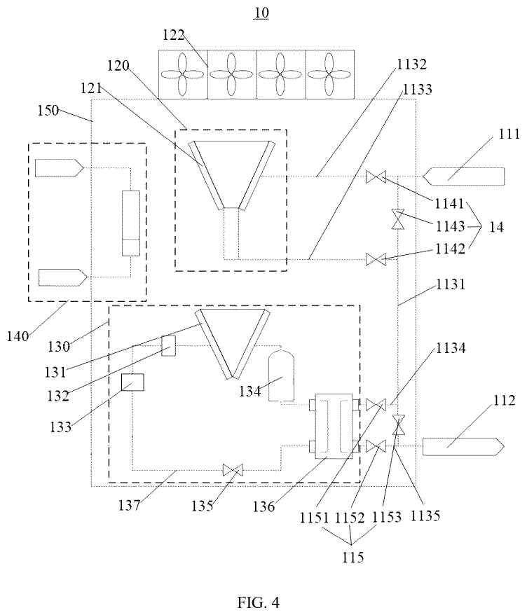

In an implementation, as shown in FIG. 4, the heat exchange assembly includes a pipeline module, a first heat exchange module 120, and a second heat exchange module 130. Specifically, the pipeline module includes an input pipeline 111 for inputting the cooling working medium to be cooled, an output pipeline 112 for outputting the cooled cooling working medium, and a connecting pipeline connected between the input pipeline 111 and the output pipeline 112. Input and output ends of the first heat exchange module 120 are in communication with the connecting pipeline respectively for cooling the cooling working medium through the gaseous medium. Input and output ends of the second heat exchange module 130 are in communication with the connecting pipeline respectively for cooling the cooling working medium through the liquid medium. The connecting pipeline is provided with a valve assembly for causing the cooling working medium to flow through at least one of the first heat exchange module 120 and the second heat exchange module 130.

Exemplarily, an input end of the input pipeline 111 and an output end of the output pipeline 112 of the pipeline module are connected with output and input ends of the cooling apparatus respectively, so as to receive, through the input end of the input pipeline 111, the high-temperature cooling working medium output from the cooling apparatus, then exchange heat with the high-temperature cooling working medium through the heat exchange module, and thereafter transport the low-temperature cooling working medium back to the cooling apparatus through the output end of the output pipeline 112. The input end of the input pipeline 111 and the output end of the output pipeline 112 are provided with a transporting pipeline for transporting the cooling working medium between them and the cooling apparatus.

Exemplarily, the first heat exchange module 120 may be a dry cooler, and the gaseous medium may be air. Specifically, heat exchange is performed between air and the cooling working medium to achieve the purpose of cooling the cooling working medium. The second heat exchange module 130 may be a compressor 134 system, and the liquid medium may be any type of liquid refrigerant, such as R22 (difluorochloromethane) refrigerant or R-134a (tetrafluoroethane). Specifically, heat exchange is performed between the liquid refrigerant and the cooling working medium to achieve the purpose of cooling the cooling working medium.

Exemplarily, the input and output ends of the first heat exchange module 120 and those of the second heat exchange module 130 are respectively connected with the connecting pipeline, and the first heat exchange module 120 and the second heat exchange module 130 may be respectively disposed adjacent to input and output sides of the input pipeline 111. The valve assembly disposed on the connecting pipeline may include a plurality of valve bodies that may be respectively disposed between the input end of the first heat exchange module 120 and the connecting pipeline, between the output end of the first heat exchange module 120 and the connecting pipeline, between the input end of the second heat exchange module 130 and the connecting pipeline, between the output end of the second heat exchange module 130 and the connecting pipeline, between two nodes of the connecting pipeline in communication with the first heat exchange module 120, and between two nodes of the connecting pipeline in communication with the second heat exchange module 130. Thus, by controlling open and closed states of the plurality of valve bodies, it is possible to achieve that the cooling working medium flows only through the first heat exchange module 120, or that the cooling working medium flows only through the second heat exchange module 130, or that the cooling working medium flows through the first heat exchange module 120 and the second heat exchange module 130 in sequence.

It should be noted that the first heat exchange module 120 exchanges heat with the cooling working medium through a gaseous medium at a relatively low heat exchange efficiency, but the operating energy consumption of the first heat exchange module 120 is also relatively low. The second heat exchange module 130 exchanges heat with the cooling working medium through a liquid medium, resulting at a relatively high heat exchange efficiency, but the operating energy consumption of the second heat exchange module 130 is also relatively high.

Based on this, by controlling open and closed states of the valve assembly to allow the cooling working medium to flow through at least one of the first heat exchange module 120 and the second heat exchange module 130, at least three heat exchange modes of the cold source device 10 can be achieved, thereby providing different degrees of cooling to the cooling working medium.

According to the above implementation, by providing the first heat exchange module 120 and the second heat exchange module 130 having different heat exchange forms, and by controlling the open and closed states of the valve assembly on the connecting pipeline, at least three different heat exchange modes of the cold source device 10 can be achieved, so that the heat exchange modes can be switched according to actual heat exchange needs (e.g., according to different outdoor ambient temperatures or different running conditions of the computing device), achieving different degrees of cooling of the cooling working medium. This can not only improve the stability of cooling the computing device, but also help to achieve energy conservation and emission reduction, and enhance environmental benefits.

In an implementation, as shown in FIG. 4, the connecting pipeline includes an intermediate pipeline 1131, a first liquid inlet pipeline 1132, a first liquid outlet pipeline 1133, a second liquid inlet pipeline 1134, and a second liquid outlet pipeline 1135, with an input end and an output end of the intermediate pipeline 1131 respectively connected to the input pipeline 111 and the output pipeline 112, the first liquid inlet pipeline 1132 connected between the input end of the first heat exchange module 120 and the intermediate pipeline 1131, the first liquid outlet pipeline 1133 connected between the output end of the first heat exchange module 120 and the intermediate pipeline 1131, the second liquid inlet pipeline 1134 connected between the input end of the second heat exchange module 130 and the intermediate pipeline 1131, and the second liquid outlet pipeline 1135 connected between the output end of the second heat exchange module 130 and the intermediate pipeline 1131.

Exemplarily, the first liquid inlet pipeline 1132 and the first liquid outlet pipeline 1133 are connected to a side of the intermediate pipeline 1131 adjacent to its input end, and the second liquid inlet pipeline 1134 and the second liquid outlet pipeline 1135 are connected to a side of the intermediate pipeline 1131 adjacent to its output end.

In the embodiment of the present application, in a first heat exchange mode in which the first heat exchange module 120 works alone, the cooling working medium to be cooled enters the intermediate pipeline 1131 via the input pipeline 111, then enters the first heat exchange module 120 through the first liquid inlet pipeline 1132, and flows back to the intermediate pipeline 1131 through the first liquid outlet pipeline 1133 following heat exchange at the first heat exchange module 120. In a second heat exchange mode in which the second heat exchange module 130 works alone, the cooling working medium to be cooled enters the intermediate pipeline 1131 via the input pipeline 111, then enters the second heat exchange module 130 through the second liquid inlet pipeline 1134, and flows back to the intermediate pipeline 1131 through the second liquid outlet pipeline 1135 following heat exchange at the second heat exchange module 130. In a third heat exchange mode in which the first heat exchange module 120 and the second heat exchange module 130 work together, the cooling working medium to be cooled, after heat exchange at the first heat exchange module 120, flows back to the intermediate pipeline 1131 through the first liquid outlet pipeline 1133, then enters the second heat exchange module 130 through the second liquid inlet pipeline 1134, flows back to the intermediate pipeline 1131 through the second liquid outlet pipeline 1135 following heat exchange at the second heat exchange module 130, and is finally output to the cooling apparatus through the output pipeline 112.

Optionally, the valve assembly includes a first valve assembly 114 and a second valve assembly 115. The first valve assembly 114 includes a first liquid inlet valve 1141 provided in the first liquid inlet pipeline 1132, a first liquid outlet valve 1142 provided in the first liquid outlet pipeline 1133, and a first on-off valve 1143 provided in the intermediate pipeline 1131. The second valve assembly 115 includes a second liquid inlet valve 1151 provided in the second liquid inlet pipeline 1134, a second liquid outlet valve 1152 provided in the second liquid outlet pipeline 1135, and a second on-off valve 1153 provided in the intermediate pipeline 1131.

It should be noted that the first on-off valve 1143 is provided between two connection nodes that connect the intermediate pipeline 1131 with the first liquid inlet pipeline 1132 and the first liquid outlet pipeline 1133 respectively. With the first liquid inlet valve 1141 and the first liquid outlet valve 1142 open and the first on-off valve 1143 closed, the cooling working medium enters the first heat exchange module 120 from the intermediate pipeline 1131, and then flows back to the intermediate pipeline 1131 following heat exchange. With the first liquid inlet valve 1141 and the first liquid outlet valve 1142 closed and the first on-off valve 1143 open, the cooling working medium does not pass through the first heat exchange module 120 at all.

The second on-off valve 1153 is provided between two connection nodes that connect the intermediate pipeline 1131 with the second liquid inlet pipeline 1134 and the second liquid outlet pipeline 1135 respectively. With the second liquid inlet valve 1151 and the second liquid outlet valve 1152 open and the second on-off valve 1153 closed, the cooling working medium enters the second heat exchange module 130 from the intermediate pipeline 1131, and then flows back to the intermediate pipeline 1131 following heat exchange. With the second liquid inlet valve 1151 and the second liquid outlet valve 1152 closed and the second on-off valve 1153 open, the cooling working medium does not pass through the second heat exchange module 130.

Exemplarily, the cold source device 10 further includes a control apparatus 160 for controlling the open and closed states of the first valve assembly 114 and the second valve assembly 115. In the first heat exchange mode, the control apparatus 160 controls the first liquid inlet valve 1141 to open, the first liquid outlet valve 1142 to open, the first on-off valve 1143 to close, the second liquid inlet valve 1151 to close, the second liquid outlet valve 1152 to close, and the second on-off valve 1153 to open, so that the cooling working medium to be cooled passes only through the first heat exchange module 120. In the second heat exchange mode, the control apparatus 160 controls the first liquid inlet valve 1141 to close, the first liquid outlet valve 1142 to close, the first on-off valve 1143 to open, the second liquid inlet valve 1151 to open, the second liquid outlet valve 1152 to open, and the second on-off valve 1153 to close, so that the cooling working medium to be cooled passes only through the second heat exchange module 130. In the third heat exchange mode, the control apparatus 160 controls the first liquid inlet valve 1141 to open, the first liquid outlet valve 1142 to open, the first on-off valve 1143 to close, the second liquid inlet valve 1151 to open, the second liquid outlet valve 1152 to open, and the second on-off valve 1153 to close, so that the cooling working medium to be cooled passes through the first heat exchange module 120 and the second heat exchange module 130 in sequence.

According to the above implementation, by controlling the open and closed states of the first valve assembly 114 and the second valve assembly 115, the automatic switching of the three heat exchange modes is implemented without the need for manual adjustment.

In an implementation, the first heat exchange module 120 includes a heat exchange coil 121 for flow of the cooling working medium, so that heat exchange takes place between the cooling working medium and the gaseous medium.

Exemplarily, the first heat exchange module 120 further includes a fan assembly 122 for drawing a gaseous medium from the outside of the cold source device 10 to the inside of the cold source device 10, and causing the gaseous medium to flow through the heat exchange coil 121, so that heat exchange takes place between the gaseous medium and the cooling working medium in the heat exchange coil 121.

It should be noted that the specific structure of the heat exchange coil 121 is not limited in the embodiments of the present application, and those skilled in the art may employ any structure already known or knowable in the future.

With the above implementation, the first heat exchange module 120 can utilize natural air cooling to exchange heat with the cooling working medium, thereby reducing the working energy consumption of the first heat exchange module 120.

In an implementation, the second heat exchange module 130 includes a condenser 131, an expansion valve 132, a liquid storage tank 133, a heat exchange unit 136, a compressor 134, and a circulation pipeline 137, the circulation pipeline 137 is used for circulation flow of the liquid medium among the condenser 131, the expansion valve 132, the liquid storage tank 133, the heat exchange unit 136, and the compressor 134, and heat exchange between the liquid medium and the cooling working medium is taken place at the heat exchange unit 136.

Exemplarily, in a circulation flow direction of the liquid medium, the condenser 131, the expansion valve 132, the liquid storage tank 133, the compressor 134, a throttle valve 135 and the heat exchange unit 136 are connected sequentially through the circulation pipeline 137. The liquid storage tank 133 is used for storing liquid medium, the expansion valve 132 is used for expanding and depressurizing to convert medium-temperature and high-pressure liquid medium into low-temperature and low-pressure liquid medium, and the compressor 134 is used for compressing low-temperature and low-pressure gaseous medium into high-temperature and high-pressure gas-phase medium and sending same into the condenser 131. The heat exchange unit 136 may be a plate heat exchanger, inside of which is provided with a first heat exchange flow path connected with the circulation pipeline 137, and a second heat exchange flow path connected with the second liquid inlet pipeline 1134 and the second liquid outlet pipeline 1135. Heat exchange between the high-temperature and high-pressure gas-phase medium in the first heat exchange path with the cooling working medium in the second heat exchange path takes place within the plate heat exchanger so as to cool the cooling working medium.

With the above implementation, the heat exchange efficiency of the second heat exchange module 130 for the cooling working medium is significantly improved. Especially under the condition of high outdoor ambient temperature, the cooling performance on the cooling working medium can be significantly improved, thereby ensuring the stable running of the computing device.

In an implementation, the cold source device 10 includes at least two heat exchange assemblies independent of each other, each including a pipeline module, a first heat exchange module 120, and a second heat exchange module 130. Different heat exchange assemblies are used for cooling different types of cooling working media.

By way of example, the cold source device 10 may include a first heat exchange assembly for cooling a first cooling working medium employed in the first cooling apparatus, and a second heat exchange assembly for cooling a second cooling working medium employed in the second cooling apparatus. A cooling method employed in the first cooling apparatus may be water cooling, and a cooling method employed in the second cooling apparatus may be immersion liquid cooling. Correspondingly, the first and second cooling working media are different. For example, the first cooling working medium may be water, and the second cooling working medium may be electronic fluorinated liquid.

Thus, the cold source device 10 can support simultaneous heat exchange of different types of cooling working media to meet the working requirements of the cooling apparatuses employing different cooling methods.

In an implementation, as shown in FIGS. 4 and 5, the cold source device 10 further includes a gaseous medium cooling module 140 for cooling the gaseous medium and guiding the cooled gaseous medium to the first heat exchange module 120.

Exemplarily, the cold source device 10 further includes a body 150, inside which the pipeline module, the first heat exchange module 120 and the second heat exchange module 130 are mounted. There may be one or more gaseous medium cooling modules 140 that are provided on side walls of the body 150 respectively, and the fan assembly 122 of the first heat exchange module 120 may be provided on a top of the body 150. Thus, the gaseous medium cooling module 140 can guide the gaseous medium laterally from the outside of the body 150 into the inside of the body 150, and guide the other media after heat exchange upward to the outside of the body 150.

Exemplarily, an air outlet side of the gaseous medium cooling module 140 is disposed toward the heat exchange coil 121 of the first heat exchange module 120, so that the gaseous medium cooled by the gaseous medium cooling module 140 exchanges heat with the cooling working medium in the heat exchange coil 121 of the first heat exchange module 120. In addition, in other examples of the present application, the air outlet side of the gaseous medium cooling module 140 may be disposed toward both the heat exchange coil 121 of the first heat exchange module 120 and the heat exchange unit 136 of the second heat exchange module 130, so that low-temperature gaseous medium is not only used by the first heat exchange module to exchange heat with the cooling working medium, but also helps to improve the heat exchange efficiency of the second heat exchange module 130 for the cooling working medium.

Optionally, the gaseous medium cooling module 140 includes a wet curtain 141 having flow guide holes that make inside and outside of the cold source device 10 in communication, a wet curtain spray pipe 142 for spraying cooling water to the wet curtain 141, and a wet curtain water tray 143 provided below the wet curtain 141 to receive the cooling water.

Exemplarily, the wet curtain 141 may be made of a polymer paper material, and a plurality of flow guide holes on the wet curtain 141 form a honeycomb structure. The wet curtain spray pipe 142 is used for spraying cooling water evenly onto the wet curtain 141, so that in a process where air outside the cold source device 10 enters the inside of the cold source device 10 through the flow guide holes of the wet curtain 141 under the negative pressure of the fan assembly 122, the air exchanges heat with the cooling water, so as to achieve the purpose of cooling the gaseous medium.

Thus, by cooling the gaseous medium, so that the cooled gaseous medium is used by the first heat exchange module 120 to cool the cooling working medium, the heat exchange efficiency of the first heat exchange module 120 is further improved.

In an implementation, the cold source device 10 further includes a control apparatus 160 for controlling open and closed states of the valve assembly according to an outdoor ambient temperature to allow the cooling working medium to flow through at least one of the first heat exchange module 120 and the second heat exchange module 130, and controlling a working state of the gaseous medium cooling module 140.

By way of example, by controlling the open and closed states of the valve assembly and the working state of the gaseous medium cooling module 140, the control apparatus 160 can achieve several heat exchange modes of the cold source device 10, which, for example, may include: the first heat exchange module 120 operating alone, the first heat exchange module 120 and the gaseous medium cooling module 140 operating together, the second heat exchange module 130 operating alone, the first heat exchange module 120 and the second heat exchange module 130 operating together, and the first heat exchange module 120, the second heat exchange module 130 and the gaseous medium cooling module 140 operating.

Optionally, the control apparatus 160 is configured to: control the valve assembly to allow the cooling working medium to flow through the first heat exchange module 120 if the outdoor ambient temperature meets a first preset temperature range; control the valve assembly to allow the cooling working medium to flow through the first heat exchange module 120 and control the gaseous medium cooling module 140 to start if the outdoor ambient temperature meets a second preset temperature range; and control the valve assembly to allow the cooling working medium to flow sequentially through the first heat exchange module 120 and the second heat exchange module 130 and control the gaseous medium cooling module 140 to start if the outdoor ambient temperature meets a third preset temperature range.

In the embodiment of the present application, a maximum value of the first preset temperature range is less than or equal to a minimum value of the second preset temperature range, and a maximum value of the second preset temperature range is less than or equal to a minimum value of the third preset temperature range. The specific numerical ranges of the first preset temperature range, the second preset temperature range, and the third preset temperature range may be specifically set by those skilled in the art according to factors such as the average temperature of the working environment where the cold source device 10 is located, the heat generation of the computing device, and the refrigerating capacity requirement of the refrigerating device, which is not specifically limited in the embodiments of the present application.

In a specific example, the cold source device 10 further includes a dry-bulb/wet-bulb temperature detection module for detecting the outdoor ambient temperature in real time. In a case where the first preset temperature range is less than or equal to 35° C., and the dry-bulb/wet-bulb temperature detection module detects that the outdoor ambient temperature is less than or equal to 35° C., the control apparatus 160 controls the first liquid inlet valve 1141 of the first valve assembly 114 to open, the first liquid outlet valve 1142 to open, and the first on-off valve 1143 to close, the second liquid inlet valve 1151 of the second valve assembly 115 to close, and the second liquid outlet valve 1152 to close, and the second on-off valve 1153 to open; and controls the gaseous medium cooling module 140 to close, so that the cooling working medium is cooled by the first heat exchange module 120 alone. In a case where the second preset temperature range is greater than 35° C. and less than or equal to 40° C., and the dry-bulb/wet-bulb temperature detection module detects that the outdoor ambient temperature is greater than 35° C. and less than or equal to 40° C., the control apparatus 160 controls the first liquid inlet valve 1141 of the first valve assembly 114 to open, the first liquid outlet valve 1142 to open, and the first on-off valve 1143 to close, and the second liquid inlet valve 1151 of the second valve assembly 115 to close, the second liquid outlet valve 1152 to close, and the second on-off valve 1153 to open; and controls the gaseous medium cooling module 140 to operate, so that the cooling working medium is cooled jointly by the first heat exchange module 120 and the gaseous medium cooling module 140. In a case where the second preset temperature range is greater than 40° C., and the dry-bulb/wet-bulb temperature detection module detects that the outdoor ambient temperature is greater than 40° C., the control apparatus 160 controls the first liquid inlet valve 1141 of the first valve assembly 114 to open, the first liquid outlet valve 1142 to open, and the first on-off valve 1143 to close, and the second liquid inlet valve 1151 of the second valve assembly 115 to open, the second liquid outlet valve 1152 to open, and the second on-off valve 1153 to close; and controls the gaseous medium cooling module 140 to operate, so that the cooling working medium is cooled jointly by the first heat exchange module 120, the gaseous medium cooling module 140, and the second heat exchange module 130.

With the above implementation, the working states of the first heat exchange module 120, the second heat exchange module 130 and the gaseous medium cooling module 140 are automatically controlled according to the different outdoor ambient temperatures, so as to provide different degrees of cooling capacity for the cooling working medium, thereby meeting different requirements of the cooling device for cooling capacity.

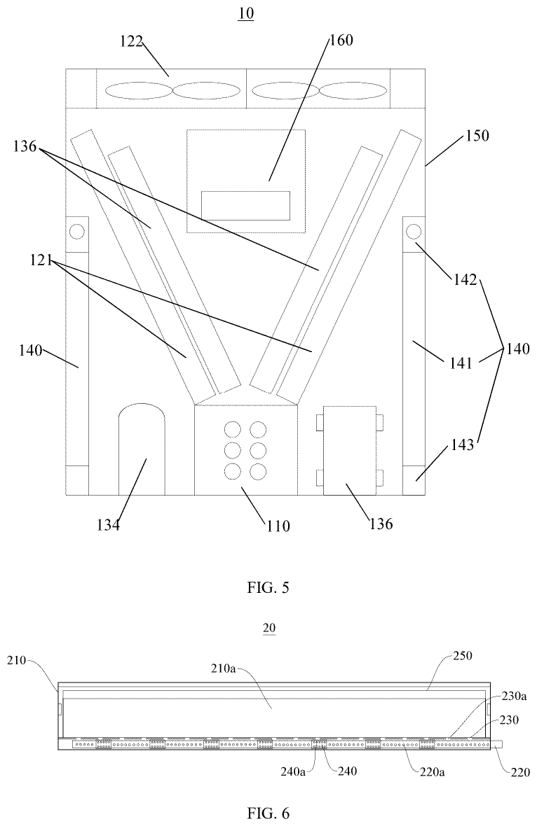

In an implementation, as shown in FIGS. 6 to 8, the cooling apparatus 20 includes a housing 210, a flow guide pipe 220, and a flow guide plate 230. Specifically, the inside of the housing 210 defines a cooling chamber 210a. The flow guide pipe 220 is provided in the cooling chamber 210a, and a pipe wall of the flow guide pipe 220 is provided with a plurality of liquid outlet holes 220a for inputting the cooling working medium to the cooling chamber 210a. The flow guide plate 230 is provided in the cooling chamber 210a and located above the flow guide pipe 220, and the flow guide plate 230 is provided with a plurality of flow guide through-holes 230a which make upper and lower sides of the flow guide plate 230 in communication. The cooling chamber 210a accommodates a plurality of server modules 30 located on the upper side of the flow guide plate 230, the flow guide plate 230 has a plurality of flow guide regions 230b corresponding to the plurality of server modules 30, and a flow-through area and/or arrangement density of the flow guide through-holes 230a in a flow guide region 230b are positively correlated with the computing capacity of a corresponding server module 30.

In the embodiment of the present application, each server module 30 may include at least one server 301 with the same computing capacity, and the computing capacity corresponding to the servers 301 in different server modules 30 may be the same or different.

It should be noted that the computing capacity may be defined in various ways well known to those skilled in the art. By way of example, the computing capacity of the server 301 may be defined according to the maximum number of floating-point operations that can be performed per unit time, or according to the maximum number of operations that can be performed per unit time, or according to the maximum number of instructions that can be processed per unit time, which is not specifically limited in the embodiments of the present application. It may be understood that the stronger the computing capacity of the server module 30, the more heat the server module 30 generates per unit time.

In the embodiment of the present application, a cooling method of the cooling apparatus 20 is an immersion liquid cooling method. The immersion liquid cooling refers to a cooling method in which the server module 30 is directly immersed in a cooling working medium with electrical insulation properties, so that heat generated by the server module 30 in a working process can be directly conducted to the cooling working medium, thereby achieving cooling of the server module 30. By employing the immersion liquid cooling method, the heat generated by the server module 30 can be directly and effectively transferred to the cooling working medium, which, compared with air cooling or water cooling methods usually employed in related technologies, significantly improves the efficiency of cooling the server module 30 without providing thermal interface materials, heat sinks, fans and other components, and is also conducive to energy conservation and environmental protection.

In the following description of the embodiments of the present application, a first direction and a second direction are perpendicular to each other and are respectively perpendicular to a vertical direction. Specifically, the first direction may be a length direction of the housing 210, and the second direction may be a width direction of the housing 210.

In the embodiment of the present application, the flow guide pipe 220 is used for inputting the cooling working medium into the cooling chamber 210a. A liquid inlet end of the flow guide pipe 220 is connected with the cold source device which is used for inputting the condensed cooling working medium into the flow guide pipe 220 through the liquid inlet end. The liquid inlet end of the flow guide pipe 220 may be provided at an end of the flow guide pipe 220, or at the middle or other positions adjacent to the middle of the flow guide pipe 220, which is not specifically limited in the embodiments of the present application.

Exemplarily, the housing 210 further includes a cover plate 211, which is movably provided on a top of the housing 210 for opening or closing a cavity inside the housing 210.

Exemplarily, the flow guide plate 230 is provided in the cooling chamber 210a along the horizontal direction to partition the cooling chamber 210a into an upper space and a lower space. A plurality of cooling modules are provided in the upper space of the cooling chamber 210a, and the flow guide pipe 220 is provided in the lower space of the cooling chamber 210a. A plurality of flow guide through-holes 230a are arranged in an array on the flow guide plate 230. For example, the plurality of flow guide through-holes 230a may be arranged in multiple sets at intervals in the first direction, with a plurality of flow guide through-holes 230a in each set arranged at intervals along the second direction. It can be understood that after the cooling working medium is input into the lower space of the cooling chamber 210a through the flow guide pipe 220, the cooling working medium can enter the upper space of the cooling chamber 210a through the plurality of flow guide through-holes 230a on the flow guide plate 230, and then immerse the plurality of cooling modules located in the upper space. The embodiments of the present application do not specifically limit the method of fixing the flow guide plate 230 in the cooling chamber 210a, and for example, it may be fixed in a connection manner by employing fasteners, or may be fixed in an engagement connection manner by employing an interlocking structure.

In the embodiments of the present application, the arrangement of the plurality of server modules 30 in the cooling chamber 210a is not specifically limited.

In one example, the plurality of server modules 30 may be arranged adjacently along a same direction. For example, the plurality of server modules 30 may be arranged adjacently in the first or second direction. In another example, the plurality of server modules 30 may be arranged in an array. For example, the plurality of server modules 30 may be arranged in multiple rows in the first direction and in multiple columns in the second direction.

In the embodiment of the present application, the plurality of flow guide regions 230b correspond to the plurality of server modules 30. It is possible that one flow guide region 230b corresponds to several server modules 30, or that several flow guide regions 230b correspond to one server module 30, or that each flow guide region 230b corresponds to one server module 30.

In one example, the plurality of flow guide regions 230b of the flow guide plate 230 and the plurality of server modules 30 are in a one-to-one correspondence, with each flow guide region 230b disposed directly opposite to a corresponding server module 30 in the vertical direction. By way of example, the plurality of server modules 30 may be arranged adjacently along the first direction, and the plurality of flow guide regions 230b may likewise be arranged adjacently along the first direction, with each flow guide region 230b located directly below a corresponding server module 30.

For different flow guide regions 230b, a flow-through area and/or arrangement density of the flow guide through-holes 230a in a flow guide region 230b may be correspondingly set according to different computing capacity of a corresponding server module 30.

For example, the flow-through area of the flow guide through-holes 230a in different flow guide regions 230b may be the same, while the arrangement density of the flow guide through-holes 230a in a flow guide region 230b is positively correlated with the computing capacity of a server module 30 corresponding to the flow guide region 230b. For another example, the arrangement density of the flow guide through-holes 230a in different flow guide regions 230b may be the same, while the flow-through area of the flow guide through-holes 230a in a flow guide region 230b is positively correlated with the computing capacity of a server module 30 corresponding to the flow guide region 230b. For still another example, the flow-through area and arrangement density of the flow guide through-holes 230a in different flow guide regions 230b are positively correlated with the computing capacity of server modules 30 corresponding to the flow guide regions 230b.

It can be understood that the stronger the computing capacity of a server module 30 corresponding to a flow guide region 230b, the larger the flow-through area of the flow guide through-holes 230a in the flow guide region 230b, and/or the greater the arrangement density of the flow guide through-holes 230a; the weaker the computing capacity of a server module 30 corresponding to a flow guide region 230b, the smaller the flow-through area of the flow guide through holes 230a in the flow guide region 230b, and/or the smaller the arrangement density of the flow guide through-holes 230a.

It should be noted that the flow-through area and arrangement density of the flow guide through-holes 230a in the flow guide regions 230b can directly affect the flow rate of the cooling working medium flowing to the server modules 30 through the flow guide regions 230b per unit time. The larger the flow-through area of the flow guide through-holes 230a in a flow guide region 230b, the greater the flow rate of the cooling working medium flowing to a corresponding server module 30 through the flow guide region 230b per unit time; conversely, the smaller the flow rate of the cooling working medium flowing to the corresponding server module 30 through the flow guide region 230b per unit time. The greater the arrangement density of the flow guide through-holes 230a in a flow guide region 230b, the greater the flow rate of the cooling working medium flowing to a corresponding server module 30 through the flow guide region 230b per unit time; conversely, the smaller the flow rate of the cooling working medium flowing to the corresponding server module 30 through the flow guide region 230b per unit time. It can be understood that the greater the flow rate of the cooling working medium flowing through a flow guide region 230b to a corresponding server module 30 per unit time, the higher the cooling efficiency of the server module 30; conversely, the lower the cooling efficiency of the server module 30.

According to the above implementation, by providing in the cooling chamber 210a the flow guide plate 230 having the plurality of flow guide through-holes 230a, and dividing the flow guide plate 230 into the plurality of flow guide regions 230b corresponding to the plurality of server modules 30, with the flow-through area and/or arrangement density of the flow guide through-holes 230a in a flow guide region 230b positively correlated with the computing capacity of a corresponding server module 30, a corresponding flow rate of the cooling working medium directed to the server module 30 is matched according to the computing capacity of the server module 30. For example, for a server module 30 with relatively strong computing capacity, a cooling working medium with a higher flow rate can be provided to the server module 30 by its corresponding flow guide region 230b; and for a server module 30 with relatively weak computing capacity, a cooling working medium with a lower flow rate can be provided to the server module 30 by its corresponding flow guide region 230b. Thus, the cooling working medium can be evenly allocated to different server modules 30 according to the computing capacity, thereby improving the uniformity of cooling for the server modules 30 with different computing capacity, reducing the probability of uneven temperature distribution of the cooling working medium in the cooling chamber 210a, then reducing the probability of backflow of the cooling working medium due to excessively high local temperature of the cooling working medium, and improving the working stability and reliability of the server modules 30.

In the embodiment of the present application, the flow guide plate 230 may be an integrally molded member, or may be formed by splicing a plurality of components that are mutually individual members.

In an implementation, the flow guide plate 230 includes a plurality of flow guide sub-plates 231 that define the flow guide regions 230b.

Exemplarily, the plurality of server modules 30 are arranged along the first direction, and the plurality of flow guide sub-plates 231 are likewise arranged adjacently along the first direction. The plurality of server modules 30 and the plurality of flow guide sub-plates 231 are in a one-to-one correspondence, with the server modules 30 disposed directly opposite to the corresponding flow guide sub-plates 231 in the vertical direction. Each flow guide sub-plate 231 defines a flow guide region 230b.

Optionally, among the plurality of flow guide sub-plates 231, adjacent flow guide sub-plates 231 may be arranged at intervals or adjacently. Furthermore, the adjacent flow guide sub-plates 231 may also be fixedly connected by fasteners or an interlocking structure to improve the stability of the overall structure of the flow guide plate 230.

In addition, the flow guide sub-plates 231 may be correspondingly shaped or sized according to the cross-sectional shape and size of the cooling chamber 210a and the projected shape and size of the server modules 30, which is not specifically limited in the embodiments of the present application.

According to the above implementation, by providing the flow guide plate 230 as the plurality of flow guide sub-plates 231 that are mutually individual members, the modular design of the flow guide plate 230 is implemented. For the server modules 30 with different computing capacity, appropriate flow guide sub-plates 231 may be matched. Furthermore, the flow-through area and arrangement density of the flow guide through-holes 230a on a flow guide sub-plate 231 are matched with the computing capacity of a server module 30 corresponding to the flow guide sub-plate 231. For example, for a server module 30 with relatively strong computing compacity, the flow-through area of the flow guide through-holes 230a on a corresponding flow guide sub-plate 231 is correspondingly larger and the arrangement density is also correspondingly larger; and for a server module 30 with relatively weak computing compacity, the flow-through area of the flow guide through-holes 230a on a corresponding flow guide sub-plate 231 is correspondingly small and the arrangement density is also correspondingly small. Based on this, the cooling device of the embodiment of the present application can provide appropriate flow guide sub-plates 231 for the server modules 30 with different computing capacity, thereby providing a uniform cooling effect for all the server modules 30, and then improving the compatibility and applicability of the cooling device.

In an implementation, the plurality of server modules 30 are arranged in the first direction perpendicular to the vertical direction, and the plurality of flow guide regions 230b are arranged in the first direction, with the plurality of flow guide regions 230b in a one-to-one correspondence with the plurality of server modules 30.

Exemplarily, the plurality of flow guide regions 230b are disposed in a one-to-one correspondence with the plurality of server modules 30 in the vertical direction. That is, each flow guide region 230b is located directly below a corresponding server module 30. It can be understood that the cooling working medium, after being input into the lower space of the cooling chamber 210a through the flow guide pipe 220, is guided upward to a server module 30 through a corresponding flow guide region 230b of the flow guide plate 230.

Such arrangement can guide to a server module 30 the cooling working medium with a flow rate matching its computing capacity through a flow guide region 230b corresponding to the server module 30, thereby providing targeted cooling for different server modules 30.

In an implementation, the flow guide pipe 220 has a plurality of flow guide segments corresponding to the flow guide regions 230b in the first direction, with a flow-through area and/or arrangement density of the liquid outlet holes 220a included in a flow guide segment positively correlated with the computing capacity of a corresponding server module 30.

In the embodiment of the present application, the plurality of flow guide segments correspond to the plurality of flow guide regions 230b. It is possible that one flow guide segment corresponds to several flow guide regions 230b, or that several flow guide segments correspond to one flow guide region 230b, or that each flow guide segment corresponds to one flow guide region 230b. The server module 30 corresponding to a flow guide segment refers to the server module 30 corresponding to a flow guide region 230b corresponding to any flow guide segment.

Optionally, the plurality of flow guide regions 230b are arranged in the first direction perpendicular to the vertical direction, and the plurality of flow guide segments are arranged in the first direction, with the plurality of flow guide segments in a one-to-one correspondence with the plurality of flow guide regions 230b. Each flow guide segment includes a plurality of liquid outlet holes 220a arranged along the first direction.

It can be understood that each flow guide segment corresponds in one-to-one manner to a respective flow-guiding region 230b, and each flow guide region 230b corresponds in one-to-one manner to a respective server module 30. Thus, each flow guide segment corresponds in one-to-one manner to a respective server module 30, so that each flow guide segment can guide the cooling working medium to a corresponding server module 30 through a corresponding flow guide region 230b. Furthermore, the flow guide segment is disposed directly opposite to the corresponding flow guide region 230b in the vertical direction, and the flow guide region 230b is disposed directly opposite to the corresponding server module 30 in the vertical direction. Thus, the flow guide segment is disposed directly opposite to the corresponding server module 30 in the vertical direction.

For different flow guide segments, a flow-through area and/or arrangement density of the flow guide through-holes 230a included in a flow guide segment may be correspondingly set according to different computing capacity of a corresponding server module 30.

For example, the flow-through area of the liquid outlet holes 220a included in different flow guide segments may be the same, while the arrangement density of the liquid outlet holes 220a included in a flow guide segment is positively correlated with the computing capacity of a server module 30 corresponding to the flow guide segment. For another example, the arrangement density of the liquid outlet holes 220a included in different flow guide segments may be the same, while the flow-through area of the liquid outlet holes 220a included in a flow guide segment is positively correlated with the computing capacity of a server module 30 corresponding to the flow guide segment. For still another example, the flow-through area and arrangement density of the liquid outlet holes 220a included in different flow guide segments are positively correlated with the computing capacity of server modules 30 corresponding to the flow guide segments.

It can be understood that the stronger the computing capacity of a server module 30 corresponding to a flow guide segment, the larger the flow-through area of the liquid outlet holes 220a included in the flow guide segment, and/or the greater the arrangement density of the liquid outlet holes 220a; the weaker the computing capacity of a server module 30 corresponding to a flow guide segment, the smaller the flow-through area of the liquid outlet holes 220a in the flow guide segment, and/or the smaller the arrangement density of the liquid outlet holes 220a.

It should be noted that the flow-through area and arrangement density of the liquid outlet holes 220a included in the flow guide segments can directly affect the flow rate of the cooling working medium flowing to the server modules 30 through the flow guide segments per unit time. The larger the flow-through area of the liquid outlet holes 220a included in a flow guide segment, the greater the flow rate of the cooling working medium flowing to a corresponding server module 30 through the flow guide segment per unit time; conversely, the smaller the flow rate of the cooling working medium flowing to the corresponding server module 30 through the flow guide segment per unit time. The greater the arrangement density of the liquid outlet holes 220a included in a flow guide segment, the greater the flow rate of the cooling working medium flowing to a corresponding server module 30 through the flow guide segment per unit time; conversely, the smaller the flow rate of the cooling working medium flowing to the corresponding server module 30 through the flow guide segment per unit time. It can be understood that the greater the flow rate of the cooling working medium flowing through a flow guide segment to a corresponding server module 30 per unit time, the higher the cooling efficiency of the server module 30; conversely, the lower the cooling efficiency of the server module 30.

Thus, with the above implementation, the flow-through area and/or arrangement density of the flow guide through-holes 230a included in the flow guide segments corresponding to the server modules 30 are correspondingly set according to different computing capacity of the server modules 30, with the flow-through area and/or arrangement density of the flow guide through-holes 230a positively correlated with the computing capacity of the corresponding server modules 30. Thus, for a server module 30 with relatively strong computing capacity, a larger flow rate can be provided for the cooling working medium directed to the server module 30 through a corresponding flow guide segment, while for a server module 30 with relatively weak computing capacity, a smaller flow rate can be provided for the cooling medium directed to the server module 30 through a corresponding flow guide segment, thereby further enhancing the uniformity of cooling for the server modules 30 with different computing capacity and being conducive to further enhancing the evenness of the temperature of the cooling working medium in the cooling chamber 210a.

In an implementation, as shown in FIG. 6, the cooling apparatus 20 further includes a plurality of baffles 240. The plurality of baffles 240 are provided in the cooling chamber 210a and located below the flow guide plate 230, the plurality of baffles 240 being disposed corresponding to the plurality of flow guide segments of the flow guide pipe 220, and the baffles 240 being located in a liquid outlet direction of the liquid outlet holes 220a included in the corresponding flow guide segments.

Exemplarily, the baffles 240 may be fixed to a lower side surface of the flow guide plate 230, or may be fixed to a bottom wall of the cooling chamber 210a, which is not specifically limited in the embodiments of the present application. Each flow guide segment may correspond to at least one baffle 240, and the baffle 240 is located in the liquid outlet direction of the liquid outlet holes 220a included in the flow guide segment, so as to block the cooling working medium output from the liquid outlet holes 220a.

In one example, each flow guide segment of the flow guide pipe 220 includes a respective set of liquid outlet holes 220a, and a plurality of liquid outlet holes 220a in the set are arranged at intervals along the first direction. Each flow guide segment corresponds to a respective baffle 240 which is located in the liquid outlet direction of all liquid outlet holes 220a in the set of liquid outlet holes 220a, so that the baffle 240 can play a role in blocking the cooling working medium output from all liquid outlet holes 220a in the set of liquid outlet holes 220a.

In another example, each flow guide segment of the flow guide pipe 220 includes two sets of liquid outlet holes 220a, with a plurality of liquid outlet holes 220a in each set distributed at intervals along the first direction, and the two sets of liquid outlet holes 220a symmetrically distributed about a central axis of the flow guide pipe 220. Each flow guide segment corresponds to two respective baffles 240 which are in a one-to-one correspondence with two sets of liquid outlet holes 220a included in the flow guide segment, with each baffle 240 located in the liquid outlet direction of all liquid outlet holes 220a in a corresponding set of liquid outlet holes 220a.

It should be noted that a flow direction of the cooling working medium in the flow guide pipe 220 is an axial direction of the flow guide pipe 220, and a velocity of the cooling working medium when it flows out through the liquid outlet holes 220a includes both a velocity component along the axial direction of the flow guide pipe 220 and a velocity component along a radial direction of the flow guide pipe 220. Therefore, an included angle between the liquid outlet direction of the liquid outlet holes 220a and the axial direction of the flow guide pipe 220 is an acute angle.

The baffles 240 are located in the liquid outlet direction of the liquid outlet holes 220a included in the flow guide segments, which means that a plane where the baffles 240 are located forms a certain included angle with the liquid outlet direction of the liquid outlet holes 220a, so that the baffles 240 can play a certain role in blocking the cooling working medium output from the liquid outlet holes 220a. Specifically, the included angle between the plane where the baffles 240 are located and the liquid outlet direction of the liquid outlet holes 220a may be from 0° to 45°.

According to the above implementation, by disposing the baffles 240 corresponding to the flow guide segments, and locating the baffles 240 in the liquid outlet direction of the liquid outlet holes 220a included in the flow guide segments, the baffles 240 can play a certain role in blocking the cooling working medium flowing out of the liquid outlet holes 220a, thereby avoiding the cooling working medium from forming turbulence in the cooling chamber 210a due to an impact of the component velocity along the axial direction of the flow guide pipe 220, and then enhancing the flow uniformity of the cooling working medium in the cooling chamber 210a.

Optionally, the included angle between the plane where the baffles 240 are located and a flow guide direction of the flow guide pipe 220 is from 30° to 60°.

In the embodiment of the present application, the flow guide direction of the flow guide pipe 220 refers to a flow direction of the cooling working medium in the flow guide pipe 220, and the flow direction of the cooling working medium in the flow guide pipe 220 is parallel to the axial direction of the flow guide pipe 220.

Exemplarily, the axial direction of the flow guide pipe 220 is disposed along the first direction. The plane where the baffles 240 are located is disposed perpendicular to a horizontal plane, and the included angle between the plane where the baffles 240 are located and the flow guide direction of the flow guide pipe 220 is from 30° to 60°. Preferably, the included angle between the plane where the baffles 240 are located and the flow guide direction of the flow guide pipe 220 is from 40° to 50°. More preferably, the included angle between the plane where the baffles 240 are located and the flow guide direction of the flow guide pipe 220 is 45°.

In a specific example, the liquid inlet end of the flow guide pipe 220 is provided at a middle position of the flow guide pipe 220. After the cooling working medium enters the flow guide pipe 220 from the liquid inlet end, it is shunted into a first branch and a second branch. A flow direction of the first branch is a direction from the middle position of the flow guide pipe 220 to a first end portion (i.e., the direction to the left in the figure), and a flow direction of the other branch is a direction from the middle position of the flow guide pipe 220 to a second end portion (i.e., the direction to the right in the figure). The flow guide pipe 220 includes a plurality of flow guide segments, each having two sets of flow guide through-holes 230a symmetrically distributed in the second direction. Each flow guide segment corresponds to two respective baffles 240, and the two baffles 240 correspond in a one-to-one manner to two respective sets of flow guide through-holes 230a of the flow guide segment. It includes first and second flow guide segments on the first branch, and third and fourth flow guide segments on the second branch. A first flow guide direction corresponding to the first and second flow guide segments is the flow direction of the first branch (i.e., the direction to the left in the figure), and a second flow guide direction corresponding to the third and fourth flow guide segments is the flow direction of the second branch (i.e., the direction to the right in the figure).

An included angle between the plane where the baffles 240 corresponding to the first and second flow guide segments are located and the first flow guide direction is 45°, and an included angle between the plane where the baffles 240 corresponding to the third and fourth flow guide segments are located and the second flow guide direction is 45°.

Optionally, the baffle 240 is provided with a flow guide via-hole 240a for making two sub-liquid inlet chambers adjacent to the baffle 240 in communication.

In one example, a plurality of flow guide via-holes 240a may be provided, which are arranged at intervals on the baffle 240.

In another example, lower side edges of the baffles 240 abut against the bottom wall of the cooling chamber 210a, and the plurality of baffles 240 partition a space of the cooling chamber 210a located below the flow guide plate 230 into a plurality of sub-liquid inlet chambers; wherein the lower side edges of the baffles 240 are provided with flow guide via-holes 240a, through which adjacent sub-liquid inlet chambers are in communication.

In the embodiment of the present application, the flow guide via-holes 240a may be arbitrarily shaped and sized according to actual situations. The shape of the flow guide via-holes 240a may be triangle, square, are, sawtooth or any other shapes, which is not specifically limited in the embodiments of the present application. The flow guide via-holes 240a may be correspondingly sized according to the overall computing capacity of all server modules 30. For example, if the overall computing capacity of all server modules 30 is stronger, the flow rate requirement for the cooling working medium is higher, and thus the size of the flow guide via-holes 240a may be set to be larger; conversely, the size of the flow guide via-holes 240a may be set to be smaller.

In an implementation, as shown in FIG. 9, the cooling apparatus 20 further includes a partition plate 250. The partition plate 250 is provided in the inside of the housing 210 along the vertical direction to partition the inside of the housing 210 into the cooling chamber 210a and a liquid outlet chamber 210b, which are in communication at upper portions thereof.

Exemplarily, the top of the housing 210 is provided with a cover plate 211 for opening or enclosing an internal space of the housing 210. The housing 210 is provided with a liquid outlet which makes the liquid outlet chamber 210b in communication with an outside space, and the cooling working medium in the liquid outlet chamber 210b may be discharged through the liquid outlet pipe 251 connected with the cold source device. It can be understood that the cooling working medium absorbs heat generated by the server modules 30 in the cooling chamber 210a and then heats up, and the high-temperature cooling working medium enters the liquid outlet chamber 210b from the cooling chamber 210a and then enters the cold source device through the liquid outlet. After the high-temperature cooling working medium is cooled by the cold source device, the low-temperature cooling working medium flows back to the cooling chamber 210a through the flow guide pipe 220, so as to implement circulation.

It can be understood that since the cooling chamber 210a and the liquid outlet chamber 210b are in communication at the upper portions, when a liquid level of the cooling working medium in the cooling chamber 210a exceeds an upper side edge of the partition plate 250, the cooling working medium may flow from the cooling chamber 210a into the liquid outlet chamber 210b.

Optionally, the partition plate 250 includes a first plate body fixedly connected to the housing 210, and a second plate body slidable in the vertical direction relative to the first plate body, an upper side edge of the second plate body being located above an upper side edge of the first plate body.

The embodiments of the present application do not specifically limit the sliding connection manner between the first plate body and the second plate body, and any connection manner known to those skilled in the art may be employed. By way of example, the first plate body may be provided with a sliding slot extending along the vertical direction, and the second plate body may be provided with a sliding fit portion. With the sliding fit between the sliding fit portion and the sliding slot, the sliding connection between the second plate body and the first plate body is implemented.

With the above implementation, a height of the partition plate 250 may be adjusted according to a height of the server module 30 to ensure that a position of the upper side edge of the partition plate 250 is not lower than a position of an upper side edge of the server module 30 in the vertical direction, thereby ensuring that the cooling working medium in the cooling chamber 210a can immerse the server module 30. Such arrangement improves the compatibility of the cooling apparatus 20 with the server modules 30 of different heights, thereby extending the applicability of the cooling apparatus 20.

In an implementation, a cross-sectional shape of the flow guide pipe 220 is circular, square, or triangular; and/or, a shape of the liquid outlet holes 220a is circular, square, or triangular.

It should be noted that the cross-sectional shape and size of the flow guide pipe 220 and the shape and size of the liquid outlet holes 220a may be arbitrarily set by those skilled in the art according to actual situations. In addition to the circular, square, or triangular shapes listed in the above implementation, the cross-sectional shape of the flow guide pipe 220 and the shape of the liquid outlet holes 220a may also be any other regular or irregular shapes.

In an implementation, the plurality of server modules 30 are arranged adjacently in the first direction perpendicular to the vertical direction, each including at least two columns of servers 301 arranged adjacently in the second direction perpendicular to the first direction, each column of servers 301 including at least one server 301 arranged along the first direction; and the flow guide pipe 220 is disposed axially parallel to the first direction.

Exemplarily, the plurality of server modules 30 are arranged adjacently along the first direction, each including a plurality of servers 301 arranged in an array, the plurality of servers 301 being arranged in at least one row in the first direction, each row including at least one server 301 arranged along the second direction; and the plurality of servers 301 being arranged in at least two columns in the second direction, each column including at least two servers 301 arranged along the first direction. The axial direction of the flow guide pipe 220 is disposed along the first direction, and the flow guide pipe 220 has a plurality of flow guide segments in the first direction, each guiding the cooling working medium for a corresponding server module 30.

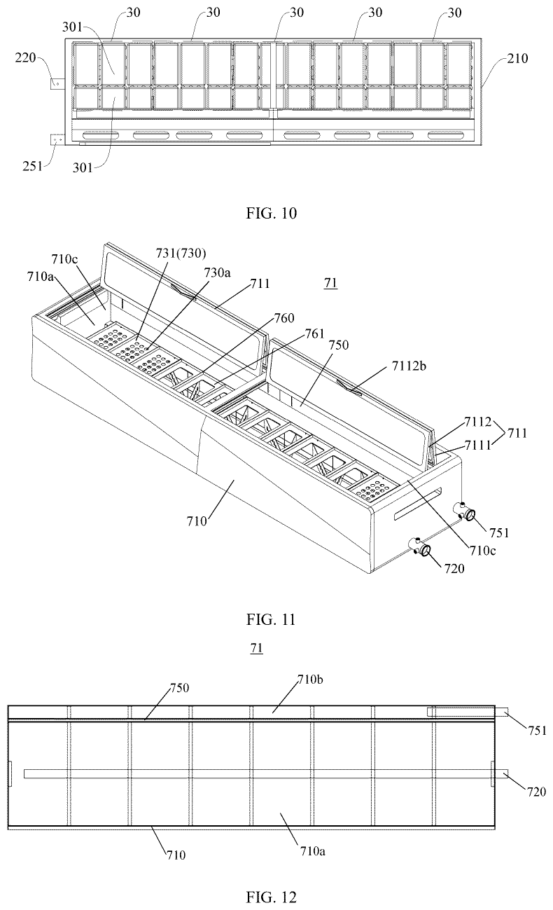

In a specific example, as shown in FIG. 10, the number of server modules 30 is five, which are arranged at intervals along the first direction. Each server module 30 includes three rows of servers arranged in the first direction, each row including two servers 301 arranged along the second direction.

In the embodiment of the present application, there may be one or more flow guide pipes 220 disposed along the first direction. In the case of a plurality of flow guide pipes 220, the plurality of flow guide pipes 220 may be arranged parallel to each other and at equal intervals in the second direction.

Optionally, each server module 30 includes N columns of servers 301 arranged in the second direction, where N is a positive integer greater than or equal to 2; the number of flow guide pipes 220 is N−1; wherein any two adjacent columns of servers 301 correspond to one flow guide pipe 220.

Exemplarily, the flow guide pipe 220 is centered relative to two columns of servers 301 corresponding thereto in the second direction. Each flow guide segment of the flow guide pipe 220 has two respective sets of liquid inlet holes disposed oppositely in the second direction, with a set of liquid inlet holes disposed corresponding to a column of the two columns of servers 301 in the server module 30 corresponding to the flow guide segment, and the other set of liquid inlet holes disposed corresponding to the other column of the two columns of servers 301 in the server module 30 corresponding to the flow guide segment.

Such arrangement enables a more rational distribution of the flow guide pipes 220 relative to the plurality of server modules 30 in the cooling chamber 210a, resulting in a more uniform allocation of the cooling working medium in the cooling chamber 210a and further enhancing the temperature evenness of the cooling working medium.

In an implementation, as shown in FIG. 2, the liquid-cooled data center 1 further includes an enclosure 40. At least one cooling apparatus 20 is integrally deployed inside the enclosure 40; alternatively, at least one cooling apparatus 20 and at least one cold source device 10 are integrally deployed inside the enclosure 40.

In the embodiment of the present application, the cooling apparatus 20 is integrally disposed into a corresponding computing device. By integrally deploying a plurality of cooling apparatuses 20 inside the enclosure 40, this is conducive to integral deployment of a plurality of computing devices inside the enclosure 40, thereby enhancing the integration of the data center.

Exemplarily, the plurality of cooling apparatuses 20 may be deployed inside the enclosure 40, and a plurality of cold source devices 10 may be deployed outside the enclosure 40. Alternatively, the plurality of cooling apparatuses 20 and the plurality of cold source devices 10 may be jointly deployed inside the enclosure 40, which is not specifically limited in the embodiments of the present application.

According to the above implementation, by utilizing the enclosure 40 to integrally deploy the at least one cooling apparatus 20 or the at least one cooling apparatus 20 and the cold source device 10, the integrated arrangement of a plurality of cold source devices 10 and a plurality of cooling apparatuses 20 is implemented, which improves the integration of the liquid-cooled data center 1 and achieves the integrated transportation and on-site use of the liquid-cooled data center 1 without secondary installation, which is conducive to achieving the modular delivery of the data center.

Optionally, the enclosure 40 includes a first container body 401 and a second container body 402, with at least one liquid-cooled device 20 integrally deployed inside the first container body 401 and at least one cold source device 10 integrally deployed inside the second container body 402.

In the embodiment of the present application, the first container body 401 may be arbitrarily shaped and sized by those skilled in the art according to actual situations. To facilitate transportation, preferably, the first container body 401 may be correspondingly shaped and sized with reference to a standard container, which, for example, may have the same shape and size as 20-foot, 40-foot, or 45-foot standard containers.

In a specific example, the computing device enclosure may be correspondingly shaped and sized with reference to a standard 40-foot container, with overall external dimensions of 12.192 m×2.438 m×2.438 m. Thus, after the cooling apparatus 20 is integrally deployed inside the first container body 401, the first container body 401 can be loaded and transported directly by marine or land transportation or other means, without secondary assembly after transportation, thereby improving the convenience of transportation and delivery.

In the embodiment of the present application, the second container body 402 may be correspondingly shaped and sized with reference to the first container body 401. For ease of transportation, preferably, the second container body 402 may likewise be correspondingly provided with reference to the specification of a standard container, which, for example, may have the same shape and size as marine or land freight containers of 20-foot, 40-foot, or 45-foot specification.

In a specific example, the shape and size of both the first container body 401 and the second container body 402 may be referenced to a 40-foot marine or land freight container, with overall external dimensions of 12.192 m×2.438 m×2.438 m. Thus, after the cooling apparatus 20 is integrally deployed inside the first container body 401 and the cold source device 10 is integrally deployed inside the second container body 402, the first container body 401 and the second container body 402 can be loaded and transported directly by marine or land transportation or other means, which improves the transportation convenience of the liquid-cooled data center 1.

According to the above implementation, by providing the first container body 401 and the second container body 402, the modular arrangement of a plurality of cooling apparatuses 20 and a plurality of cold source devices 10 can be implemented to improve the convenience of transportation and delivery of the data center.

In the embodiment of the present application, the first container body 401 and the second container body 402 are integrally disposed. For example, the first container body 401 and the second container body 402 may be adjacent and fixedly connected in the vertical or horizontal direction to achieve the integrated arrangement of the first container body 401 and the second container body 402.

In other embodiments of the present application, the first container body 401 and the second container body 402 are detachably connected.

In an implementation, the first container body 401 and the second container body 402 are detachably connected in the horizontal direction.

It can be understood that the first container body 401 and the second container body 402, when in a separate state, may be loaded and transported separately. The first container body 401 and the second container body 402, when in a connected state, may be disposed side by side and adjoin each other in the horizontal direction to achieve the integrated deployment of the first container body 401 and the second container body 402.

In an implementation, an interlocking structure is provided between adjoining top walls and/or side walls of the first container body 401 and the second container body 402.

In one example, the first container body 401 and the second container body 402 each include corner fittings. The corner fittings are located at eight corner positions of the first container body 401 and the second container body 402. The interlocking structure is connected by the corner fittings of the first container body 401 and the second container body 402. Exemplarily, the interlocking structure may be a general-purpose interlocking structure used for splicing and fixing standard containers, which is not limited in the present application. By using the interlocking structure to fixedly connect the first container body 401 and the second container body 402, displacement between the first container body 401 and the second container body 402 can be avoided during installation, ensuring the stability of the data center employing the first container body 401 and the second container body 402.

In one example, the first container body 401 has a first side wall, and the second container body 402 has a second side wall, with the first side wall abutted against the second side wall. The interlocking structure includes a first interlocking member provided on a first side wall of the first container body 401, and a second interlocking member provided on a second side wall of the second container body 402, with the first interlocking member and the second interlocking member engaged and fixedly connected by fasteners.

In another example, the first interlocking member and the second interlocking member are respectively provided on the top walls of the first container body 401 and the second container body 402. The first interlocking member may extend toward a side of the second container body 402, so that the first interlocking member and the second interlocking member are correspondingly disposed and thereby fixedly connected by fasteners. In addition, the second interlocking member may also extend toward a side of the first container body 401, so that the first interlocking member and the second interlocking member are correspondingly disposed and thereby fixedly connected by fasteners.

In an implementation, the first container body 401 and the second container body 402 are detachably connected in the vertical direction.

It can be understood that the first container body 401 and the second container body 402, when in a separate state, may be loaded and transported separately. The first container body 401 and the second container body 402, when in a connected state, may be disposed in a stacked manner in the vertical direction to achieve the integrated deployment of the first container body 401 and the second container body 402. Such arrangement can save space, enabling more container data centers to be arranged in the same space.

In the embodiment of the present application, when the first container body 401 and the second container body 402 are in a connected state, the first container body 401 may be located above or below the second container body 402.

In an implementation, an upper side of the first container body 401 is provided with a first mounting fit member, and a lower side of the second container body 402 is provided with a second mounting fit member, the first mounting fit member and the second mounting fit member being connected by interlocking.

Exemplarily, the first mounting fit member may be an interlocking aperture, and the second mounting fit member may be an interlocking projection that extends downwardly, the interlocking projection being positioned corresponding to the interlocking aperture to form an interlocking fit.

In addition, corresponding multiple sets of interlocking apertures and interlocking projections may also be provided, which are arranged at intervals in the horizontal direction, so as to improve the stability of connection between the first container body 401 and the second container body 402.

Optionally, the first mounting fit member and the second mounting fit member are fixedly connected by fasteners.

Exemplarily, the first and second mounting fit members are respectively provided with fastening through-holes, and in a case where the first and second mounting fit members form an interlocking fit, the two fastening through-holes correspond to each other, so that the fasteners can pass through the fastening through-holes on the first and second mounting fit members in sequence.

Such arrangement can further improve the stability and reliability of connection between the first container body 401 and the second container body 402.

It should be noted that the first and second mounting fit members mentioned above are merely examples, which are not limited in the present application as long as they can implement a fixed connection between the first container body 401 and the second container body 402.

In an implementation, a ladder is provided between bottom and top ends of the second container body 402.

Exemplarily, the ladder is provided between top and bottom beam frames of the second container body 402. An upper end of the ladder is detachably connected to the top beam frame, so that the ladder can be carried to a corresponding position according to actual needs, thereby allowing the staff to climb to inspect the cold source device 10.

In an implementation, the first container body 401 defines an enclosed cavity, and the second container body 402 employs a framework structure to define an open cavity.

Exemplarily, the second container body 402 may include a plurality of beam bodies connected to each other to define an open container body 40. The plurality of beam bodies include connecting beams and supporting beams. A plurality of connecting beams are connected to each other to form a main frame of the second container body 402, and a plurality of supporting beams are connected between the connecting beams to provide support and improve the structural stability of the main frame. It can be understood that the second container body 402 is formed by connecting the plurality of beam body structures, which increases a communication region between the inside and outside of the open cavity, thereby enabling the plurality of cold source devices 10 integrally deployed inside the second container body 402 to dissipate heat in a timely manner and improving the heat exchange efficiency of the cold source devices 10.

In an implementation, the first container body is provided with a pipeline window for allowing a cooling pipeline to pass through to connect the cold source device in the second container body with the liquid-cooled device in the first container body.

It can be understood that the second container body defines an open cavity through the beam body structures, and the cooling pipeline connected to the cold source device in the open cavity can extend through an interspace among the beam body structures of the second container body and then connect with the liquid cooling device in the first container body through the pipeline window.

Exemplarily, the pipeline window may be provided on a side wall of the first container body and disposed corresponding to a power module arranged in the first container body, so as to improve the convenience of connection between the cooling pipeline and the power module.

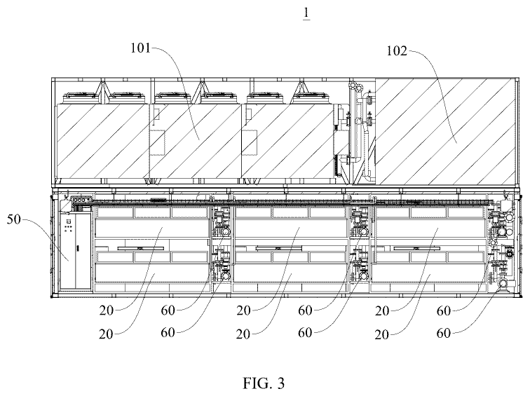

Optionally, as shown in FIG. 3, the liquid-cooled data center 1 further includes a power distribution module 50 and/or a power module 60. The power distribution module 50 is used for providing electrical power to the cooling apparatus 20 and the cold source device 10, and the power module 60 is used for providing power to the cooling working medium in the circulation flow path between the cooling apparatus 20 and the cold source device 10. The power distribution module 50 and the power module are integrally deployed inside the first container body 401.

In an implementation, the power distribution module 50 and the power module 60 are respectively disposed close to two opposite sides within the first container body 401.

Exemplarily, the computing devices may be arranged in rows along a length direction of the first container body 401 to form a computing device row. The power distribution module 50 and the power module 60 are respectively provided on two sides of the computing device row in the length direction of the first container body 401. Such arrangement enables water-electricity isolation in the physical space, thereby improving the power consumption safety of the liquid-cooled data center 1.

Other constructions of the liquid-cooled data center 1 of the above embodiment may employ various technical solutions known to those skilled in the art now and in the future, which will not be described in detail here.

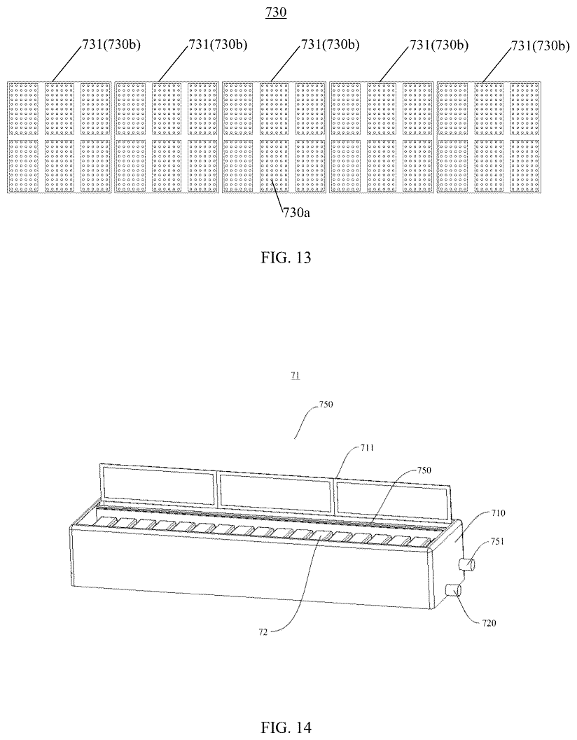

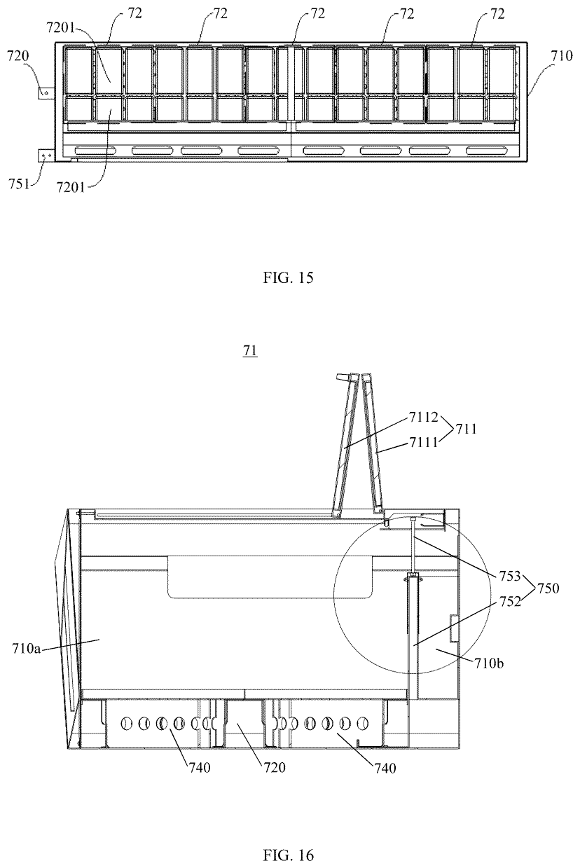

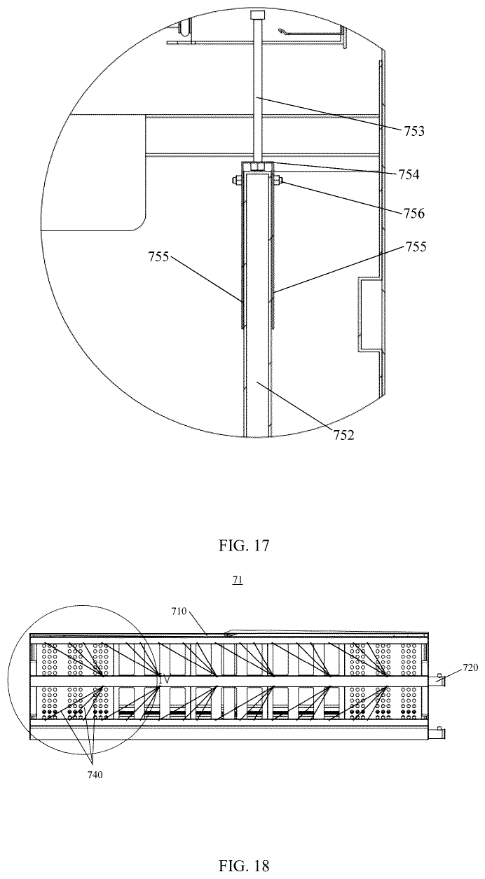

As a second aspect of the embodiments of the present application, a cooling apparatus 71 according to an embodiment of the present application will be described below with reference to FIGS. 11 to 19.

The cooling apparatus 71 includes: a housing 710 defining a cooling chamber 710a inside for mounting a server module 72; and a liquid supply pipe 720 disposed in the cooling chamber 710a for providing a cooling working medium to the cooling chamber.

A pipe wall of the liquid supply pipe 720 is provided with a plurality of liquid outlet holes 720a for inputting the cooling working medium to the cooling chamber. The liquid outlet holes 720a are arranged along a length direction of the liquid supply pipe 720 for evenly providing the cooling working medium to regions of the cooling chamber in the length direction.

A support member is provided above the liquid supply pipe 720 for mounting the server module 72. The support member may be a flow guide plate 730. When the liquid supply pipe 720 provides the cooling working medium, the cooling working medium flows from bottom to top to cool and dissipate heat from the server module on the support member. The support member itself or the outer periphery is provided with a channel for allowing the cooling working medium to flow through.

A baffle 740 is located in a liquid outlet direction of the liquid supply pipe 720 and provided below the server module 72. A support portion may be provided on an upper portion of the baffle 740 for arranging the server module 72. A plurality of baffles 740 may be provided following the length direction of the liquid supply pipe, with a cooling working medium flow region formed between adjacent baffles 740, so that the liquid supply pipe 720 discharges liquid to the cooling working medium flow region, and the server module 72 is arranged above the cooling working medium flow region.

A partition plate 750 is provided in the inside of the housing 710 along the vertical direction to partition the inside of the housing 710 into the cooling chamber and a liquid outlet chamber, which are in communication at upper portions thereof.

As shown in FIGS. 11 to 13, the cooling apparatus 71 includes a housing 710, a liquid supply pipe 720, and a flow guide plate 730. Specifically, the inside of the housing 710 defines a cooling chamber 710a. The liquid supply pipe 720 is provided in the cooling chamber 710a, and a pipe wall of the liquid supply pipe 720 is provided with a plurality of liquid outlet holes 720a for inputting the cooling working medium to the cooling chamber 710a. The flow guide plate 730 is provided in the cooling chamber 710a and located above the liquid supply pipe 720, and the flow guide plate 730 is provided with a plurality of flow guide through-holes 730a which make upper and lower sides of the flow guide plate 730 in communication. The cooling chamber 710a accommodates a plurality of server modules 72 located on the upper side of the flow guide plate 730, the flow guide plate 730 has a plurality of flow guide regions 730b corresponding to the plurality of server modules 72, and a flow-through area and/or arrangement density of the flow guide through-holes 730a in a flow guide region 730b are positively correlated with the computing capacity of a corresponding server module 72.

Exemplarily, a flow-through area of the flow guide through-holes 730a in a flow guide region 730b may be a sum of areas of all the flow guide through-holes 730a in the flow guide region 730b. Alternatively, it may be a sum of areas of all the flow guide through-holes 730a on a flow guide sub-plate corresponding to the flow guide region 730b.

Exemplarily, an arrangement density of the flow guide through-holes 730a in a flow guide region 730b may be a ratio of a sum of aeras of all the flow guide through-holes 730a in the flow guide region 730b to a total area of the flow guide region 730b. Alternatively, it may be a ratio of a sum of areas of all the flow guide through-holes 730a on a flow guide sub-plate corresponding to the flow guide region 730b to a total area of the flow guide sub-plate.

In the embodiment of the present application, the cooling apparatus 71 may be used for cooling the server module 72, specifically for cooling a plurality of server modules 72 simultaneously. Each server module 72 may include at least one server 7201 with the same computing capacity, and the computing capacity corresponding to the servers 7201 in different server modules 72 may be the same or different.

In other examples of the present application, each flow guide sub-plate 731 may also correspond to a plurality of server modules 72 having the same computing capacity. The plurality of flow guide through-holes 730a on the flow guide sub-plate 731 are evenly distributed, and the arrangement density of the plurality of flow guide through-holes 730a is correspondingly set according to the computing capacity of the plurality of server modules 72.

Optionally, as shown in FIG. 11, the cooling apparatus 71 further includes a holder 760 provided in the cooling chamber 710a. Atop of the holder 760 is provided with a plurality of recesses 761 for bearing the flow guide sub-plate 731.

Exemplarily, the plurality of recesses 761 are adapted to be disposed at intervals in the length direction of the housing 710, each provided with a clearance through-hole that penetrates in the vertical direction. A plurality of flow guide sub-plates 731 are provided in one-to-one correspondence with the plurality of recesses 761, each flow guide sub-plate 731 being borne on a corresponding recess 761.

Exemplarily, a flow-through area of the liquid outlet holes 720a included in a flow guide segment may be a sum of areas of all the liquid outlet holes 720a in the flow guide segment.

Exemplarily, an arrangement density of the liquid outlet holes 720a included in a flow guide segment may be a ratio of a sum of areas of all the liquid outlet holes 720a in the flow guide segment to a total area of the flow guide segment.

Exemplarily, an upper edge of the baffle 740 corresponds to a lower surface of the flow guide plate 730, a lower edge of the baffle 740 corresponds to a bottom face of the housing, and side edges of the baffle 740 correspond to inner walls of the housing, thereby dividing two sides of two surfaces of the baffle 740 into two regions.

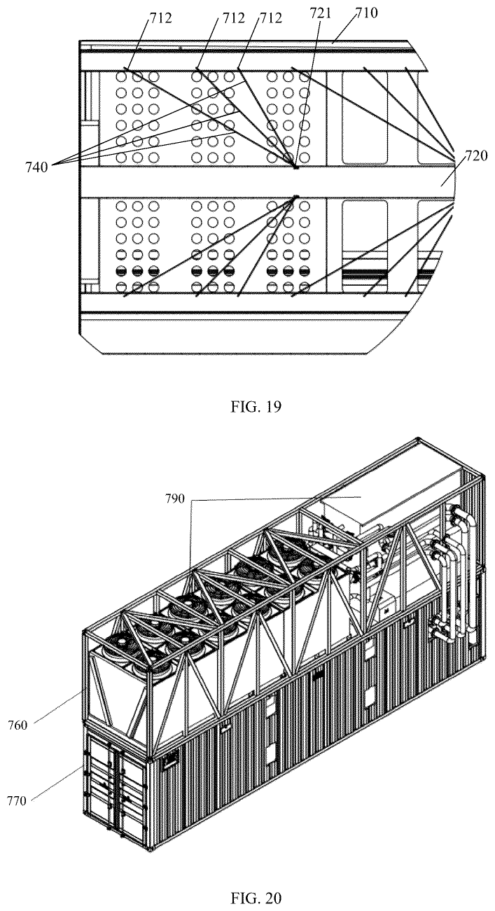

Optionally, as shown in FIGS. 18 and 19, a wall body of the liquid supply pipe 720 is provided with a first slot 721, and an inner side wall of the housing 710 is provided with a second slot 712, the two side edges of the baffle 740 are respectively inserted into the first slot 721 and the second slot 712.

Exemplarily, a plurality of first slots 721 are provided, which are disposed at intervals along an axial direction of the liquid supply pipe 720, and a plurality of second slots 712 are provided corresponding to the plurality of first slots 721. The first slots 721 and the second slots 712 both extend along the vertical direction, so that the baffle 740 inserted in the first slots 721 and the second slots 712 is disposed vertically.

The first slot 721 is formed by inwardly recessing the wall body of the liquid supply pipe 720, or the first slot 721 is a slot structure mounted on the liquid supply pipe 720 or a slot structure mounted at the bottom of the housing and adjoining the wall body of the liquid supply pipe 720. The above are merely illustrative examples, and the present application does not limit the specific form of the first slot.

The second slot 712 is formed by inwardly recessing the inner side wall of the housing 710, or the second slot 712 is a slot structure mounted on the inner wall of the housing 710 or a slot structure mounted at the bottom of the housing and adjoining the inner wall of the housing 710. The above are merely illustrative examples, and the present application does not limit the specific form of the second slot.

The first slots 721 and the second slots 712 are disposed at intervals in the axial direction of the liquid supply pipe 720, so that the baffle 740 engaged with the first slots 721 and the second slots 712 is disposed inclinedly relative to the axial direction of the liquid supply pipe 720.

Further, a plurality of second slots 712 are provided, which are disposed at intervals along a direction parallel to the axial direction of the liquid supply pipe 720, and a side edge of the baffle 740 is inserted into any one of the plurality of second slots 712.

Exemplarily, the second slots 712 are provided in multiple sets respectively corresponding to the plurality of first slots 721, each set including a plurality of slots disposed at intervals along a direction parallel to the axial direction of the liquid supply pipe 720. It can be understood that a side edge of the baffle 740 may be inserted into a corresponding first slot 721, and the other side edge of the baffle 740 is adapted to be inserted into any one of a corresponding set of second slots 712.

By providing the plurality of second slots 712 corresponding to the first slots 721, a side edge of the baffle 740 can be selectively inserted into any one of the second slots 712 according to actual situations, thereby adjusting the included angle between the baffle 740 and the flow guide direction of the liquid supply pipe 720, and then adaptably improving the blocking effect of the baffle 740 on the cooling working medium flowing out of the liquid outlet holes 720a.

In a specific example, each first slot 721 corresponds to three respective second slots 712 that are disposed at intervals along the direction parallel to the axial direction of the liquid supply pipe 720. When the baffles 740 are inserted into the three second slots 712 respectively, included angles between planes where the baffles 740 are located and the flow guide direction of the liquid supply pipe 720 are 30°, 45°, and 60°, respectively.

In one example, one partition plate 750 is disposed along the vertical direction to define one cooling chamber 710a and one liquid outlet chamber 710b inside the housing 710, with the cooling chamber 710a and the liquid outlet chamber 710b disposed side by side in the horizontal direction.

In another example, two partition plates 750 are disposed apart to divide the inside of the housing 710 into two liquid outlet chambers 710b and one cooling chamber 710a in the horizontal direction, with the cooling chamber 710a located between the two liquid outlet chambers 710b. The two liquid outlet chambers 710b are each provided with a liquid outlet pipe 751 to direct the cooling working medium out of the cooling chamber 710a.

In still another example, two partition plates 750 are spaced part to divide the inside of the housing 710 into two cooling chambers 710a and one liquid outlet chamber 710b in the horizontal direction, with the liquid outlet chamber 710b located between the two cooling chambers 710a. The two cooling chambers 710a are both provided with a flow guide plate 730 and a liquid supply pipe 720, the flow guide plate 730 bearing at least one server module 72.

Optionally, a lower end of the second plate body 753 is provided with a sliding fit member 754, and a part of the first plate body 752 is slidably fitted inside the sliding fit member 754.

Exemplarily, a sliding slot is defined within the sliding fit member 754 and extends in the vertical direction. The sliding fit member 754 may be fixed to the lower end of the second plate body 753 by fasteners. A part of the first plate body 752 close to an upper end thereof is located in the sliding slot and is movable relative to the sliding slot along the vertical direction, so that the first plate body 752 and the second plate body 753 are slidable relative to each other in the vertical direction.

Optionally, the sliding fit member 754 includes two oppositely disposed side retaining walls 755, with the sliding slot defined between the two side retaining walls 755.

Exemplarily, the two side retaining walls 755 are disposed oppositely in a thickness direction of the first plate body 752, and a distance between the two side retaining walls 755 is greater than or equal to a thickness of the first plate body 752. The sliding slot is defined between the two side retaining walls 755, and the part of the first plate body 752 close to the upper portion is adapted to protrude into the inside of the sliding slot through an opening at the bottom of the sliding slot.

Optionally, the side retaining walls 755 are provided with positioning holes for allowing a positioning member 756 to pass through, so as to adjust a spacing between the two side retaining walls 755.

Exemplarily, the positioning holes on the two side retaining walls 755 are disposed directly opposite to each other in the thickness direction of the first plate body 752. The positioning member 756 may be a bolt that passes through the positioning holes on the two side retaining walls 755. Two ends of the bolt are threadedly fitted with nuts. The spacing between the two side retaining walls 755 is adjusted by screwing positions of the two nuts on the bolt, so that the two side retaining walls 755 are pressed against two side surfaces of the first plate body 752, thereby implementing fixing between the first plate body 752 and the second plate body 753; or so that the two side retaining walls 755 are separated from the two side surfaces of the first plate body 752, thereby implementing relative movement between the first plate body 752 and the second plate body 753, thereby adjusting a height of the partition plate 750.

In an implementation, as shown in FIGS. 11 and 16, the cooling apparatus 71 of the embodiment of the present application further includes a cover plate 711, which is movably provided on the top of the housing 710 for opening or closing an opening 710c on the top of the housing 710.

In the embodiment of the present application, a manner of connection between the cover plate 711 and the housing 710 may be sliding connection, or may be rotating connection, which is not specifically limited here in the embodiments of the present application as long as the cover plate 711 can move relative to the housing 710, thereby enabling the cover plate 711 to open or close the opening 710c at the top of the housing 710.

Optionally, a plurality of openings 710c are disposed at intervals, and a plurality of cover plates 711 are provided in a one-to-one correspondence with the plurality of openings 710c.

Exemplarily, there may be a plurality of openings 710c disposed at intervals in the first direction, each provided with a corresponding cover plate 711 to open or close the corresponding opening 710c. By way of example, the top of the housing 710 may have two openings 710c disposed side by side in its length direction, each provided with a corresponding cover plate 711.

Optionally, the cover plate 711 includes a first sub-cover plate 7111 and a second sub-cover plate 7112, which are rotatably connected.

Exemplarily, a side edge of the first sub-cover plate 7111 extending along the first direction is rotatably connected to a side edge of the opening 710c extending along the first direction. The other side edge of the first sub-cover plate 7111 extending along the first direction is rotatably connected to a side edge of the second sub-cover plate 7112 extending along the first direction. Two side edges of the opening 710c extending along the second direction are respectively provided with guide rails 713 extending along the second direction, and two ends of the other side edge of the second sub-cover plate 7112 extending along the first direction are respectively provided with sliding shafts 7112a fitted to the guide rails 713, the sliding shafts 7112a being slidable and rotatable along the guide rails 713. Thus, the first sub-cover plate 7111 and the second sub-cover plate 7112 can be in linkage, and the opening 710c on the top of the housing 710 is opened or closed by means of rotation and sliding of the second sub-cover plate 7112 relative to the opening 710c and rotation of the first sub-cover plate 7111 relative to the housing 710.

Further, an outer side surface of the second sub-cover plate 7112 is further provided with a handle 7112b, facilitating the staff's pushing and pulling of the second sub-cover plate 7112 by holding the handle 7112b, so as to achieve the linkage between the second sub-cover plate 7112 and the first sub-cover plate 7111, thereby opening and closing the opening 710c.

According to another aspect of the embodiments of the present application, there is further provided a computing device including a plurality of server modules 72 and the cooling apparatus 71 of the above embodiment of the present application.

A computing device of an embodiment of the present application may specifically be a server 7201 cluster, a data center, or a mining farm (a computing system consisting of a plurality of mining machines), or the like. The server module 72 may include at least one server 7201 with the same computing capacity, and the computing capacity of the servers 7201 in different server modules 72 may be the same or different.

By employing the cooling apparatus 71 of the above embodiment of the present application, the computing device according to the embodiment of the present application improves the cooling effect on the plurality of server modules 72 and has better working stability and reliability.

As another aspect of the embodiments of the present application, an embodiment of the present application further provides a data center including the computing device of the above embodiment of the present application.

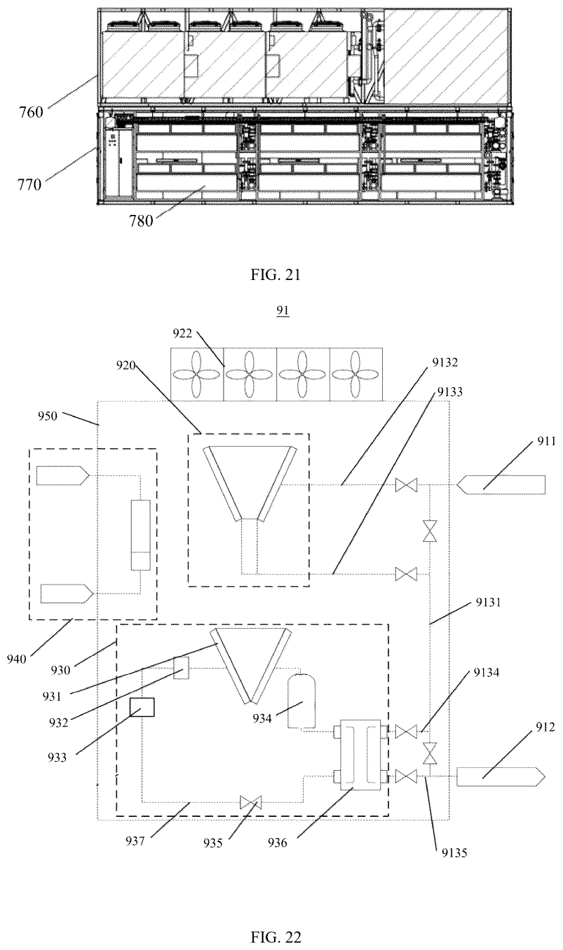

As shown in FIGS. 20 and 21, as another aspect of the embodiments of the present application, an embodiment of the present application provides a container data center, including;
a computing device enclosure 770; and
a computing device 780 as described in any of the foregoing embodiments, which is mounted in the computing device enclosure 770.

As another aspect of the embodiments of the present application, an embodiment of the present application provides a container data center, including;
a cold source enclosure 760 provided with a cold source device 790; and
a computing device enclosure 770 provided with a computing device 780 as described in any of the foregoing embodiments.

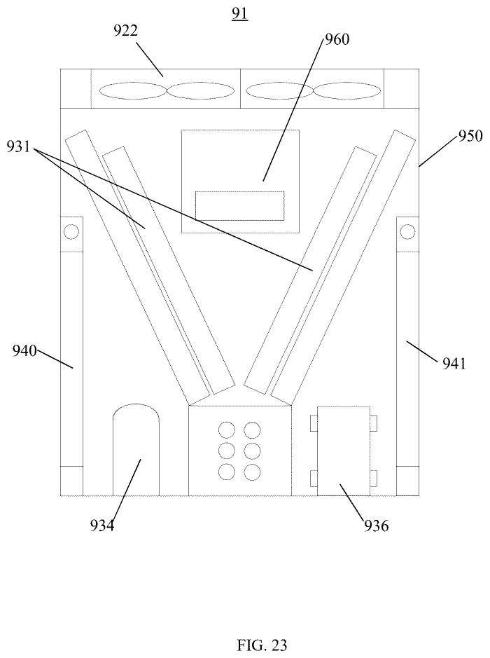

As a third aspect of the embodiments of the present application, a heat exchange device 91 according to an embodiment of the present application will be described below with reference to FIGS. 22 and 23.

As shown in FIG. 22, the heat exchange device 91 according to the embodiment of the present application includes a pipeline module and a heat exchange module. In an implementation, as shown in FIG. 22, a connecting pipeline includes an intermediate pipeline 9131, input and output ends of the intermediate pipeline 9131 being in communication with an input pipeline 911 and an output pipeline 912, respectively. The intermediate pipeline 9131 is used for allowing the cooling working medium to flow through the heat exchange module for gaseous medium cooling and/or liquid medium cooling.

Optionally, the connecting pipeline further includes a first liquid inlet pipeline 9132 communicating between an input end of a first heat exchange module 920 and the intermediate pipeline 9131, and a first liquid outlet pipeline 9133 connected between an output end of the first heat exchange module 920 and the intermediate pipeline 9131.

Further, the connecting pipeline further includes a second liquid inlet pipeline 9134 communicating between an input end of a second heat exchange module 930 and the intermediate pipeline 9131, and a second liquid outlet pipeline 9135 communicating between an output end of the second heat exchange module 930 and the intermediate pipeline 9131.

In an implementation, the heat exchange device 91 further includes a valve assembly for limiting an entry of the cooling working medium into the first liquid inlet pipeline 9132 and the first liquid outlet line 9133, and/or an entry of the cooling working medium into the second liquid inlet line 9134 and the second liquid outlet line 9135.

In the embodiment of the present application, the valve assembly includes a plurality of valve bodies, which are respectively arranged on at least one of a first pipeline set and a second pipeline set. By controlling each valve body in the valve assembly to open and close, the flow of the cooling working medium can be guided or dammed. For example, the first liquid inlet pipeline 9132 and the first liquid outlet pipeline 9133 may be respectively provided with at least one valve body; for another example, the first liquid outlet pipeline 9133 and the second liquid inlet pipeline 9134 may be respectively provided with at least one valve body; for yet another example, the first liquid inlet pipeline 9132, the first liquid outlet pipeline 9133, the second liquid inlet pipeline 9134 and the second liquid outlet pipeline 9135 may be respectively provided with at least one valve body.

Optionally, the second heat exchange module 930 includes a condenser 931, an expansion valve 932, a liquid storage tank 933, a throttle valve 935, a heat exchange unit 936, a compressor 934, and a circulation pipeline 937, the circulation pipeline 937 is used for circulation flow of the liquid medium among the condenser 931, the expansion valve 932, the liquid storage tank 933, the throttle valve 935, the heat exchange unit 936, and the compressor 934.

In an implementation, the heat exchange device 91 further includes a frame body 950, inside which the pipeline module, the first heat exchange module 920 and the second heat exchange module 930 are mounted. There may be one or more gaseous medium cooling modules 940 that are provided on side walls of the frame body 950 respectively, and a fan assembly 922 of the first heat exchange module 920 may be provided on a top of the frame body 950. Thus, the gaseous medium cooling module 940 can guide the gaseous medium laterally from the outside of the frame body 950 into the inside of the frame body 950, and guide the other media after heat exchange upward to the outside of the frame body 950. Exemplarily, a wet curtain 941 may be arranged on a side wall of the frame body. Optionally, the gaseous medium cooling module 940 further includes a fan assembly 922 arranged on the top of the frame body 950 and located above the first heat exchange module 920. It can be understood that after entering through the wet curtain 941 located on the side wall of the frame body 950, external air flows through the first heat exchange module 923 and the second heat exchange module 930, and is then discharged through the fan assembly 922 at the top. Thus, the flow of the air within the frame body 950 can pass through the internal heat exchange modules as much as possible, thereby further improving the cooling efficiency of the heat exchange modules.

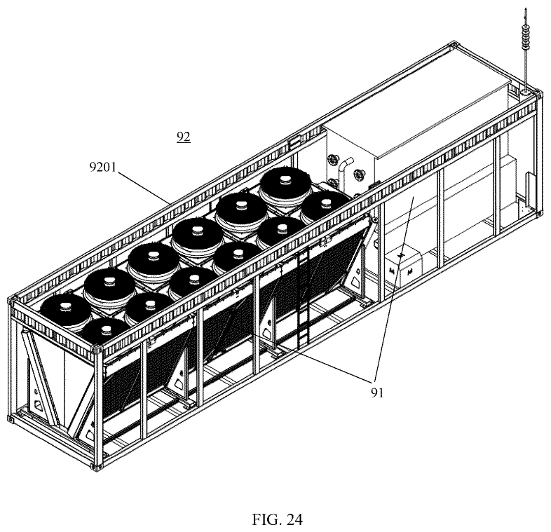

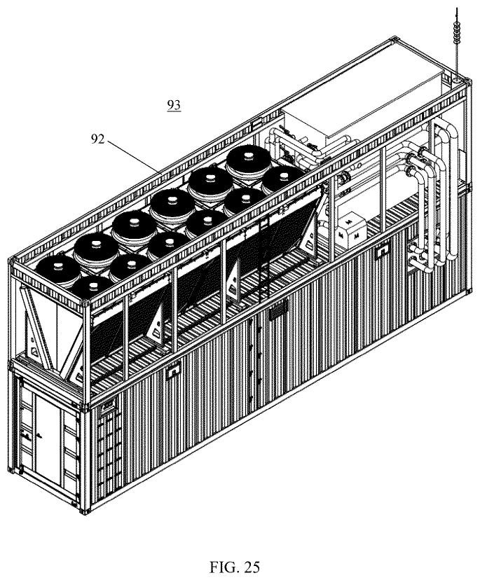

According to another aspect of the embodiments of the present application, there is further provided a container heat exchange device 92. As shown in FIG. 24, the container heat exchange device 92 includes a frame 9201 and a heat exchange device 91 of the above embodiment of the present application, wherein the heat exchange device 91 is mounted in the frame 9201.

According to another aspect of the embodiments of the present application, there is further provided a data center 93. As shown in FIG. 25, the data center 93 includes a computing device and a container heat exchange device 92 of the above embodiment of the present application. Specifically, the computing device includes a plurality of server modules and a cooling apparatus which cools the plurality of server modules with a cooling working medium. A pipeline module of the container heat exchange device 92 is in communication with the cooling apparatus.

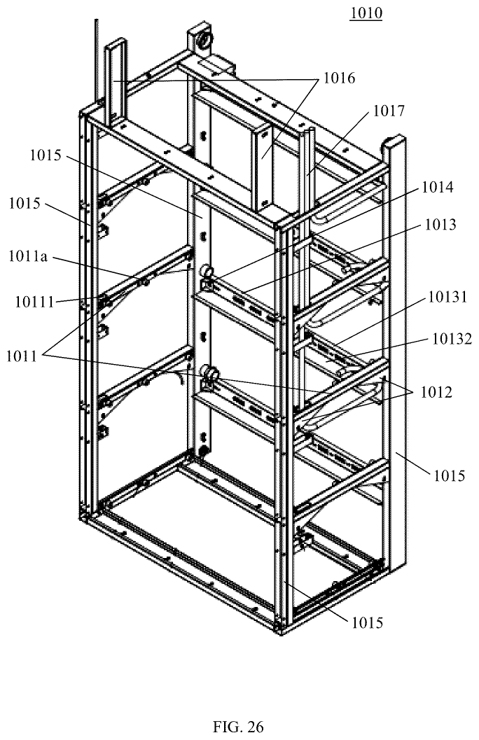

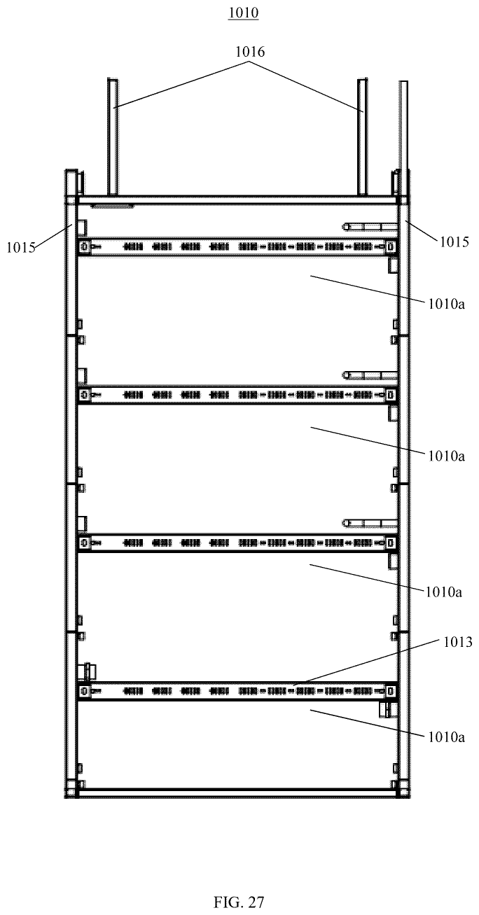

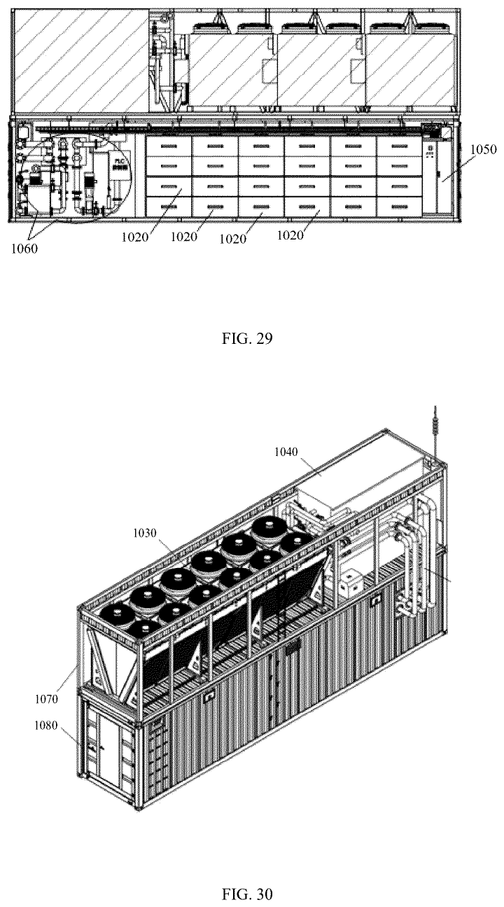

As a fourth aspect of the embodiments of the present application, a device framework and a container data center according to an embodiment of the present application will be described below with reference to FIGS. 26 to 30.

In the embodiment of the present application, there is provided a device framework, which includes: a frame body 1010 defining at least one storage chamber 1010a; and at least one bearing portion slidably provided on the frame body to slide into or out of the corresponding storage chamber 1010a, the bearing portion is used for bearing a computing module.

The technique according to the embodiment of the present application improves the integration of computing devices, which is conducive to reduced space footprint of the computing devices, thereby reducing the external size of the data center and being conducing to fast deployment of the data center.

In the embodiment of the present application, the frame body 1010 includes a support portion 1020 for supporting the bearing portion. With the arrangement of the support portion, the stable mounting of the bearing portion is achieved.

In the embodiment of the present application, the frame body 1010 includes uprights 1015 for vertical support of the device framework. This facilitates arrangement of a storage chamber 1010a in the vertical space to achieve accommodation of the bearing portion and improve the stability of the device framework in a vertical direction.

In the embodiment of the present application, the frame body 1010 includes support beams (e.g., a first support beam 1011 and a second support beam 1013) for transverse support of the device framework. With the arrangement of the cross beams, the transverse stability of the device framework is achieved.

In the embodiment of the present application, the frame body 1010 further includes uprights 1015, the support portion 1020 being connected between two uprights 1015. The support portion 1020 reinforces the stability of connection between the two uprights 1015.

In the embodiment of the present application, the frame body 1010 further includes support beams (e.g., a first support beam 1011 and a second support beam 1013) connected between two uprights 1015. With the arrangement of the support beams, the connection between the uprights 1015 is not only achieved, but also the bearing function of the bearing portion is implemented.

In the embodiment of the present application, the frame body 1010 includes a support portion 1020, uprights 1015 and support beams, the support portion 1020 and the support beams being connected between two uprights 1015. The mutual combination of the support portion 1020, the uprights 1015 and the support beams forms a storage chamber 1010a that can accommodate the bearing portion, and the combination of the vertical uprights 1015 and the support beams strengthens the stability of the frame body 1010. As shown in FIGS. 26 to 30, the frame body 1010 of the device framework according to the embodiment of the present application defines at least one storage chamber 1010a. The bearing portion is slidably provided on the frame body, so as to slide into or out of the corresponding storage chamber 1010a. A computing module is borne on the bearing portion, which includes a server module and a cooling module for cooling the server module.

In the embodiment of the present application, the number of storage chambers 1010a defined by the frame body may be one or more, and correspondingly, the number of bearing portions 1020 may be one or more in a one-to-one correspondence with the at least one storage chamber 1010a. Each bearing portion is slidably disposed on the frame body and forms a sliding fit with the corresponding storage chamber 1010a, so that the bearing portion can slide into or out of the corresponding storage chamber 1010a.

The shape and size of the bearing portion are not specifically limited in the embodiments of the present application. Exemplarily, a size of the bearing portion may be adapted to a size of the storage chamber 1010a. An upper wall face of the bearing portion forms a bearing face for bearing and fixing the computing module.

The computing module may include at least one server module, and each server module may include at least one server that is integrally disposed and may be closely arranged along a certain direction, such as along a horizontal or vertical direction. It should be noted that the computing module may employ a plurality of server modules of the same specifications, or may employ a plurality of server modules of different specifications, which is not specifically limited in the embodiments of the present application. In addition, the number of server modules included in the computing module or the number of servers included in the server modules are not specifically limited in the embodiments of the present application either, which may be correspondingly set by those skilled in the art according to actual situations.

It should be noted that the cooling module may employ any cooling method to cool the server module, including but not limited to air cooling, water cooling, and immersion liquid cooling.

The embodiments of the present application do not specifically limit the specific arrangement position of the server module or the cooling module on the bearing portion. Exemplarily, the server module and the cooling module may be disposed side by side in the horizontal direction. For example, they may be disposed side by side along a horizontal sliding direction of the bearing portion relative to the frame body, or may be disposed side by side along the horizontal direction perpendicular to the horizontal sliding direction of the bearing portion, or may be disposed side by side along the vertical direction.

By providing the frame body and the bearing portion for bearing the computing module, the computing device according to the embodiment of the present application can implement the integrated deployment of a plurality of computing modules, thereby improving the integration of computing devices, being conducive to reduced space footprint of the computing devices, then reducing the external size of the data center, and being conducing to fast deployment of the data center. Second, by means of the sliding-fit between the bearing portion and the frame body to enable the bearing portion to slide into or out of the corresponding storage chamber 1010a, the computing module on the bearing portion can be conveniently slid into or out of the storage chamber 1010a, thereby improving the convenience of maintenance or hardware updates of the computing module on the bearing portion.

In an implementation, the bearing portion is slidable relative to the frame body along a first horizontal direction, which is parallel to the horizontal plane.

In the embodiment of the present application, the first horizontal direction may be a horizontal direction parallel to a length direction or a width direction of the frame body.

Exemplarily, any manner of sliding fit between the bearing portion and the frame body may be employed. By way of example, a structure in which slide rails and rollers 1011a are fitted between the bearing portion and the frame body may be employed. For example, the bearing portion may be provided with slide rails extending along the first horizontal direction, and the frame body may be provided with rollers 1011a that form a rolling fit with the slide rails. Still for example, the frame may be provided with slide rails extending along the first horizontal direction, and the bearing portion may be provided with rollers 1011a that form a rolling fit with the slide rails.

In an implementation, as shown in FIGS. 26 to 28, the frame body includes a support assembly corresponding to the at least one storage chamber 1010a, the support assembly including two first support beams 1011 respectively located on two opposite sides of the storage chamber 1010a in a second horizontal direction, each extending along the first horizontal direction, the bearing portion being slidably supported on the two first support beams 1011, wherein the second horizontal direction is perpendicular to the first horizontal direction.

In the embodiment of the present application, the second horizontal direction may be a horizontal direction perpendicular to the first horizontal direction. For example, in a case where the first horizontal direction is the length direction of the frame body, the second horizontal direction may be the width direction of the frame body; still for example, in a case where the first horizontal direction is the width direction of the frame body, the second horizontal direction may be the length direction of the frame body.

In a specific example, the two first support beams 1011 are disposed apart in the second horizontal direction that is perpendicular to the first horizontal direction, and an extension direction of the two first support beams 1011 is parallel to the first horizontal direction. Two ends of the first support beams 1011 are respectively fixed to the two uprights 1015 of the frame body disposed apart in the first horizontal direction.

The bearing portion forms a sliding fit with the two first support beams 1011. By way of example, the two first support beams 1011 are respectively provided with a sliding slot, an extension direction of the sliding slot being parallel to the extension direction of the first support beams 1011. Two side walls of the bearing portion disposed oppositely in the second horizontal direction are respectively provided with a sliding fit portion that forms a sliding fit with the sliding slot of the first support beam 1011 on a corresponding side. The sliding slot may be formed by downwardly recessing the upper wall face of the first support beam 1011, or by recessing an inner side surface of the first support beam 1011 close to the storage chamber 1010a in a direction away from the storage chamber 1010a.

Optionally, inner side wall faces of the first support beam 1011 are provided with a plurality of rollers 1011a, and two side wall faces of the bearing portion disposed oppositely in the second horizontal direction are respectively provided with a sliding slot, the plurality of rollers 1011a forming a rolling fit with the sliding slot on a corresponding side.

Exemplarily, the sliding slots are formed by inwardly recessing the two side wall faces of the bearing portion disposed oppositely in the second horizontal direction, an extension direction of the sliding slots being parallel to the first horizontal direction. The plurality of rollers 1011a are disposed at intervals on the inner side wall faces of the first support beam 1011 along the first horizontal direction, a rotation axis of the rollers 1011a being disposed along the second horizontal direction. The plurality of rollers 1011a are located in the sliding slot on the corresponding side and form a rolling fit with an inner wall face of the sliding slot.

Optionally, an upper wall face of the first support beam 1011 forms a rolling support face, and two side wall faces of the bearing portion disposed oppositely in the first horizontal direction are respectively provided with a plurality of rollers 1011a, the plurality of rollers 1011a forming a rolling fit with the rolling support face.

Exemplarily, the upper wall face of the first support beam 1011 is parallel to the horizontal plane to form the rolling support face. The plurality of rollers 1011a are disposed at intervals along the first horizontal direction and are rollably supported on the rolling support face. It can be understood that in a process where the bearing portion slides relative to the frame body to slide into or out of the storage chamber 1010a, the rollers 1011a roll relative to the rolling support face.

With the above implementation, the sliding friction between the bearing portion and the first support beam 1011 is transformed into rolling friction, thereby reducing the frictional force between the bearing portion and the first support beam 1011, and resulting in smoother movement of the bearing portion relative to the frame body.

Further, the frame body is further provided with a telescopic drive apparatus, a movable end of which is fixedly connected with the bearing portion for driving the bearing portion to slide relative to the frame body along the first horizontal direction. The telescopic drive apparatus may be a gas strut, an electric telescopic rod, or the like. Thus, automatic sliding of the bearing portion relative to the frame body can be implemented, thereby meeting the purpose of saving manpower.

Optionally, a lower side of the first support beam 1011 is provided with a first structural reinforcement 1012, a side wall of the first structural reinforcement 1012 being fixed to the uprights 1015 of the frame body.

Exemplarily, the first support beam 1011 is supported on an upper wall face of the first structural reinforcement 1012, and the side wall of the first structural reinforcement 1012 is fixed to the uprights 1015 of the frame body by fasteners. In other examples of the present application, the side wall of the first structural reinforcement 1012 may also be welded to the uprights 1015 of the frame body.

With the above implementation, the first structural reinforcement 1012 can play a certain role in supporting the first support beam 1011, thereby enhancing the structural strength of the first support beam 1011 and avoiding the first support beam 1011 from deforming in a load-bearing state.

Further, the lower side of the first support beam 1011 is provided with two first structural reinforcements 1012, which are respectively disposed close to the two end portions of the first support beam 1011.

Exemplarily, the two end portions of the first support beam 1011 are respectively fixed to the two uprights 1015 of the frame body that are disposed oppositely in the first horizontal direction. The two first structural reinforcements 1012 are spaced apart in the first horizontal direction and respectively close to the two end portions of the first support beam 1011, which are respectively fixed to the two uprights 1015 by fasteners.

With the above implementation, by providing the two first structural reinforcements 1012, regions of the first support beam 1011 close to the two end portions can be supported, thereby alleviating the problem of stress concentration at connections between the first support beam 1011 and the frame body, and improving the stability and structural strength of connection between the first support beam 1011 and the frame body.

Further, a height dimension of the first structural reinforcement 1012 decreases in a direction from an end portion of the first support beam 1011 to a middle portion of the first support beam 1011.

It can be understood that the height dimension of the first structural reinforcement 1012 refers to a dimension of the first structural reinforcement 1012 in the vertical direction. The middle portion of the first support beam 1011 refers to a part of the first support beam 1011 that is centered in the first horizontal direction, and the end portion of the first support beam 1011 refers to either end portion of the first support beam 1011 in the first horizontal direction.

In a specific example, a cross-sectional shape of the first structural reinforcement 1012 may be a right triangle. Projected outlines of an upper side wall of the first structural reinforcement 1012 and a side wall adjacent to the upright 1015 form two right-angled sides of the right triangle, so that the height dimension of the first structural reinforcement 1012 gradually decreases from the end portion to the middle portion of the first support beam 1011.

Optionally, the first support beam 1011 is provided with a via-hole 10111 penetrating the first support beam 1011 in the vertical direction. The via-hole 10111 is used for allowing a cable 1017 of the computing device to pass through, so that the cable 1017 is electrically connected with the computing module 1030 borne on the bearing portion.

Exemplarily, the frame body is provided with a plurality of storage chambers 1010a disposed at intervals along the vertical direction, and correspondingly, a plurality of first support beams 1011, respectively corresponding to the plurality of storage chambers 1010a, are disposed at intervals along the vertical direction. The via-holes 10111 on the plurality of first support beams 1011 disposed at intervals along the vertical direction are disposed directly oppositely in the vertical direction. The computing device further includes a plurality of cables 1017 that are electrically connected with the computing modules borne on a plurality of bearing portions 1020 respectively. The plurality of cables 1017 pass through the via-holes 10111 of the first support beams 1011 from top to bottom and are electrically connected with the corresponding computing modules respectively.

More specifically, the frame body defines four storage chambers 1010a in the vertical direction, which are a first storage chamber 1010a, a second storage chamber 1010a, a third storage chamber 1010a, and a fourth storage chamber 1010a from top to bottom. The computing device includes a first computing module, a second computing module, a third computing module, and a fourth computing module, which are borne on the bearing portions 1020 respectively corresponding to the four storage chambers 1010a. The computing device further includes a first cable, a second cable, a third cable, and a fourth cable respectively corresponding to the four computing modules. The first cable passes downward through the via-hole 10111 on the first support beam 1011 corresponding to the first storage chamber 1010a and is electrically connected with the first computing module borne on the bearing portion located in the first storage chamber 1010a; the second cable passes downward sequentially through the via-holes 10111 on the first support beams 1011 respectively corresponding to the first storage chamber 1010a and the second storage chamber 1010a and is electrically connected with the second computing module borne on the bearing portion located in the second storage chamber 1010a; the third cable passes downward sequentially through the via-holes 10111 on the first support beams 1011 respectively corresponding to the first storage chamber 1010a, the second storage chamber 1010a, and the third storage chamber 1010a and is electrically connected with the third computing module borne on the bearing portion located in the third storage chamber 1010a; and the fourth cable passes downward sequentially through the via-holes 10111 on the first support beams 1011 respectively corresponding to the first storage chamber 1010a, the second storage chamber 1010a, the third storage chamber 1010a, and the fourth storage chamber 1010a and is electrically connected with the fourth computing module borne on the bearing portion located in the fourth storage chamber 1010a.

Further, the via-holes 10111 are disposed close to either end portion of the first support beam 1011. By way of example, the first horizontal direction may be a front-rear direction of the frame body, and the via-holes 10111 may be disposed close to a front end or a rear end of the first support beam 1011.

With the above implementation, the storage effect on the cables 1017 is improved, and the convenience of cable routing for the computing device is enhanced.

Optionally, the support assembly further includes a second support beam 1013 corresponding to the at least one storage chamber 1010a, the second support beam 1013 is used for supporting the bearing portion having slid into the storage chamber 1010a.

Exemplarily, the second support beam 1013 is located on a side of the storage chamber 1010a in the first horizontal direction, and the second support beam 1013 extends along the second horizontal direction. Two end portions of the second support beam 1013 are respectively fixed to two uprights 1015 of the frame body that are disposed oppositely in the second horizontal direction. The end portions of the second support beam 1013 and the uprights 1015 may be fixedly connected by fasteners, or by welding.

Optionally, the second support beam 1013 includes a first bent portion 10131 and a second bent portion 10132 which are connected. A plane where the first bent portion 10131 is located is perpendicular to the horizontal plane, and a plane where the second bent portion 10132 is located is parallel to the horizontal plane. In other words, the planes where the first bent portion 10131 and the second bent portion 10132 are located are perpendicular to each other. The bearing portion located in the storage chamber 1010a is supported on an upper wall face of the second bent portion 10132.

It can be understood that when the bearing portion slides into the storage chamber, a rear wall face of the bearing portion abuts against an inner wall face of the first bent portion 10131, and part of the bearing portion is supported on the upper wall face of the second bent portion 10132.

In one example, the two first support beams 1011 included in any support assembly are located below the second support beam 1013 in the vertical direction. The rear wall face of the bearing portion is provided with an extended support portion located above the lower wall face of the bearing portion in the vertical direction. When the bearing portion slides into the storage chamber 1010a, the lower wall face of the bearing portion is supported on the upper wall faces of the two first support beams 1011, and the extended support portion is supported on an upper wall face of the second support beam 1013.

With the above implementation, the support stability for the bearing portion having slid into the storage chamber 1010a is improved, which is conducive to reducing a load-bearing weight of the two first support beams 1011, thereby reducing the probability of deformation of the first support beams 1011.

Optionally, the end portions of the second support beam 1013 are connected to the uprights 1015 of the frame body through a second structural reinforcement 1014.

Exemplarily, there are two second structural reinforcements 1014, which are respectively provided at the two end portions of the second support beam 1013. The second structural reinforcements 1014 each have a first connecting wall fixedly connected with the first bent portion 10131 by a fastener, and a second connecting wall fixedly connected with the upright 1015 of the frame body by a fastener. More specifically, planes where the first connecting wall and the second connecting wall are located are perpendicular to each other, and the plane where the first connecting wall is located is perpendicular to the first horizontal direction, so that a side wall face of the first connecting wall can abut against a side wall face of the first bent portion 10131; and the plane where the second connecting wall is located is perpendicular to the second horizontal direction, so that a side wall face of the second connecting wall can abut against a side wall face of the upright 1015. The first connecting wall and the first bent portion 10131, as well as the second connecting wall and the upright 1015, are respectively fixedly connected by fasteners.

Thus, the stability of connection between the second support beam 1013 and the uprights 1015 is improved, and the second support beam 1013 is connected and fixed to the uprights 1015 through the second structural reinforcements 1014, which avoids the problem of stress concentration in the second support beam 1013 caused by connection between the same and the uprights 1015, and can reduce the probability of deformation of the second support beam 1013 or the uprights 1015.

In an implementation, as shown in FIGS. 26 to 28, the frame body includes a plurality of uprights 1015 disposed at intervals, the plurality of uprights 1015 including two rows of uprights 1015 disposed apart along the first horizontal direction, each row including two uprights 1015 disposed apart along the second horizontal direction.

Exemplarily, the number of the plurality of uprights 1015 is four, and four uprights 1015 are arranged in two rows along the first horizontal direction and in two columns along the second horizontal direction, the four uprights 1015 jointly define at least one storage chamber 1010a. The first support beams 1011 are respectively provided between the two uprights 1015 in each column, in a quantity the same as that of the storage chambers 1010a, and the second support beams 1013 are provided between the two uprights 1015 in a rear row, in a quantity the same as that of the storage chambers 1010a.

In an implementation, as shown in FIGS. 26 to 28, a top of the frame body is provided with a fixed connection portion 1016, which is fixedly connected with a fixing portion located on an upper side of the frame body by fasteners.

Exemplarily, the fixed connection portion 1016 may be a sheet metal member, and a length direction of the sheet metal member is parallel to the vertical direction. Two fixed connection portions 1016 may be disposed apart in the first horizontal direction or the second horizontal direction. The fixed connection portions 1016 are provided with fixing through-holes for allowing the fasteners to pass through for fixed connections between the fasteners and the fixing portion on the upper side of the frame body. It should be noted that the computing device is mounted inside an enclosure of the data center, and the fixing portion on the upper side of the frame body may be an upper wall face of the enclosure of the data center.

In an implementation, the server module and the cooling module are disposed side by side in the first horizontal direction.

Exemplarily, a side of the frame body in the first horizontal direction is provided with an opening region, through which the bearing portion slides into or out of the storage chamber 1010a. Thus, according to the maintenance needs for the server module or the cooling module, a corresponding part of the bearing portion can be pulled out from the storage chamber 1010a, thereby saving the external space occupied by the bearing portion during maintenance to a certain extent.

Optionally, the bearing portion further includes a housing for bearing the server module, in which a cooling working medium may be accommodated to cool the server module.

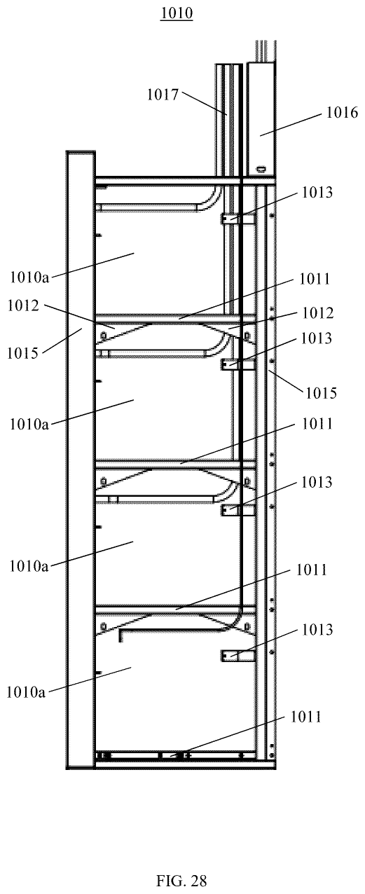

As shown in FIGS. 28 to 30, an embodiment of the present application provides a data center, including: a power distribution cabinet 1050, a bearing portion, and a cold source connection device 1060. The cold source connection device 1060 is used for connecting between the bearing portion and a cold source device (1030, 1040). The power distribution cabinet 1050 and the cold source connection device 1060 are disposed at two ends of the bearing portion, wherein the bearing portion is mounted on the frame body in any of the foregoing embodiments.

An embodiment of the present application further provides a data center, including an upper enclosure 1070 and a lower enclosure 1080, wherein a cold source device 1030 (1040) is assembled in the upper enclosure 1070, and a bearing portion is assembled in the lower enclosure 1080, the cold source device in the upper enclosure 1070 is used for cooling the bearing portion in the lower enclosure 1080.

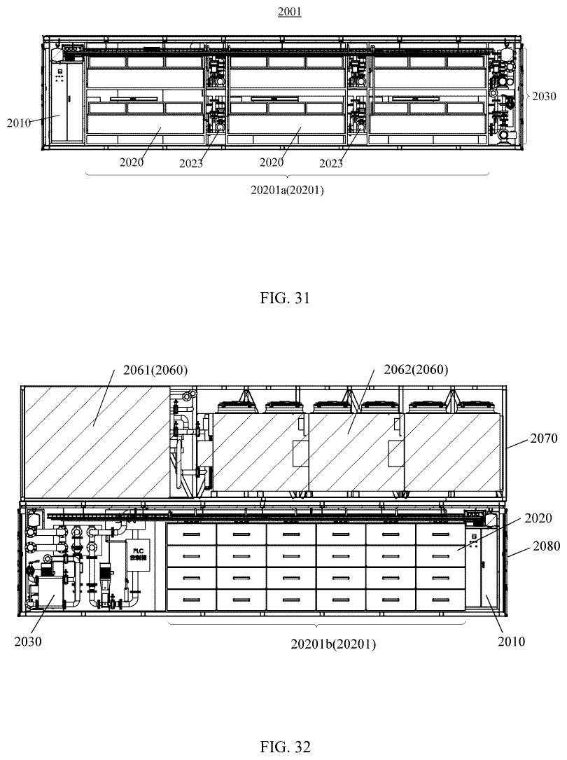

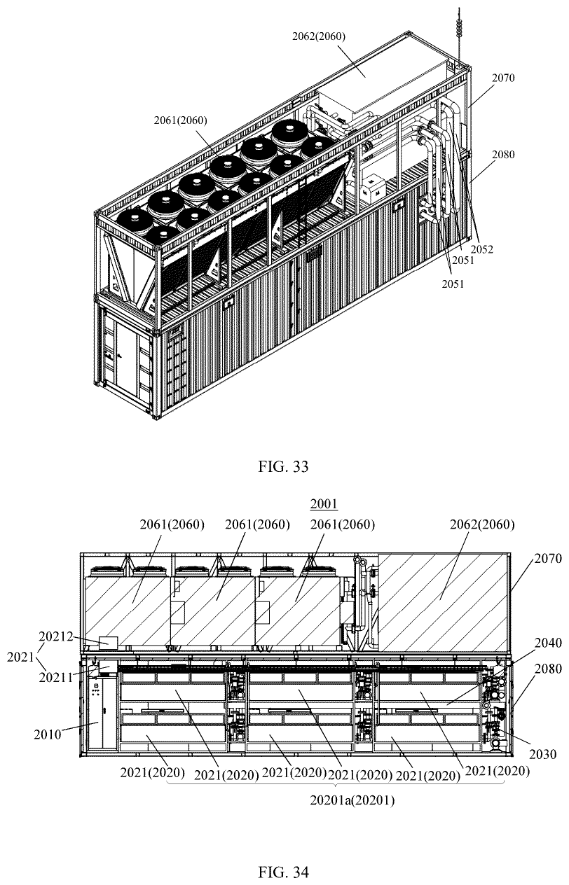

As a fifth aspect of the embodiments of the present application, a data center 2001 according to an embodiment of the present application will be described below with reference to FIGS. 31 to 39. The data center 2001 of the embodiment of the present application may be integrally deployed inside a container to form a container data center according to another aspect of the embodiments of the present application.

The data center 2001 of the embodiment of the present application includes a power distribution cabinet 2010, a computing device 2020, and a cold source connection device 2030. Specifically, the cold source connection device 2030 is connected between the computing device 2020 and a cold source device 2060, and the power distribution cabinet 2010 and the cold source connection device 2030 are disposed on two sides of the computing device 2020.

In the embodiment of the present application, the power distribution cabinet is used for distributing electrical power to the computing device 2022, the cold source connection device 2030, the cold source device 2060 and other powered devices of the data center 2001. The cold source connection device 2030 is used for transporting the cooling working medium cooled by the cold source device 2060 to a cooling apparatus of the computing device 2030, or for transporting to the cold source device 2060 the cooling working medium to be cooled as output from the cooling apparatus of the computing device 2030, so as to implement liquid cooling heat dissipation, reduce the temperature of the data center 2001, and improve the working efficiency.

In the embodiment of the present application, the two sides of the computing device 2020 may be understood as two sides of one computing device 2020, or as two sides of a computing device group formed by integrally deploying a plurality of computing devices 2020.

By way of example, the plurality of computing devices 2020 may be arranged side by side along a certain direction to form a computing device group, with the power distribution cabinet 2010 and the cold source connection device 2030 on two opposite sides of the computing device group in a first direction.

Exemplarily, the cold source connection device 2030 includes a power pump including a liquid supply power pump and a liquid return power pump, and a pipeline including a liquid inlet pipe and a liquid outlet pipe. With the above power pump and pipeline, the communication between the computing device 2020 and the cold source device 2060 is achieved, thereby implementing circulation flow of the cooling working medium.

By disposing the power distribution cabinet 2010 and the cold source connection device 2030 of the data center 2001 on the two sides of the computing device 2020, the data center 2001 according to the embodiment of the present application implements physical isolation between the power distribution cabinet 2010 and the cold source connection device 2030, effectively avoiding the risk caused by leakage of the cold source connection device 2030.

In an implementation, a cooling pipeline set 2040 is further included, through which the computing device 2020 and the cold source connection device 2030 are connected.

In the embodiment of the present application, the cooling pipeline set 2040 is connected with each computing device 2020 in sequence. The cooling pipeline set 2040 includes a liquid supply main pipeline connected with an output end of the cold source connection device 2030, and a liquid return main pipeline connected with an input end of the cold source connection device 2030.

In an implementation, a computing device enclosure 2080 is further included, in which the computing device 2020 and the cold source connection device 2030 are provided.

In the embodiment of the present application, the computing device enclosure 2080 is used for integrally arranging the computing device 2020 and the cold source connection device 2030.

In an implementation, further included are a cooling pipeline set 2040, through which the computing device 2020 is connected with the cold source connection device 2030, and a computing device enclosure 2080, in which the cooling pipeline set 2040, the computing device 2020, and the cold source connection device 2030 are provided.

In an implementation, a computing device enclosure 2080 is further included, and the computing device 2020 includes a first cooling apparatus including a cooling housing for bearing the server module of the computing device 2020, the cooling housing 2020 being provided in the computing device enclosure 2080.

In an implementation, the computing devices 2020 are arranged in the first direction to form at least one computing device row 20201; the power distribution cabinet 2010 and the cold source connection device 2030 are disposed on two sides of the computing device row 20201 in the first direction.

In the embodiment of the present application, the first direction may be a length direction of an accommodating space for accommodating the computing devices 2020, wherein the accommodating space may be defined by a factory building or an enclosure. In the following description of the specification of the present application, description will be made by taking as an example a case where the first direction is a length direction of the computing device enclosure 2080 that defines the accommodating space.

Exemplarily, a plurality of computing devices 2020 are arranged in a row in the length direction of the computing device enclosure 2080 to form a computing device row 20201 extending along the length direction of the computing device enclosure 2080. It can be understood that the computing device row 20201 has two sides disposed oppositely in the first direction, namely the length direction of the computing device enclosure 2080, with the power distribution cabinet 2010 provided on a side of the computing device row 20201 in the length direction of the computing device enclosure 2080, and the cold source connection device 2030 provided on the other side of the computing device row 20201 in the length direction of the computing device enclosure 2080.

In an implementation, the computing device row 20201 includes a first computing device row 20201a and a second computing device row 20201b arranged side by side in a second direction, to which the first direction is perpendicular.

In the embodiment of the present application, the second direction is perpendicular to the first direction and may be a width direction of an accommodating space for accommodating the computing devices 2020, wherein the accommodating space may be defined by a factory building or an enclosure. In the following description of the specification of the present application, description will be made by taking as an example a case where the second direction is a width direction of the computing device enclosure 2080 that defines the accommodating space. The computing devices 2020 in the first computing device row 20201a and the second computing device row 20201b have different dimensions, and the computing devices 2020 of different sizes may correspondingly bear server modules of different numbers or specifications.

Exemplarily, the first computing device row 20201a and the second computing device row 20201b are arranged apart in the width direction of the computing device enclosure 2080, and the plurality of computing devices 2020 included in the first computing device row 20201a and the second computing device row 20201b are respectively arranged in rows in the length direction of the computing device enclosure 2080.

In an implementation, the first computing device row 20201a and the second computing device row 20201b share one and the same power distribution cabinet 2010, and/or the first computing device row 20201a and the second computing device row 20201b share one and the same cold source connection device 2030.

Exemplarily, the power distribution cabinet 2010 is located on the same side in an extension direction of the first computing device row 20201a and the second computing device row 20201b, and disposed close to an end of the computing device enclosure 2080 in the length direction. The cold source connection device 2030 is located on the same side in the extension direction of the first computing device row 20201a and the second computing device row 20201b, and disposed close to the other end of the computing device enclosure 2080 in the length direction.

In one example, the power distribution cabinet 2010 is centered in the width direction of the computing device enclosure 2080 so that cables connected with the power distribution cabinet 2010 can be electrically connected with the plurality of computing devices 2020 included in the first computing device row 20201a and the second computing device row 20201b, respectively.

In one example, the cold source connection device 2030 is centered in the width direction of the computing device enclosure 2080 so that pipelines included in the cold source connection device 2030 can be pipeline connected with the plurality of computing devices 2020 included in the first computing device row 20201a and the second computing device row 20201b, respectively.

With the above implementation, the first computing device row 20201a and the second computing device row 20201b share one and the same power distribution cabinet 2010, which facilitates containerization and management of the power distribution cabinet 2010. Furthermore, only one power distribution cabinet 2010 needs to be mounted during assembly, thereby making it simplified to mount the power distribution cabinet 2010.

In an implementation, the power distribution cabinet 2010 includes a first power distribution cabinet 2010 and a second power distribution cabinet 2010, which correspond to the first computing device row 20201a and the second computing device row 20201b, respectively; and/or, the cold source connection device 2030 includes a first cold source connection device and a second cold source connection device, which correspond to the first computing device row 20201a and the second computing device row 20201b, respectively.

Exemplarily, the first power distribution cabinet 2010 and the second power distribution cabinet 2010 are both located on the same side in the extension direction of the first computing device row 20201a and the second computing device row 20201b, and both disposed close to an end of the computing device enclosure 2080 in the length direction. The first power distribution cabinet 2010 and the first computing device row 20201a are arranged in the same row in the length direction of the computing device enclosure 2080, and the second power distribution cabinet 2010 and the second computing device row 20201b are arranged in the same row in the length direction of the computing device enclosure 2080. The first cold source connection device and the second cold source connection device are both located on the same side in the extension direction of the first computing device row 20201a and the second computing device row 20201b, and both disposed close to the other end of the computing device enclosure 2080 in the length direction. The first cold source connection device and the first computing device row 20201a are arranged in the same row in the length direction of the computing device enclosure 2080, and the second cold source connection device and the second computing device row 20201b are arranged in the same row in the length direction of the computing device enclosure 2080.

With the above implementation, in a case where the number of computing devices 2020 is large, the electrical power supply and cooling needs of a plurality of computing devices 2020 can be satisfied.

In an implementation, a maintenance passage is formed between the first computing device row 20201a and the second computing device row 20201b.

Exemplarily, the first computing device row 20201a and the second computing device row 20201b are respectively disposed close to two sides of the accommodating space in the width direction of the computing device enclosure 2080, so that the first computing device row 20201a and the second computing device row 20201b are spaced apart from each other in the width direction of the computing device enclosure 2080, thereby defining the maintenance passage in a space between the first computing device row 20201a and the second computing device row 20201b.

With the above implementation, the maintenance passage may allow the staff to walk through, so that the staff can perform maintenance work on the two computing device rows 20201 in the maintenance passage, thereby enhancing the staffs operation and maintenance efficiency.

In an implementation, the first computing device row 20201a and the first cold source connection device, as well as the second computing device row 20201b and the second cold source connection device are connected through the cooling pipeline set 2040, respectively.

Exemplarily, the cooling pipeline set 2040 is arranged along the extension direction of the computing device row 20201, so that the cooling pipeline set 2040 can pass through each computing device 2020 in the computing device row 20201, thereby connecting the cooling pipeline set 2040 with each computing device 2020 in sequence.

More specifically, the first computing device row 20201a and the first cold source connection device are connected through a first cooling pipeline set, and the second computing device row 20201b and the second cold source connection device are connected through a second cooling pipeline set. Furthermore, the first cooling pipeline set is provided above the first computing device row 20201a, and the second cooling pipeline set is provided above the second computing device row 20201b. With such arrangement, the layout rationality of the cooling pipeline set 2040 is enhanced, and the space utilization rate of the accommodating space is improved.

In an implementation, the cooling pipeline set 2040 includes a main liquid supply pipeline connected with an output end of the cold source connection device 2030, and a main liquid return pipeline connected with an input end of the cold source connection device 2030.

Optionally, the cooling pipeline set 2040 further includes a plurality of branch liquid supply pipelines and a plurality of branch liquid return pipelines. Any computing device 2020 in the computing device row 20201 is connected with the main liquid supply pipeline through a corresponding branch liquid supply pipeline and with the main liquid return pipeline through a corresponding branch liquid return pipeline.

Exemplarily, cooling apparatuses of a plurality of computing devices 2020 in the first computing device row 20201a are connected to a main liquid supply pipeline of a first pipeline set through corresponding branch liquid supply pipelines, and to a main liquid return pipeline of the corresponding first pipeline set through corresponding branch liquid return pipelines. An input end of the main liquid supply pipeline of the first pipeline set is connected with a liquid supply end of the first cold source connection device, and an output end of the main liquid return pipeline of the first pipeline set is connected with a liquid return end of the first cold source connection device. Cooling apparatuses of a plurality of computing devices 2020 in the second computing device row 20201b are connected to a main liquid supply pipeline of a second pipeline set through corresponding branch liquid supply pipelines, and to a main liquid return pipeline of the corresponding second pipeline set through corresponding branch liquid return pipelines. An input end of the main liquid supply pipeline of the second pipeline set is connected with a liquid supply end of the second cold source connection device, and an output end of the main liquid return pipeline of the second pipeline set is connected with a liquid return end of the second cold source connection device.

In an implementation, a first connection pipeline set 2051 is connected between the first cold source connection device and a first cold source device 2061 and a second cold source device 2062, the first connection pipeline set 2051 including a first liquid supply connection pipeline and a first liquid return connection pipeline.

In the embodiment of the present application, the first cold source device 2061 and the second cold source device 2062 may be the same device, or may be different devices. For example, the first cold source device 2061 and the second cold source device 2062 may both be a cooling tower. For another example, the first cold source device 2061 and the second cold source device 2062 may both be a dry cooler. For still another example, the first cold source device 2061 and the second cold source device 2062 may be a cooling tower and a dry cooler, respectively.

Exemplarily, an end of the first connection pipeline set 2051 is correspondingly connected with the first cold source device 2061 and the second cold source device 2062, and the other end of the first connection pipeline set 2051 is connected with the first cold source connection device. It can be understood that an input end of the first liquid supply connection pipeline is connected with an output end of the first cold source device 2061 or the second cold source device 2062, and an output end of the first liquid supply connection pipeline is connected with the liquid inlet end of the first cold source connection device. An input end of the first liquid return pipeline is connected with the liquid outlet end of the first cold source connection device, and an output end of the first liquid return pipeline is connected with an input end of the first cold source device 2061 or the second cold source device 2062.

In an implementation, at least two first computing device rows 20201a are disposed in a stacked manner along a vertical direction, the at least two first computing device rows 20201a being connected with the first cold source connection device through at least two first cooling pipeline sets.

Exemplarily, two first computing device rows 20201a are provided, which are disposed directly oppositely and apart in the vertical direction. The two first computing device rows 20201a are respectively connected with the first cold source connection device through the corresponding first cooling pipeline sets.

More specifically, the first cold source connection device is further used for correspondingly connecting two first cooling pipeline sets with two first connection pipeline sets 2051, so that the first cold source device 2061 cools the cooling working medium of one of the two first computing device rows 20201a, and the second cold source device 2062 cools the cooling working medium of one of the two first computing device rows 20201a.

In an implementation, a second connection pipeline set 2052 is connected between the second cold source connection device and the first cold source device 2061 and the second cold source device 2062, the second connection pipeline set 2052 including a second liquid supply connection pipeline and a second liquid return connection pipeline.

Exemplarily, the first cold source device 2061 and the second cold source device 2062 are connected with the second cold source connection device through the second connection pipeline set 2052. It can be understood that an input end of the second liquid supply connection pipeline is connected with output ends of the first cold source device 2061 and the second cold source device 2062, and an output end of the second liquid supply connection pipeline is connected with the liquid inlet end of the second cold source connection device. An input end of the second liquid return pipeline is connected with the liquid outlet end of the second cold source connection device, and an output end of the second liquid return pipeline is connected with input ends of the first cold source device 2061 and the second cold source device 2062.

In an implementation, the second computing device row 20201b and the second cold source connection device are connected through a second cooling pipeline set.

Exemplarily, the second cooling pipeline set is arranged along an extension direction of the second computing device row 20201b, so that the second cooling pipeline set can pass through the plurality of computing devices 2020 in the second computing device row 20201b in sequence. The second cold source connection device is used for correspondingly connecting the second cooling pipeline set with the second connection pipeline set 2052.

In an implementation, the computing device 2020 includes a first cooling apparatus 2022 including a cooling housing for bearing the server module. The first cooling apparatus 2022 further includes a power assembly 2023 for implementing circulation of the cooling working medium within the cooling housing. Exemplarily, the power assembly 2023 may include a power pump and a liquid inlet/outlet pipeline. The power pump is provided in the liquid inlet/outlet pipeline to provide power to the flow of the cooling working medium in the liquid inlet/outlet pipeline, thereby implementing circulation of the cooling working medium into and out of the cooling housing.

Optionally, the power assembly 2023 is disposed on a side of the cooling housing away from the power distribution cabinet 2010. By disposing the power assembly 2023 away from the power distribution cabinet 2010, safety hazards caused by leakage in the pipeline of the power assembly 2023 can be prevented.

In an implementation, the data center 2001 further includes a second cooling apparatus 2021. The second cooling apparatus 2021 is used for transporting cold air to the inside of the data center 2001 to cool the inside of the data center 2001.

Exemplarily, the data center 2001 includes an enclosure and a cooling device. Specifically, the enclosure includes a computing device enclosure 2080. The cooling device is integrally deployed inside the computing device enclosure 2080, which includes a second cooling apparatus 2021 for transporting cold air to the inside of the computing device enclosure 2080 to cool the inside of the computing device enclosure 2080, and a first cooling apparatus 2022 for cooling the server module of the computing device 2020 through the cooling working medium.

In the embodiment of the present application, the computing device enclosure 2080 may be arbitrarily shaped and sized by those skilled in the art according to actual situations. To facilitate transportation of the data center 2001, optionally, the computing device enclosure 2080 may be correspondingly shaped and sized with reference to a marine freight container, which, for example, may have the same shape and size as 20-foot, 40-foot, or 45-foot marine freight containers. In this regard, the present application imposes no limitations, and reference may also be made to the standards for land freight containers.

Exemplarily, the second cooling apparatus 2021 may be an air conditioning device. Specifically, the second cooling apparatus 2021 may include an evaporation module 20211 and a condensation module 20212, a refrigerant flowing in a circulating manner between the evaporation module 20211 and the condensation module 20212, and phase change taking place in the evaporation module 20211 and the condensation module 20212 respectively.

In a specific example, the refrigerant may be R22, R410A, R32, R290, or the like. The condensation module 20212 includes a condensing unit, at which the refrigerant is adapted to change from a gaseous state to a liquid state to implement condensation and heat release; and the evaporation module 20211 includes an evaporator, at which the refrigerant is adapted to change from a liquid state to a gaseous state to implement evaporation and heat absorption. It can be understood that air flowing through the evaporator exchanges heat with the refrigerant and is converted into cold air, which is then transported to the inside of the computing device enclosure 2080.

In the embodiment of the present application, the data center 2001 may include a plurality of computing devices 2020, each including at least one server module. A plurality of first cooling apparatuses 2022 are provided, which are integrated with corresponding computing devices 2020 for providing cooling to the server modules of the corresponding computing devices 2020. A cooling method of the first cooling apparatuses 2022 may be immersion liquid cooling. That is, the server modules may be directly immersed in the cooling working medium to exchange heat with the cooling working medium. By employing immersion liquid cooling as the cooling method, heat generated by the server modules can be efficiently transferred to the cooling working medium, which, compared with air cooling or water cooling methods usually employed in related technologies, significantly improves the cooling efficiency of the first cooling apparatuses 2022 for the server modules without providing thermal interface materials, heat sinks, fans and other components, and is also conducive to achieving energy conservation and environmental protection.

According to the above implementation, by integrating within the computing device enclosure 2080 the second cooling apparatus 2021 for cooling the inside of the computing device enclosure 2080 and the first cooling apparatus 2022 for cooling the server module of the computing device 2020, the cooling range of the data center 2001 is thus increased, which can not only ensure the working stability of the server module at a suitable and constant temperature, but also dissipate heat from the internal space of the computing device enclosure 2080, thereby implementing overall cooling of the data center 2001 and then meeting the temperature comfort requirements of the staff working inside the computing device enclosure 2080.

In an implementation, as shown in FIG. 34, the data center 2001 of the embodiment of the present application further includes a cold source device 2060 for providing cooling to the cooling device.

In the embodiment of the present application, the cold source device 2060 is used both for providing a cold source to the second cooling apparatus 2021 and for providing a cold source to the first cooling apparatus 2022. The cold source device 2060 may be a cooling tower or a dry cooler, or may be a combination of a cooling tower and a dry cooler.

With the above implementation, by utilizing the cold source device 2060 to provide a cold source to the second cooling apparatus 2021, there is no need to dispose an outdoor unit for the second cooling apparatus 2021 in an external space of the computing device enclosure 2080, thereby reducing the occupation of the external space of the computing device enclosure 2080 and also decreasing the machining difficulty of the computing device enclosure 2080.

In an implementation, as shown in FIG. 34, the second cooling apparatus 2021 includes an evaporation module 20211 and a condensation module 20212, a refrigerant flowing in a circulating manner between the evaporation module 20211 and the condensation module 20212, and the refrigerant exchanging heat with air at the evaporation module 20211 to decrease a temperature of the air and thereby generate cold air; and the cold source device 2060 is used for inputting to the condensation module 20212 a heat exchange medium used for heat exchange with the refrigerant.

Exemplarily, the condensation module 20212 includes a compressor and a condensing unit, the evaporation module 20211 includes an expansion valve, an evaporator and a fan, and a refrigerant circulation pipeline is provided between the condensation module 20212 and the evaporation module 20211. The condensing unit may be a liquid-cooled condenser or a plate heat exchanger. A low-pressure gaseous refrigerant output from the evaporator enters the compressor through the refrigerant circulation pipeline; after being compressed by the compressor, the low-pressure gaseous refrigerant is converted into a high-pressure gaseous refrigerant and transported to the condensing unit; after being condensed at the condensing unit, the high-pressure gaseous refrigerant is converted into a high-pressure liquid refrigerant, and then enters the expansion valve through the refrigerant circulation pipeline; the high-pressure liquid refrigerant is converted into a low-pressure liquid refrigerant through the throttling effect of the expansion valve and transported to the evaporator; the low-pressure liquid refrigerant absorbs heat and evaporates at the evaporator, is converted into a low-pressure gaseous refrigerant and transported to the compressor again, so as to implement circulation. The air guided by the fan to the evaporator exchanges heat with the refrigerant to form cold air, which is then transported to the inside of the computing device enclosure 2080.

A first heat exchange flow path is provided between the cold source device 2060 and the second cooling apparatus 2021 for allowing the heat exchange medium to flow in a circulating manner between the cold source device 2060 and the condensation module 20212 of the second cooling apparatus 2021; and a second heat exchange flow path is provided between the cold source device 2060 and the first cooling apparatus 2022 for allowing the cooling working medium to flow in a circulating manner between the cold source device 2060 and the first cooling apparatus 2022.

In the embodiment of the present application, the cold source device 2060 may employ any cooling method to cool the heat exchange medium to form a low-temperature heat exchange medium and transport the same to the condensation module 20212 of the second cooling apparatus 2021. For example, the cold source device 2060 may employ air cooling or water cooling to cool the heat exchange medium. For example, when the low-temperature heat exchange medium is cold air, the cold air is blown directly to the condensation module 20212, causing a gaseous refrigerant within the condensation module 20212 to liquefy; and when the low-temperature heat exchange medium is a low-temperature liquid (e.g., water), the low-temperature liquid may be sprayed to the condensation module 20212, or the condensation module 20212 may be immersed in the low-temperature liquid, causing the gaseous refrigerant within the condensation module 20212 to liquefy.

In an implementation, the cold source device 2060 includes a cooling tower that cools the heat exchange medium with a liquid medium.

Exemplarily, the cooling tower includes a spray water system, cooling packing, and a liquid-cooled coil for allowing the heat exchange medium to flow, the spray water system is used for spraying the liquid medium to the cooling packing so that the liquid medium is cooled by the cooling packing, and the cooled liquid medium flows through the liquid cooling coil and exchanges heat with the heat exchange medium within the liquid cooling coil to cool the heat exchange medium. The liquid medium may be cooling water.

In one example, the heat exchange medium may specifically be a cooling working medium. One liquid cooling coil is provided, and an output end of the liquid cooling coil is in communication with the condensation module 20212 of the second cooling apparatus 2021 and the first cooling apparatus 2022 respectively through the first heat exchange flow path and the second heat exchange flow path, so as to transport the cooling working medium to the condensation module 20212 of the second cooling apparatus 2021 and the first cooling apparatus 2022 respectively.

In another example, the heat exchange medium may specifically be cooling water. Two liquid cooling coils are provided, which are a first liquid cooling coil and a second liquid cooling coil respectively. The first liquid cooling coil is used for allowing the cooling water to flow in a circulating manner, and an output end of the first liquid cooling coil is connected with the condensation module 20212 of the second cooling apparatus 2021 for supplying the cooling water to the condensation module 20212 of the second cooling apparatus 2021; and the second liquid cooling coil is used for allowing the cooling working medium to flow in a circulating manner, and an output end of the second liquid cooling coil is in communication with the first cooling apparatus 2022 for transporting the cooling working medium to the first cooling apparatus 2022.

In an implementation, the cold source device 2060 includes a dry cooler that cools the heat exchange medium with a gaseous medium.

Exemplarily, the dry cooler includes a heat exchange coil for allowing the heat exchange medium to flow, and a fan assembly for drawing the gaseous medium to a surface of the heat exchange coil so that the gaseous medium exchanges heat with the heat exchange medium within the heat exchange coil. The gaseous medium may specifically be air.

In one example, the heat exchange medium may specifically be a cooling working medium. One heat exchange coil is provided, and an output end of the heat exchange coil is in communication with the condensation module 20212 of the second cooling apparatus 2021 and the first cooling apparatus 2022 respectively through the first heat exchange flow path and the second heat exchange flow path, so as to transport the cooling working medium to the condensation module 20212 of the second cooling apparatus 2021 and the first cooling apparatus 2022 respectively.

In another example, the heat exchange medium may specifically be cooling water. Two heat exchange coils are provided, which are a first heat exchange coil and a second heat exchange coil respectively. The first heat exchange coil is used for allowing the cooling water to flow in a circulating manner, and an output end of the first heat exchange coil is connected with the condensation module 20212 of the second cooling apparatus 2021 for supplying the cooling water to the condensation module 20212 of the second cooling apparatus 2021; and the second heat exchange coil is used for allowing the cooling working medium to flow in a circulating manner, and an output end of the second heat exchange coil is in communication with the first cooling apparatus 2022 for transporting the cooling working medium to the first cooling apparatus 2022.

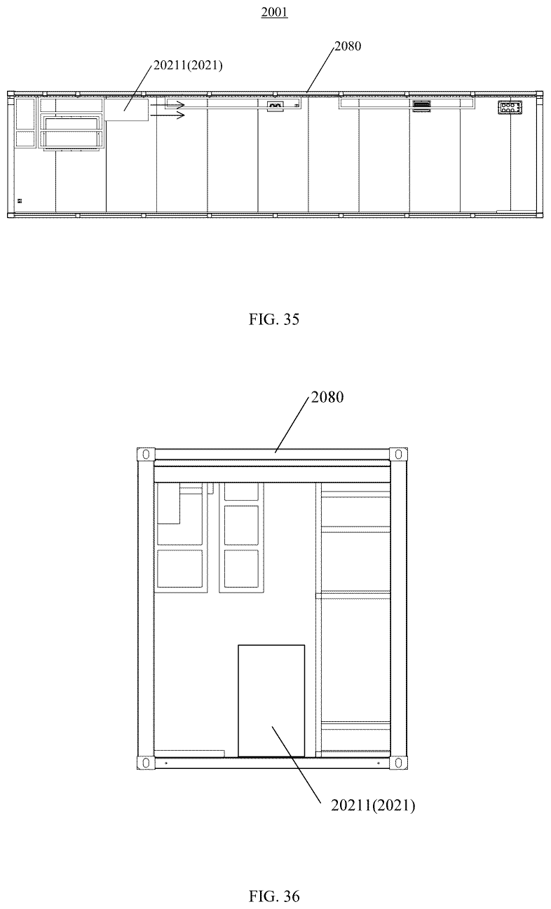

In an implementation, as shown in FIG. 35, the evaporation module 20211 is mounted to a top wall of the computing device enclosure 2080.

Exemplarily, the top wall of the computing device enclosure 2080 is provided with a mounting bracket, on which the evaporation module 20211 is borne and fixed. Specifically, the mounting bracket includes connecting beams and bearing beams, the connecting beams extending along the vertical direction and having upper ends connected to the top wall of the computing device enclosure 2080; and the bearing beams being provided as two bearing beams disposed side by side along the horizontal direction and respectively connected to lower ends of the connecting beams. The evaporation module 20211 is borne on the two bearing beams and is fixedly connected with the two bearing beams by fasteners.

In an implementation, the evaporation module 20211 is mounted on a bottom wall or side wall of the computing device enclosure 2080.

Exemplarily, the evaporation module 20211 may be an upright cabinet unit and be fixedly connected with the bottom wall or side wall of the computing device enclosure 2080 by fasteners.

In an implementation, as shown in FIG. 36, a plurality of first cooling apparatuses 2022 are provided, which are disposed in two rows at intervals in a first direction, the evaporation module 20211 being centered in the first direction.

In the embodiment of the present application, the first direction may be a width direction of the computing device enclosure 2080, and a second direction may be a length direction of the computing device enclosure 2080.

Exemplarily, the first cooling apparatus 2022 includes a housing, inside of which defines a cooling chamber for accommodating at least one server module. The cooling chamber contains a cooling working medium, and at least one server module is immersed in the cooling working medium. The plurality of first cooling apparatuses 2022 are arranged in two rows at intervals along the width direction of the computing device enclosure 2080, each row including a plurality of first cooling apparatuses 2022 arranged along the second direction. The plurality of first cooling apparatuses 2022 in each row may be arranged at multiple layers in a stacked manner along the vertical direction. A maintenance passage is defined between the two rows of first cooling apparatuses 2022, and the evaporation module 20211 is centered in the length direction of the computing device enclosure 2080, so as to output cold air to the maintenance passage.

Optionally, as shown in FIG. 36, the number of evaporation modules 20211 is one, and the evaporation module 20211 is disposed close to an end of the computing device enclosure 2080 in the second direction that is perpendicular to the first direction.

Exemplarily, the evaporation module 20211 may be provided at an end of the computing device enclosure 2080 in the length direction, and an air outlet direction of the evaporation module 20211 is disposed towards the other end of the computing device enclosure 2080 in the length direction, so that the output cold air flows through the internal space of a first sub-enclosure 2012 as much as possible. Further, the evaporation module 20211 may be centered in the width direction of the computing device enclosure 2080.

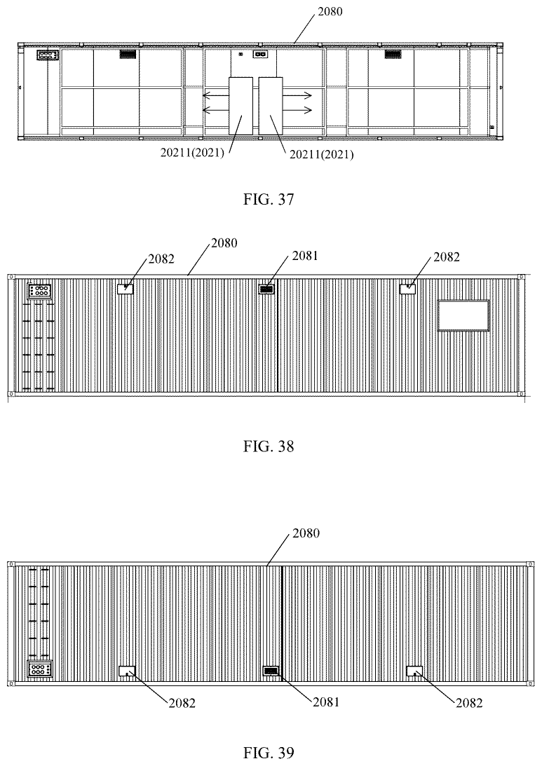

Optionally, as shown in FIG. 37, two evaporation modules 20211 are provided, and the two evaporation modules 20211 are disposed close to a middle portion of the computing device enclosure 2080 in the second direction, with air outlet directions of the two evaporation modules 20211 being opposite.

Exemplarily, the two evaporation modules 20211 are centered in the length direction of the computing device enclosure 2080, and the air outlet directions of the two evaporation modules 20211 are disposed oppositely, so as to transport cold air to corresponding regions of the two evaporation modules 20211 respectively. In addition, one condensation module 20212 may be provided, which is in communication with the two evaporation modules 20211 through a refrigerant flow path for condensing the refrigerant in the two evaporation modules 20211 respectively. Alternatively, two condensation modules 20212 may also be provided, which are in communication with the two evaporation modules 20211 through corresponding refrigerant flow paths.

In an implementation, as shown in FIGS. 38 and 39, at least one of two side walls of the computing device enclosure 2080 disposed oppositely in the first direction is provided with an air inlet 2081 that is positioned in the second direction corresponding to the evaporation module 20211.

Exemplarily, two side walls of the computing device enclosure 2080 disposed oppositely in the width direction are respectively provided with an air inlet 2081 for guiding air into the inside of the computing device enclosure 2080. Further, the air inlet 2081 is positioned in the length direction of the computing device enclosure 2080 corresponding to the evaporation module 20211, and positioned in the vertical direction corresponding to the fan assembly of the evaporation module 20211, so that the fan assembly can guide external air to the evaporator through the air inlet 2081.

Optionally, as shown in FIGS. 38 and 39, at least one of the two side walls of the computing device enclosure 2080 disposed oppositely in the first direction is provided with an air outlet 2082 that is disposed apart from the air inlet 2081 in the second direction.

Exemplarily, the two side walls of the computing device enclosure 2080 disposed oppositely in the width direction are respectively provided with an air outlet 2082, and two air outlets 2082 may be provided on each side wall, which are respectively located on two sides of the air inlet 2081 in the length direction of the computing device enclosure 2080. It can be understood that the air outlets 2082 are used for guiding the air inside the computing device enclosure 2080 to the outside.

With the above implementation, the airflow inside the computing device enclosure 2080 can be improved, thereby further enhancing the cooling effect inside the computing device enclosure 2080.

It should be noted that in the embodiment of the present application, the height position of the air inlet 2081 and the air outlets 2082 in the computing device enclosure 2080 may be correspondingly set according to the position of the evaporation module 20211 of the second cooling apparatus 2021. For example, in a case where the evaporation module 20211 is mounted to the top wall of the computing device enclosure 2080, as shown in FIG. 38, the air inlet 2081 and the air outlets 2082 are disposed close to the top of the computing device enclosure 2080. For another example, in a case where the evaporation module 20211 is mounted to the bottom wall or side wall of the computing device enclosure 2080, as shown in FIG. 39, the air inlet 2081 and the air outlets 2082 are disposed close to the bottom of the computing device enclosure 2080.

Optionally, the air inlet 2081 is provided with an intake fan; and/or, the air outlet 2082 is provided with an exhaust fan.

Exemplarily, the air inlet 2081 and the air outlet 2082 are provided with an intake fan and an exhaust fan respectively. A flow guide direction of the intake fan of the air inlet 2081 is disposed towards the inside of the computing device enclosure 2080, and a flow guide direction of the exhaust fan of the air outlet 2082 is disposed towards the outside of the computing device enclosure 2080, so as to improve the air exchange efficiency inside the computing device enclosure 2080.

Optionally, the air inlet 2081 is provided with an air intake grille; and/or, the air outlet 2082 is provided with an air exhaust grille.

Exemplarily, the air inlet 2081 and the air outlet 2082 are provided with an air intake grille and an air exhaust grille respectively. The air intake grille and the air exhaust grille respectively include: a plurality of flow guide plates arranged at intervals along the horizontal direction, each extending along the vertical direction; and two mounting plates, two ends of each flow guide plate being rotatably connected to the two mounting plates. It can be understood that the flow guide plates are rotatable to open and closed positions, and when the plurality of flow guide plates are rotated to the open position, a flow guide gap is formed between two adjacent flow guide plates, so that air can flow through the air inlet 2081 or the air outlet 2082; and when the plurality of flow guide plates are rotated to the closed position, two adjacent flow guide plates are spliced with each other, so that air cannot flow through the air inlet 2081 or the air outlet 2082.

As another aspect of the embodiments of the present application, an embodiment of the present application further provides a container data center 2001. The container data center 2001 includes a computing device enclosure 2080. The computing device enclosure 2080 is configured with a data center 2001 as described in any of the above implementations of the present application.

In an implementation, as shown in FIG. 34, the container data center 2001 further includes a cold source device enclosure 2070, inside which the cold source device 2060 is integrally deployed.

Exemplarily, the cold source device enclosure 2070 may be correspondingly shaped and sized with reference to the computing device enclosure 2080. Optionally, the cold source device enclosure 2070 may likewise be correspondingly provided with reference to the specifications of a marine freight container, which, for example, may have the same shape and size as 20-foot, 40-foot, or 45-foot marine freight containers. In this regard, the present application imposes no limitations, and reference may also be made to the standards for land freight containers.

In a specific example, the shape and size of both the computing device enclosure 2080 and the cold source device enclosure 2070 may be referenced to a 40-foot marine freight container, with overall external dimensions of 12.192 m×2.438 m×2.438 m. Thus, the data center 2001 of the embodiment of the present application may directly load and transport the computing device enclosure 2080 and the cold source device enclosure 2070 by means of marine transportation, which improves the convenience of transportation.

Optionally, the condensation module 20212 is provided inside the cold source device enclosure 2070.

Exemplarily, the condensation module 20212 may be integrated with the cold source device 2060. Specifically, the cold source device 2060 includes a first heat exchange assembly and a second heat exchange assembly. The first heat exchange assembly includes: a heat exchange coil for allowing a cooling working medium to flow, so that the cooling working medium exchanges heat with a gaseous medium; and a fan assembly for drawing a gaseous medium from the outside of the cold source device 2060 to the inside of the cold source device 2060, and causing the gaseous medium to flow through the heat exchange coil, so that heat exchange takes place between the gaseous medium and the cooling working medium in the heat exchange coil. The second heat exchange assembly is the condensation module 20212 of the second cooling apparatus 2021, and the second heat exchange assembly includes a compressor, a condensing unit and a liquid storage tank. The condensing unit is in communication with an output end of the first heat exchange assembly through a cooling working medium pipeline, and in communication with the evaporation module 20211 through a refrigerant pipeline. The cooling working medium cooled by the first heat exchange assembly exchanges heat with the refrigerant at the condensing unit. The condensing unit may specifically be a liquid-cooled condenser or a plate heat exchanger.

As another aspect of the embodiments of the present application, an embodiment of the present application further provides a container data center 2001. The container data center 2001 includes a cold source device enclosure and a computing device enclosure 2080. Specifically, the cold source device enclosure is configured with a cold source device, and the computing device enclosure 2080 is configured with a data center 2001 as described in any of the above implementations of the present application.

Optionally, the cold source device enclosure 2070 is detachably connected to an upper side of the computing device enclosure 2080.

Exemplarily, a bottom of the cold source device enclosure 2070 is provided with an interlocking fit member, and a top of the computing device enclosure 2080 is provided with an interlocking fit aperture. The interlocking fit member is adapted to protrude into the interlocking fit aperture and is fixedly connected with the interlocking fit aperture by a fastener.

It can be understood that in a transportation process of the data center 2001, the computing device enclosure 2080 and the cool source device enclosure 2070 may be detached and loaded separately for transportation. After transportation to a designated location, the cold source device enclosure 2070 can be mounted to the upper side of the computing device enclosure 2080, and delivery can be completed directly after pipeline connection.

Thus, the transportation convenience and delivery efficiency of the data center 2001 are enhanced.

Optionally, the computing device enclosure 2080 defines an enclosed cavity, and the cold source device enclosure 2070 employs a framework structure to define an open cavity.

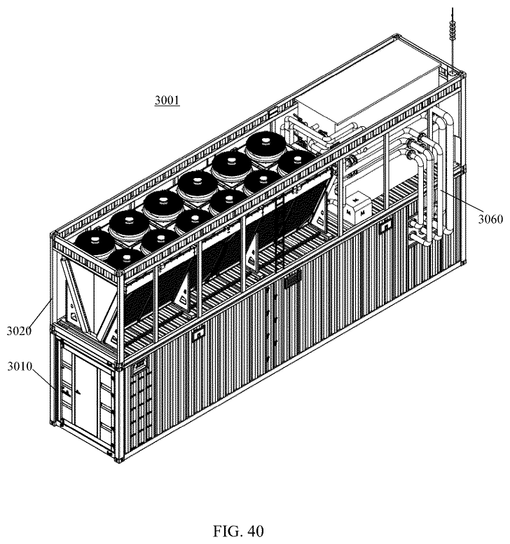

As a sixth aspect of the embodiments of the present application, an enclosure structure according to an embodiment of the present application will be described below with reference to FIGS. 40 to 49. The enclosure structure of the embodiment of the present application may be used in a data center 3001, and a cooling system and a computing device 3030 of the data center 3001 are integrally deployed inside the enclosure structure.

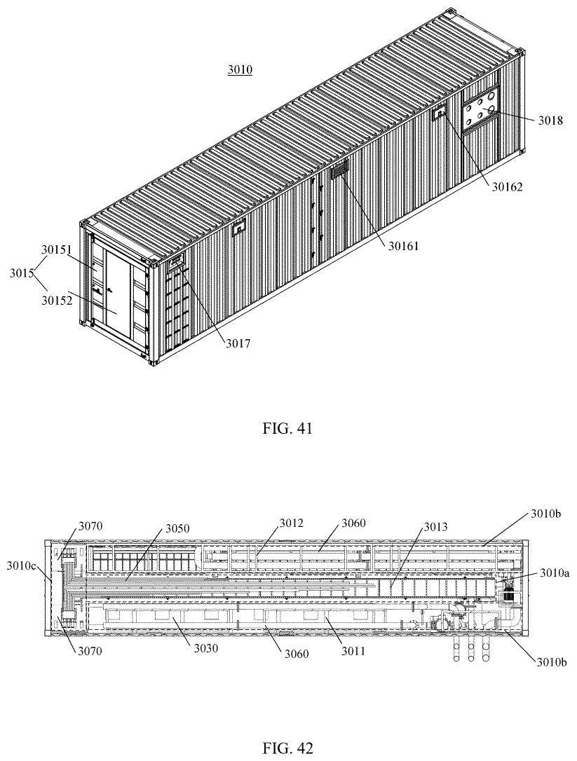

As shown in FIGS. 40 and 41, the data center according to the embodiment of the present application includes a computing device enclosure 3010. Specifically, the computing device enclosure 3010 defines an enclosed cavity for accommodating the computing device 3030 of the data center 3001, the computing device 3030 including a server module and a cooling apparatus for cooling the server module.

In an implementation, as shown in FIG. 42, the inside of the computing device enclosure 3010 has a cable mounting region 3010a and a pipeline mounting region 3010b, which are disposed apart in a first horizontal direction, the cable mounting region 3010a is used for mounting a cable 3050, and the pipeline mounting region 3010b is used for mounting a cooling pipeline 3060 that is connected between the cooling apparatus of the computing device 3030 and the cold source device 3040 of the data center 3001 for allowing a cooling working medium to flow.

In the description of the specification of the present application, the first horizontal direction may be a width direction of the computing device enclosure 3010, and a second horizontal direction may be a length direction of the computing device enclosure 3010, which will not be repeatedly defined below.

Exemplarily, the cable mounting region 3010a and the pipeline mounting region 3010b are disposed apart in the width direction of the computing device enclosure 3010. The cable mounting region 3010a and the pipeline mounting region 3010b extend in the length direction of the computing device enclosure 3010, so as to mount the cable 3050 and the cooling pipeline 3060 respectively, which are disposed along the length direction of the computing device enclosure 3010. It can be understood that there may be a plurality of cables 3050 disposed corresponding to a plurality of computing devices 3030 for connecting a power distribution cabinet 3070 and a corresponding computing device 3030, so as to transmit electrical power distributed by the power distribution cabinet 3070 to the corresponding computing device 3030. The cooling pipeline 3060 is connected between the computing device 3030 and the cold source device 3040 for allowing the cooling working medium to flow in a circulating manner between the cooling apparatus of the computing device 3030 and the cold source device 3040. Further, the plurality of computing devices 3030 may be disposed side by side along the length direction of the computing device enclosure 3010. Based on this, the piping mounting region 3010b is adapted to extend along the length direction of the computing device enclosure 3010, so that the cooling pipeline 3060 mounted in the pipeline mounting region 3010b can transport the cooling working medium to the cooling apparatus of each computing device 3030.

With the above implementation, isolation of liquid and power supply to the data center 3001 can be implemented in physical space, avoiding water and electricity contact caused by leakage in the cooling pipeline 3060, thereby decreasing the probability of safety hazards.

Optionally, as shown in FIG. 42, two pipeline mounting regions 3010b are provided, which are located on two sides of the cable mounting region 3010a in the first horizontal direction.

Exemplarily, the two pipeline mounting regions 3010b are respectively disposed close to two side walls of the computing device enclosure 3010 disposed oppositely in the width direction, and a certain spacing is reserved for the two pipeline mounting regions 3010b in the width direction of the computing device enclosure 3010, so that the cable mounting region 3010a can be arranged between the two pipeline mounting regions 3010b.

In one example, the plurality of computing devices 3030 are arranged in two rows in the width direction of the computing device enclosure 3010, each row including a plurality of computing devices 3030 arranged side by side along the length direction of the computing device enclosure 3010. The two pipeline mounting regions 3010b are disposed respectively corresponding to the two rows of computing devices 3030, and a cooling pipeline 3060 mounted on each pipeline mounting region 3010b is respectively connected with cooling apparatuses of a plurality of computing devices 3030 in a corresponding row.

Optionally, the cable mounting region 3010a is disposed close to a top wall of the computing device enclosure 3010 and located above the pipeline mounting region 3010b.

Exemplarily, the cable mounting region 3010a and the pipeline mounting region 3010b are respectively disposed close to the top wall of the computing device enclosure 3010, so as to form clearance for a plurality of computing devices 3030 close to a bottom wall of the computing device enclosure 3010. The cable mounting region 3010a is disposed closer to the top wall of the computing device enclosure 3010 than the pipe mounting region 3010b, so that the cable 3050 mounted in the cable mounting region 3010a is positioned in the vertical direction above the cooling pipeline 3060 mounted in the pipeline mounting region 3010b.

Such arrangement can avoid the leaked cooling working medium from the cooling pipeline 3060 from splashing onto the cable 3050 when leakage occurs in the cooling pipeline 3060, thereby implementing physical isolation between the cooling pipeline 3060 and the cable 3050 in the vertical direction and further improving safety.

Optionally, the inside of the computing device enclosure 3010 further has a power distribution cabinet mounting region 3010c for mounting the power distribution cabinet 3070. The power distribution cabinet mounting region 3010c is disposed apart from the pipeline mounting region 3010b and the cable mounting region 3010a in the second horizontal direction that is perpendicular to the first horizontal direction. The power distribution cabinet 3070 is used for distributing electrical power to the computing device 3030, the cold source device 3040 and other powered facilities of the data center 3001.

Exemplarily, the inside of the computing device enclosure 3010 further has a computing device 3030 mounting region for mounting the computing device 3030. The power distribution cabinet mounting region 3010c and the computing device 3030 mounting region are disposed side by side in the length direction of the computing device enclosure 3010. More specifically, the computing device 3030 mounting region is arranged on a side of the enclosed cavity in the length direction of the computing device enclosure 3010, and the power distribution cabinet mounting region 3010c is arranged on the other side of the enclosed cavity in the length direction of the computing device enclosure 3010.

More specifically, the power distribution cabinet mounting region 3010c and the cable mounting region 3010a are connected in the length direction of the computing device enclosure 3010, so that the cable 3050 mounted in the cable mounting region 3010a can extend to the power distribution cabinet mounting region 3010c and be electrically connected with the power distribution cabinet 3070 mounted in the power distribution cabinet mounting region 3010c. The power distribution cabinet mounting region 3010c and the pipeline mounting region 3010b are spaced apart in the length of the computing device enclosure 3010, so as to implement isolation between the power distribution cabinet 3070 and the cooling pipeline 3060 mounted in the pipeline mounting region 3010b in physical space.

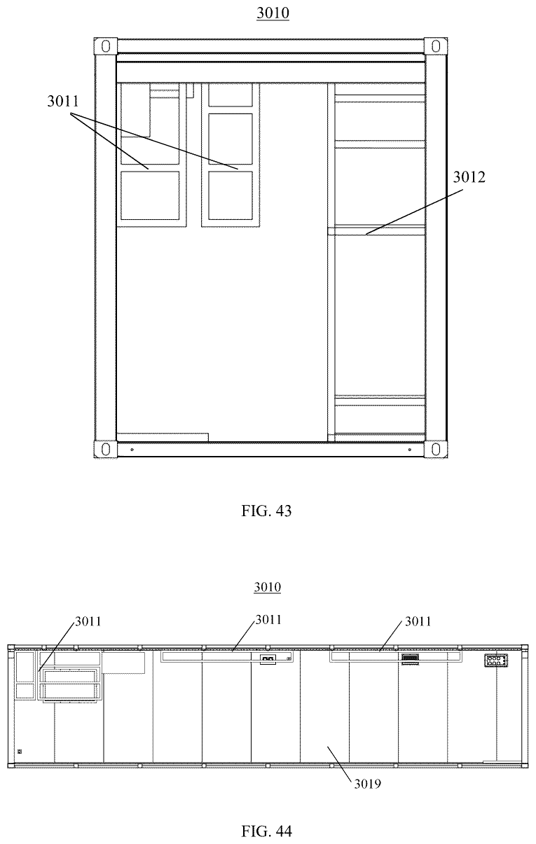

In an implementation, as shown in FIG. 43, the inside of the computing device enclosure 3010 is provided with a mounting bracket for mounting at least one of the cooling pipeline 3060, the computing device 3030, and the cable 3050. In other words, at least one of the pipeline mounting region 3010b, the computing device 3030 mounting region, and the cable mounting region 3010a may be defined by the mounting bracket.

Exemplarily, the mounting bracket may be fixedly connected with a wall body of the computing device enclosure 3010 by fasteners or welding, which is not specifically defined in the embodiments of the present application.

Optionally, the mounting bracket includes a first bracket 3011 for mounting the cooling pipeline 3060, and a second bracket 3012 for mounting the computing device 3030 and the cooling pipeline 3060. The first bracket 3011 and the second bracket 3012 are disposed apart in the first horizontal direction.

Exemplarily, the first bracket 3011 defines a first cooling pipeline 3060 mounting region 3010b, and the second bracket 3012 defines a computing device 3030 mounting region and a second cooling pipeline 3060 mounting region. The computing device 3030 mounting region and the second cooling pipeline 3060 mounting region 3010b are correspondingly disposed in the vertical direction, and the first cooling pipeline 3060 mounting region 3010b and the second cooling pipeline 3060 mounting region 3010b are disposed apart in the width direction of the computing device enclosure 3010.

In a specific example, the first bracket 3011 is fixedly connected to the top wall of the computing device enclosure 3010. The first bracket 3011 includes a first connecting beam and a first bearing beam. Two first connecting beams are provided and have upper ends fixedly connected to the top wall of the computing device enclosure 3010. Two ends of the first bearing beam are respectively connected to lower ends of the two first connecting beams. The cooling pipeline 3060 is borne on an upper wall face of the first bearing beam.

The second bracket 3012 is fixedly connected to the bottom wall or side wall of the computing device enclosure 3010. The second bracket 3012 includes a structural vertical beam fixedly connected to the bottom wall or side wall of the computing device enclosure 3010, and a second bearing beam including a plurality of second bearing cross beams and a plurality of second bearing longitudinal beams, the second bearing cross beams extending along the length direction of the computing device enclosure 3010 and connected to a plurality of structural vertical beams, the plurality of second bearing longitudinal beams extending along the width direction of the computing device enclosure 3010, and the plurality of second bearing longitudinal beams arranged side by side along the length direction of the computing device enclosure 3010 and connected to two oppositely disposed second bearing cross beams. The computing device 3030 is borne on the plurality of second bearing longitudinal beams.

Further, as shown in FIG. 43, the first bracket 3011 and the second bracket 3012 are respectively disposed close to two sides of the computing device enclosure 3010 in the first horizontal direction.

Exemplarily, the first bracket 3011 is disposed close to a side of the enclosed cavity located in the width direction of the computing device enclosure 3010, and the second bracket 3012 is disposed close to the other side of the enclosed cavity located in the width direction of the computing device enclosure 3010. The cable mounting region 3010a is formed between the first bracket 3011 and the second bracket 3012.

Further, as shown in FIGS. 43 and 44, the first brackets 3011 are in two rows disposed apart in the first horizontal direction, each row including a plurality of first brackets 3011 disposed side by side along the second horizontal direction.

Exemplarily, the first brackets 3011 are in two rows disposed apart in the width direction of the computing device enclosure 3010, each row including a plurality of first brackets 3011 arranged side by side along the length direction of the computing device enclosure 3010. The two rows of first brackets 3011 define corresponding pipeline mounting regions 3010b respectively. The cooling pipeline 3060 includes a liquid supply pipeline and a liquid return pipeline. A pipeline mounting region 3010b defined by one row of first brackets 3011 is used for mounting the liquid supply pipeline, and a pipeline mounting region 3010b defined by the other row of first brackets 3011 is used for mounting the liquid return pipeline. A plurality of first computing devices 3030 are integrally deployed on lower sides of two first brackets 3011. The liquid supply pipeline is used for transporting the cooling working medium to a cooling apparatus of each first computing device 3030, and the liquid return pipeline is used for transporting the cooling working medium within a cooling apparatus of each first computing device 3030 to the cold source device 3040.

Further, the second bracket 3012 includes a pipeline mounting layer and a device mounting layer, which are disposed apart in the vertical direction. The pipeline mounting layer is located above the device mounting layer for mounting the cooling pipeline 3060, and the device mounting layer is used for mounting the computing device 3030.

Exemplarily, the second bracket 3012 defines two computing device 3030 mounting regions, which are disposed apart in the vertical direction. Each computing device 3030 mounting region includes a pipeline mounting layer and a device mounting layer, which are disposed apart in the vertical direction, the pipeline mounting layer being located above the device mounting layer. The device mounting layer extends along the length direction of the computing device enclosure 3010, so as to mount a plurality of computing devices 3030 arranged side by side along the length direction of the computing device enclosure 3010. The pipeline mounting layer is used for mounting cooling pipelines 3060 that are respectively connected with cooling apparatuses of the plurality of computing devices 3030 on the corresponding device mounting layer.

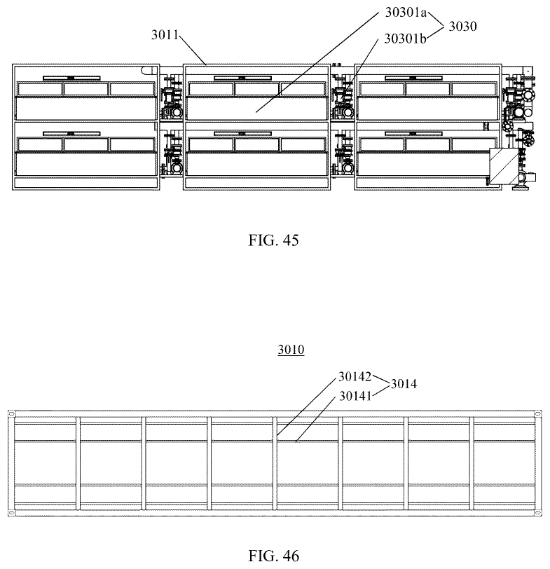

Further, as shown in FIG. 45, the cooling apparatus of the computing device 3030 includes a cooling housing 30301a for containing the cooling working medium that immerses the server module, and a powertrain 30301b for providing circulation power for the cooling working medium. The cooling housing 30301a and the powertrain 30301b are both mounted on the device mounting layer.

Exemplarily, the powertrain 30301b may include a pump body, a liquid supply flow path and a liquid return flow path, the liquid supply flow path being connected with the liquid supply pipeline of the cooling pipeline 3060, the liquid return flow path being connected with the liquid return pipeline of the cooling pipeline 3060, and the pump body is used for providing power to the cooling working medium within the liquid supply flow path or the liquid return flow path. The cooling housing 30301a and the powertrain 30301b are integrated in the horizontal direction and adjoin each other in the length direction of the computing device enclosure 3010. The cooling housing 30301a and the powertrain 30301b are jointly borne on the device mounting layer of the second bracket 3012.

Optionally, the powertrain 30301b is disposed at an end of the cooling housing 30301a away from the power distribution cabinet. Such arrangement makes the pipeline connection between the powertrain 30301b and the cooling housing 30301a away from the power distribution cabinet, avoiding an impact of the leaking liquid from the pipeline on the power distribution cabinet.

Optionally, as shown in FIG. 42, the mounting bracket further includes a cable mounting bracket 3013 fixed to the top wall of the computing device enclosure 3010 and used for mounting the cable 3050. The cable mounting bracket 3013 is located between the first bracket 3011 and the second bracket 3012 in the first horizontal direction.

Exemplarily, the cable mounting bracket 3013 is suspended from the top wall of the enclosure. The cable mounting region 3010a is defined by the cable mounting bracket 3013 for mounting a plurality of cables connected between the power distribution cabinet 3070 and the computing devices 3030. The plurality of computing devices 3030 integrally deployed within the computing device enclosure 3010 may be designed side by side along the length direction of the computing device enclosure 3010. Correspondingly, the cable mounting bracket 3013 extends in the length direction of the computing device enclosure 3010, so as to mount the plurality of cables 3050 extending along the length direction of the computing device enclosure 3010.

In a specific example, a plurality of first computing devices 3030 and a plurality of second computing devices 3030 are integrally deployed inside the computing device enclosure 3010. The plurality of first computing devices 3030 are disposed close to a side of the enclosed cavity in the width direction of the computing device enclosure 3010, and the plurality of second computing devices 3030 are disposed close to the other side of the enclosed cavity in the width direction of the computing device enclosure 3010. The inside of the computing device enclosure 3010 has two device mounting regions for mounting the plurality of first computing devices 3030 and the plurality of second computing devices 3030 respectively.

Two power distribution cabinets 3070 are further integrally deployed inside the computing device enclosure 3010, one of which is disposed side by side with the plurality of first computing devices 3030 in the length direction of the computing device enclosure 3010 for distributing electrical power to the plurality of first computing devices 3030, and the other of which is disposed side by side with the plurality of second computing devices 3030 in the length direction of the computing device enclosure 3010 for distributing electrical power to the plurality of second computing devices 3030. The inside of the computing device enclosure 3010 further has a power distribution cabinet mounting region 3010c for mounting the two power distribution cabinets 3070. The two device mounting regions are disposed side by side and apart in the width direction of the computing device enclosure 3010, and the power distribution cabinet mounting region 3010c and the two device mounting regions are disposed side by side and apart in the length direction of the computing device enclosure 3010.

The cable mounting bracket 3013 is located between the first bracket 3011 and the second bracket 3012 in the width direction of the computing device enclosure 3010, and the defined cable mounting region 3010a is located between the two device mounting regions for mounting the plurality of cables 3050 between the two power distribution cabinets 3070 and the corresponding plurality of computing devices 3030.

Optionally, as shown in FIG. 46, the mounting bracket further includes a bottom support frame body 3014, which has a preset gap with the bottom wall of the computing device enclosure 3010.

Exemplarily, the bottom support frame body 3014 is used for supporting the power distribution cabinets 3070, the computing devices 3030 and other devices deployed within the computing device enclosure 3010. The preset gap between the bottom support frame body 3014 and the bottom wall of the computing device enclosure 3010 may be 10 cm to 20 cm. It can be understood that in a case where leakage occurs in the cooling pipeline 3060, the leaked cooling working medium may converge to a space between the bottom support frame body 3014 and the bottom wall of the computing device enclosure 3010, which can prevent, to some extent, the leaked cooling working medium from flowing to the power distribution cabinets 3070 and other devices borne on the bottom support frame body 3014, thereby further enhancing electrical safety.

Further, the bottom support frame body 3014 includes a plurality of first support beams 30141 disposed at intervals in the first horizontal direction and a plurality of second support beams 30142 disposed at intervals in the second horizontal direction, the second support beams 30142 being lapped over the plurality of first support beams 30141.

Exemplarily, the plurality of first support beams 30141 are disposed side by side at intervals in the width direction of the computing device enclosure 3010, and each first support beam 30141 extends along the length direction of the computing device enclosure 3010. The plurality of second support beams 30142 are disposed side by side at intervals in the length direction of the computing device enclosure 3010, and each second support beam 30142 extends along the width direction of the computing device enclosure 3010. Each second support beam 30142 is lapped over the plurality of first support beams 30141, and the second support beam 30142 and the first support beams 30141 may be fixedly connected by fasteners, or may be fixedly connected by welding.

In an implementation, an inner wall of the computing device enclosure 3010 is provided with a mounting groove for fixing a power distribution unit of the computing device 3030.

Exemplarily, each computing device 3030 is provided with a corresponding power distribution unit for providing electrical power to the server module, the cooling apparatus and other powered facilities of the computing device 3030. The power distribution unit is electrically connected with the cable 3050 to provide electrical power distributed by the power distribution cabinet 3070 to the computing device 3030 through the cable 3050 and the power distribution unit. The mounting groove is formed by inwardly recessing the inner wall of the computing device enclosure 3010, and the mounting groove is positioned in the vertical and horizontal directions corresponding to the computing device 3030.

In addition, in other examples of the present application, the power distribution unit of the computing device 3030 may also be integrated inside the computing device 3030 housing.

In an implementation, as shown in FIG. 41, at least one end of the computing device enclosure 3010 in the second horizontal direction is provided with a door body apparatus 3015 including a first door body 30151 and a second door body 30152. The first door body 30151 is movably provided at a first opening at the end of the computing device enclosure 3010. The first door body 30151 is further provided with a second opening, at which the second door body 30152 is movably provided.

In the embodiment of the present application, at least one end of the computing device enclosure 3010 in the length direction is provided with a first opening, at which a door body apparatus 3015 is provided to open or close the first opening.

In one example, the first door body 30151 includes a monolithic door panel, and a side edge of the monolithic door panel is rotatably connected to a wall body of the computing device enclosure 3010 on a horizontal side at the first opening, so that the monolithic door panel is pivotable relative to the computing device enclosure 3010, thereby opening and closing the first opening. The monolithic door panel is provided with a second opening, to which the second door body 30152 is rotatably connected to open or close the second opening. The second opening may be correspondingly shaped and sized with reference to the devices deployed within the computing device enclosure 3010. For example, the second opening may be correspondingly shaped and sized with reference to the shape and size of the power distribution cabinet 3070, so that the power distribution cabinet 3070 can be transported to the inside of the computing device enclosure 3010 through the opened second opening.

In another example, the first door body 30151 includes two monolithic door panels that are disposed in a confronting and mating manner, and side edges of the two monolithic door panels are rotatably connected to two side wall bodies of the computing device enclosure 3010 at the first opening respectively. The two monolithic door panels are respectively provided with a second opening, and the two second openings are joined together. Two second door bodies 30152 are provided, which are correspondingly provided at the two second openings.

Further, the first door body 30151 or the second door body 30152 is further provided with a shelf groove for placing items, so as to facilitate placement of tools and other items by the staff through the shelf groove.

In an implementation, as shown in FIG. 41, at least one of two side walls of the computing device enclosure 3010 disposed oppositely in the first horizontal direction is provided with an air inlet 30161, and at least one of the two side walls of the computing device enclosure 3010 disposed oppositely in the first horizontal direction is provided with an air outlet 30162 that is disposed apart from the air inlet 30161 in the second horizontal direction.

Exemplarily, two side walls of the computing device enclosure 3010 disposed oppositely in the width direction are respectively provided with an air inlet 30161 for guiding air into the inside of the computing device enclosure 3010. The two side walls of the computing device enclosure 3010 disposed oppositely in the width direction are respectively provided with an air outlet 30162, and two air outlets 30162 may be provided on each side wall, which are respectively located on two sides of the air inlet 30161 in the length direction of the computing device enclosure 3010. It can be understood that the air outlets 30162 are used for guiding the air inside the computing device enclosure 3010 to the outside.

With the above implementation, the airflow inside the computing device enclosure 3010 can be improved, thereby further enhancing the cooling effect inside the computing device enclosure 3010.

Optionally, the air inlet 30161 is provided with an intake fan; and/or, the air outlet 30162 is provided with an exhaust fan.

Exemplarily, the air inlet 30161 and the air outlet 30162 are provided with an intake fan and an exhaust fan respectively. A flow guide direction of the intake fan of the air inlet 30161 is disposed towards the inside of the computing device enclosure 3010, and a flow guide direction of the exhaust fan of the air outlet 30162 is disposed towards the outside of the computing device enclosure 3010, so as to improve the air exchange efficiency inside the computing device enclosure 3010.

Optionally, the air inlet 30161 is provided with an air intake grille; and/or, the air outlet 30162 is provided with an air exhaust grille.

Exemplarily, the air inlet 30161 and the air outlet 30162 are provided with an air intake grille and an air exhaust grille respectively. The air intake grille and the air exhaust grille respectively include: a plurality of flow guide plates arranged at intervals along the horizontal direction, each extending along the vertical direction; and two mounting plates, two ends of each flow guide plate being rotatably connected to the two mounting plates. It can be understood that the flow guide plates are rotatable to open and closed positions, and when the plurality of flow guide plates are rotated to the open position, a flow guide gap is formed between two adjacent flow guide plates, so that air can flow through the air inlet 30161 or the air outlet 30162; and when the plurality of flow guide plates are rotated to the closed position, two adjacent flow guide plates are spliced with each other, so that air cannot flow through the air inlet 30161 or the air outlet 30162.

In an implementation, as shown in FIG. 41, either of the two side walls of the computing device enclosure 3010 disposed oppositely in the first horizontal direction is provided with an electrical power access window 3017; and/or, either of the two side walls of the computing device enclosure 3010 disposed oppositely in the first horizontal direction is provided with a pipeline access window 3018.

Exemplarily, one of the two side walls of the computing device enclosure 3010 disposed oppositely in the width direction thereof is provided with an electrical power access window 3017. The electrical power access window 3017 is used for mounting a cable connection device which is used for connecting to external electrical power input and transport electrical power to the power distribution cabinet 3070 inside the computing device enclosure 3010.

In an implementation, as shown in FIG. 44, the inner wall of the computing device enclosure 3010 is provided with a fireproof board 3019, which employs a thermal insulation material.

Exemplarily, the fireproof board 3019 may specifically be a rock wool board. It can be understood that the rock wool board, also known as rock wool thermal insulation decorative board, is an inorganic fiber board made from basalt as the main raw material and processed by high-temperature melting, which has the characteristics of being lightweight, having a low thermal conductivity, absorbing heat, and being non-combustible.

With the above implementation, the thermal insulation performance of the computing device enclosure 3010 can be improved, which is conducive to keeping a constant temperature in the internal space of the computing device enclosure 3010, and also provides a certain degree of fire resistance.

In an implementation, the top of the computing device enclosure 3010 is provided with a lightning protection apparatus 3025.

Exemplarily, the lightning protection apparatus 3025 includes a lightning arrester, a down conductor, and a grounding apparatus. The lightning arrester employs a metal material, which, for example, may be a metal rod for receiving lightning strikes. The down conductor is a metal conductor connected between the lightning arrester and the grounding apparatus.

With the above implementation, various electrical devices inside the computing device enclosure 3010 can be protected against lightning strikes, further enhancing the safety and reliability of the data center 3001.

In one example, a plurality of cold source devices 3040 are provided and include a first cold source device 3040 and a second cold source device 3040, which employ different cooling methods. The first cold source device 3040 and the second cold source device 3040 are disposed side by side within the open cavity along a length direction of a cold source enclosure 3020.

In addition, the cold source device 3040 further includes a wet curtain disposed on an outer periphery of the cold source enclosure 3020, a wet curtain spray pipe for spraying cooling water to the wet curtain, and a wet curtain water tray provided below the wet curtain to receive the cooling water.

In an implementation, the cold source enclosure 3020 includes a bottom beam frame 3023, above which an open cavity is established, the bottom beam frame 3023 is used for mounting the cold source device 3040.

In the above solution, the bottom beam frame 3023 serves as a bearing base for the cold source enclosure 3020, above which an open cavity is established for accommodating the cold source device 3040 that can be mounted on the bearing base.

In an implementation, the cold source enclosure 3020 includes a support vertical beam 3022. A plurality of support vertical beams 3022 are provided, and an encircled region among the plurality of support vertical beams 3022 establishes an open cavity. The plurality of support vertical beams 3022 are disposed on a peripheral side of the cold source device 3040.

In the above solution, the support vertical beams 3022 serve as a peripheral protective structure of the cold source enclosure 3020, in which lower ends of the support vertical beams 3022 may be connected with the bottom beam frame 3023. Two sets of support vertical beams 3022 are arranged, with two support vertical beams in each set disposed apart along a width direction of the cold source enclosure 3020, and the two sets of support vertical beams 3022 disposed apart along the length direction of the cold source enclosure 3020.

In an implementation, the cold source enclosure 3020 includes a top beam frame 3021, below which an open cavity is established, the top beam frame 3021 being disposed on an outer periphery of the cold source device 3040.

In the above solution, the top beam frame 3021 serves as an upper constraint structure of the cold source enclosure 3020, in which upper ends of the support vertical beams 3022 may be connected with the top beam frame 3021. The top beam frame 3021, the support vertical beams 3022, and the bottom beam frame 3023 jointly establish a framework structure to form an open cavity to accommodate the cold source device 3040.

In an implementation, the cold source enclosure 3020 includes a top beam frame 3021, a support vertical beam 3022, and a bottom beam frame 3023 that jointly define an open cavity.

Optionally, the top beam frame 3021 is located above the bottom beam frame 3023, and the support vertical beam 3022 is connected between the bottom beam frame 3023 and the top beam frame 3021 to jointly define an open cavity for accommodating the cold source device 3040 of the data center 3001, the cold source device 3040 is used for providing cooling for the cooling working medium of the cooling apparatus.

Exemplarily, the top beam frame 3021 and the bottom beam frame 3023 are respectively formed by connecting a plurality of beam body structures. The top beam frame 3021 and the bottom beam frame 3023 are disposed apart and directly oppositely in the vertical direction, and a plurality of support vertical beams 3022 are provided and supported between the top beam frame 3021 and the bottom beam frame 3023.

By providing the cold source enclosure 3020 that defines an open cavity making the inside and outside of the cold source enclosure 3020 in communication, and by integrally deploying the cold source device 3040 in the open cavity, the enclosure structure according to the embodiment of the present application is conducive to improving the efficiency of air entering or flowing out of the inside of the cold source enclosure 3020, thereby improving the heat dissipation effect of the cold source enclosure 3020 and further improving the cooling efficiency of the cold source device 3040.

In an implementation, the cold source enclosure 3040 includes a structural reinforcement for enhancing the structural performance of the cold source enclosure.

In the above solution, the structural reinforcement may be disposed on at least one of the top beam frame 3021, the support vertical beam 3022, and the bottom beam frame 3023. When disposed on the top beam frame 3021, it may be a first plate body 302121, a second plate body 302122, and a third plate body 302123 between two top beam assemblies 30211. When mounted on the support vertical beam 3022, it may be a reinforcement vertical beam along the length direction of the cold source enclosure 3020. When mounted on the bottom beam frame 3023, it may be a bottom support cross beam 30231, a bottom support longitudinal beam 30232, and a bottom structurally reinforcement longitudinal beam 30233.

In an implementation, a height of the support vertical beam 3022 is greater than heights of the top beam frame 3021 and the bottom beam frame 3023.

In the above solution, a plurality of support vertical beams 3022 are provided, which are disposed sequentially at intervals. An encircled region of the plurality of support vertical beams 3022 establishes an open cavity. The structural heights of the top beam frame 3021 and the bottom beam frame 3023 do not need to be excessively high, and are only required to be sufficient to form a bearing-coupling and upper constraint structure for the cold source device 3040. The plurality of support vertical beams 3022 play a role of vertical structural support, and their height covers the cold source device 3040. A spacing between the plurality of support vertical beams 3022 is conducive to improving the efficiency of air entering or flowing out of the inside of the cold source enclosure 3020.

In an implementation, a height of the top beam frame 3021 is greater than a height of the bottom beam frame 3023.

In the above solution, the bottom beam frame 3023 may be fixed to the top of the computing device enclosure 3010, or to other foundation planes, and the top beam frame 3021 has no other fixing or support structures, so its height is increased to enhance the structural strength and strengthen the structure of the cold source enclosure 3020 as a whole, so as to facilitate transportation or actual use.

In an implementation, a reinforcement vertical beam is further disposed between the support vertical beams 3022 along the length direction of the cold source enclosure 3020, the reinforcement vertical beam being connected between the bottom beam frame 3023 and the top beam frame 3021.

In the above solution, two sets of support vertical beams 3022 are arranged, with two support vertical beams in each set disposed apart along the width direction of the cold source enclosure 3020, and the two sets of support vertical beams 3022 disposed apart along the length direction of the cold source enclosure 3020. The reinforcement vertical beam may be added between the two sets of support vertical beams 3022 so as to increase the peripheral structural performance of the cold source enclosure 3020 and provide support and protection for the cold source device 3040, so as to facilitate transportation or actual use.

In an implementation, as shown in FIG. 40, the cold source enclosure 3020 is detachably connected to an upper side of the computing device enclosure 3010.

Exemplarily, a bottom of the cold source enclosure 3020 is provided with an interlocking fit member, and a top of the computing device enclosure 3010 is provided with an interlocking fit aperture. The interlocking fit member is adapted to protrude into the interlocking fit aperture and is fixedly connected with the interlocking fit aperture by a fastener.

It can be understood that in a transportation process of the enclosure structure, the computing device enclosure 3010 and the cool source enclosure 3020 may be detached and loaded separately for marine or land transportation. After transportation to a designated location, the cold source enclosure 3020 can be mounted to the upper side of the computing device enclosure 3010, so as to complete delivery.

Thus, the transportation convenience and delivery efficiency of the enclosure structure are enhanced.

In other implementations of the present application, the cold source enclosure 3020 may also be disposed side by side with the computing device enclosure 3010 in the horizontal direction, which may be specifically disposed by those skilled in the art according to actual situations.

In an implementation, as shown in FIG. 48, the top beam frame 3021 includes two top beam assemblies 30211 disposed apart in the vertical direction.

Exemplarily, the bottom beam frame 3023 may be fixed to the top of the computing device enclosure 3010, or to other foundation planes, and the top beam frame 3021 has no other fixing or support structures, so its height is increased to enhance the structural strength and strengthen the structure of the cold source enclosure 3020 as a whole, so as to facilitate transportation or actual use. Therefore, the two top beam assemblies 30211 may be disposed, which may have the same shape and size and be disposed apart and directly oppositely in the vertical direction.

Optionally, a structural reinforcement 30212 is provided between the two top beam assemblies 30211.

Exemplarily, the structural reinforcement 30212 may be in the shape of a vertically disposed plate, or may include a plurality of monolithic connectors that are respectively connected with the two top beam assemblies 30211, which is not specifically limited here in the embodiments of the present application.

In the embodiment of the present application, the cold source enclosure 3020 may be correspondingly shaped and sized with reference to standard containers for marine or land transportation, so as to be directly loaded and transported in marine or land transportation or other transportation scenarios. It should be noted that in order to meet the transportation standards for marine or land freight containers, on the premise that dimensions of the cold source enclosure 3020 meet the dimensional specifications, the structural strength of the cold source enclosure 3020 still need meet the corresponding requirements. According to the above implementation, by disposing the structural reinforcement 30212 between the two top beam assemblies 30211, the structural strength and structural stability of the top beam frame 3021 are improved, thereby meeting the relevant requirements for marine or land transportation of the cold source enclosure 3020.

In an implementation, the two top beam assemblies 30211 are disposed directly oppositely in the vertical direction, each top beam assembly 30211 including a plurality of top beams.

Optionally, the plurality of top beams of the top beam assembly 30211 include two top transverse side beams 302111 that are disposed oppositely in a first horizontal direction, and two top longitudinal side beams 302112 that are disposed oppositely in a second horizontal direction. The structural reinforcements 30212 are respectively provided between each set of top beams of the two top beam assemblies 30211 correspondingly disposed in the vertical direction.

In the embodiment of the present application, the first horizontal direction is the width direction of the cold source enclosure 3020, and the second horizontal direction is the length direction of the computing device enclosure 3010.

Exemplarily, the two top transverse side beams 302111 are disposed oppositely in the width direction of the cold source enclosure 3020, and each top transverse side beam 302111 extends along the length direction of the cold source enclosure 3020. The two top longitudinal side beams 302112 are disposed oppositely in the length direction of the cold source enclosure 3020, and each top longitudinal side beam 302112 extends along the width direction of the cold source enclosure 3020. One of the top transverse side beams 302111 has two ends respectively connected with first ends of the two top longitudinal side beams 302112, and the other top transverse side beam 302111 has two ends respectively connected with second ends of the two top longitudinal side beams 302112. Thus, the top beam frame 3021 with an outer contour in the shape of a rectangle is formed by connecting the two top transverse side beams 302111 and the two top longitudinal side beams 302112.

It can be understood that the two top beam assemblies 30211 jointly form four sets of corresponding top beams in the vertical direction, with the structural reinforcements 30212 respectively provided between each set of corresponding top beams in the vertical direction.

Optionally, a connector is provided at a connection between the top transverse side beam 302111 and the top longitudinal side beam 302112, the connector including connecting walls respectively corresponding to the top transverse side beam 302111 and the top longitudinal side beam 302112, the connecting walls being fixedly connected with wall bodies of the corresponding top transverse side beam 302111 or the corresponding top longitudinal side beam 302112.

Exemplarily, inner side wall faces of the two connecting walls of the connector respectively abut against outer side wall faces of the top transverse side beam 302111 and the top longitudinal side beam 302112, and the two connecting walls are respectively fixedly connected with the corresponding top transverse side beam 302111 and top longitudinal side beam 302112 by bolts and nuts.

In other examples of the present application, the connecting walls and the wall bodies of the corresponding top transverse side beam 302111 or the corresponding top longitudinal side beam 302112 may also be fixedly connected by welding.

Optionally, the structural reinforcement 30212 is plate-shaped and extends along a length direction of the corresponding top beam.

Exemplarily, a plane where the structural reinforcement 30212 is located is perpendicular to the horizontal plane. In the two top beam assemblies 30211, the structural reinforcement 30212 between the two corresponding top transverse side beams 302111 in the vertical direction extends along the second horizontal direction, and the structural reinforcement 30212 between the two corresponding top longitudinal side beams 302112 in the vertical direction extends along the first horizontal direction. The structural reinforcement 30212 may be in the shape of a flat plate.

Optionally, as shown in FIG. 48, the structural reinforcement 30212 includes a first plate body 302121 and a second plate body 302122 which are disposed apart in the length direction of the corresponding top beam, the first plate body 302121 and the second plate body 302122 being disposed apart in a direction perpendicular to the length direction of the top beam.

Exemplarily, there may be a plurality of first plate bodies 302121 and a plurality of second plate bodies 302122 respectively, with the plurality of first plate bodies 302121 and the plurality of second plate bodies 302122 disposed apart and alternately in the length direction of the top beam.

Optionally, the structural reinforcement 30212 further includes a plurality of connecting plate bodies 302123 connected between adjacent first plate bodies 302121 and second plate bodies 302122.

Planes where the first plate body 302121 and the second plate body 302122 are located are parallel to each other and both perpendicular to the horizontal plane, while a plane where the connecting plate body 302123 is located is perpendicular to the horizontal plane. That is to say, the planes where the first plate body 302121, the second plate body 302122, and the connecting plate body 302123 are located are all parallel to the vertical direction.

Exemplarily, the structural reinforcement 30212 may be a multi-segment bent plate that has been bent multiple times in its extension direction. Specifically, the plurality of first plate bodies 302121 are disposed side by side at intervals along a direction parallel to the length direction of the top beam, and the plurality of second plate bodies 302122 are disposed side by side at intervals along the direction parallel to the length direction of the top beam, the plurality of first plate bodies 302121 and the plurality of second plate bodies 302122 being disposed in a staggered manner along the length direction of the top beam. The first plate bodies 302121 and the second plate bodies 302122 are disposed at intervals in a direction perpendicular to the length direction of the top beam. The connecting plate bodies 302123 are correspondingly connected between the adjacent first plate bodies 302121 and second plate bodies 302122.

With such arrangement, the structural reinforcement 30212 can be in a corrugated shape, thereby increasing the support area of the structural reinforcement 30212 in the horizontal direction, and significantly enhancing the structural strength and stability of the top beam frame 3021.

Optionally, a spacing between the plane where the first plate body 302121 is located and the plane where the second plate body 302122 is located is 4 mm to 10 mm.

Exemplarily, the spacing between the plane where the first plate body 302121 is located and the plane where the second plate body 302122 is located may be correspondingly set according to a width dimension of the corresponding top beam. It should be noted that a wall thickness dimension of marine or land freight containers is usually 4 mm to 10 mm, and in order to meet the marine or land transportation needs of the cold source enclosure 3020, the width dimension of the top beam is adapted to be set between 4 mm and 10 mm. Based on this, the spacing between the plane where the first plate body 302121 is located and the plane where the second plate body 302122 is located is adapted to be set between 4 mm and 10 mm. Preferably, the spacing between the plane where the first plate body 302121 is located and the plane where the second plate body 302122 may be set to 7 mm.

Optionally, an included angle between the plane where the connecting plate body 302123 is located and the plane where the first plate body 302121 is located or the plane where the second plate body 302122 is located is 120° to 150°.

Exemplarily, the planes where the first plate body 302121, the second plate body 302122, and the connecting plate body 302123 are located are all perpendicular to the horizontal plane, and the plane where the first plate body 302121 is located is parallel to the plane where the second plate body 302122 is located. The included angle between the plane where the first plate body 302121 is located and the plane where the connecting plate body 302123 is located is equal to the included angle between the plane where the second plate body 302122 is located and the plane where the connecting plate body 302123 is located. Preferably, the included angle between the plane where the connecting plate body 302123 is located and the plane where the adjacent first plate body 302121 or second plate body 302122 is located is 135°.

Optionally, the first plate body 302121 and the second plate body 302122 have equal dimensions in the length direction of the top beam. In other words, the width dimensions of the first plate body 302121 and the second plate body 302122 are equal. The width dimensions of the first plate body 302121 and the second plate body 302122 may be specifically set according to actual situations, which is not specifically limited in the embodiments of the present application.

Exemplarily, a ratio of a dimension of the connecting plate body 302123 in the length direction of the top beam to a dimension of the first plate body 302121 or the second plate body 302122 in the length direction of the top beam is greater than or equal to ½ and less than or equal to 1.

It can be understood that the dimension of the connecting plate body 302123 in the length direction of the top beam refers to a dimension of projection of the connecting plate body 302123 in the length direction of the top beam. The dimensions of the first plate body 302121 and the second plate body 302122 in the length direction of the top beam may be the width dimensions of the first plate body 302121 and the second plate body 302122.

Preferably, the ratio of the dimension of the connecting plate body 302123 in the length direction of the top beam to the dimension of the first plate body 302121 or the second plate body 302122 in the length direction of the top beam may be 1. That is, the ratio of the dimension of the connecting plate body 302123 in the length direction of the top beam is equal to the dimension of the first plate body 302121 or the second plate body 302122 in the length direction of the top beam.

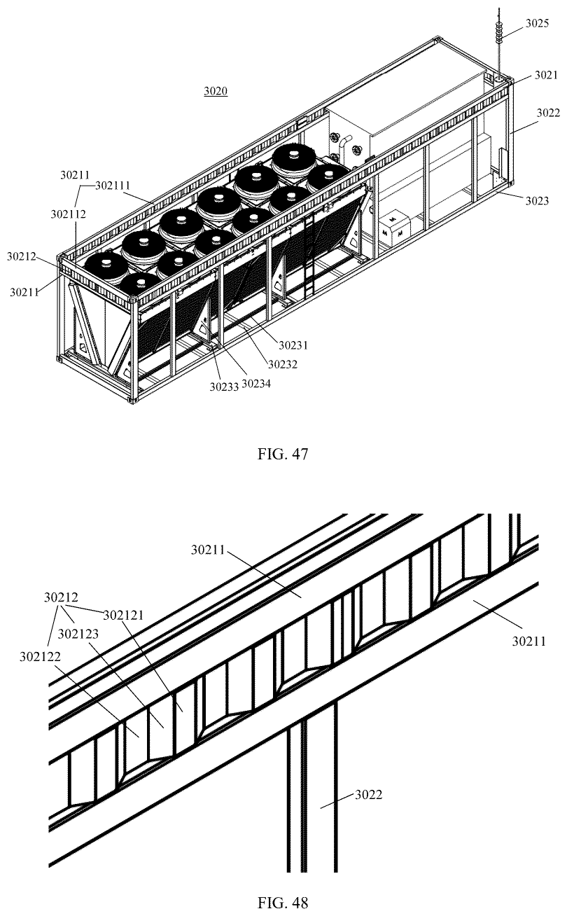

In an implementation, as shown in FIG. 47, the bottom beam frame 3023 includes two bottom transverse side beams that are disposed oppositely in the first horizontal direction, and two bottom longitudinal side beams that are disposed oppositely in the second horizontal direction.

Exemplarily, the two bottom transverse side beams are disposed oppositely in the width direction of the cold source enclosure 3020, and each bottom transverse side beam extends along the length direction of the cold source enclosure 3020. The two bottom longitudinal side beams are disposed oppositely in the length direction of the cold source enclosure 3020, and each bottom longitudinal side beam extends in the width direction of the cold source enclosure 3020. One of the bottom transverse side beams has two ends respectively connected with first ends of the two bottom longitudinal side beams, and the other bottom transverse side beam has two ends respectively connected with second ends of the two bottom longitudinal side beams. Thus, the bottom beam frame 3023 with an outer contour in the shape of a rectangle is formed by connecting the two bottom transverse side beams and the two bottom longitudinal side beams.

In an implementation, as shown in FIG. 47, the bottom beam frame 3023 further includes at least one bottom support cross beam 30231 disposed side by side at intervals in the first horizontal direction, and/or at least one bottom support longitudinal beam 30232 disposed side by side at intervals in the second horizontal direction. Each bottom support cross beam 30231 is lapped over an upper side of the at least one bottom support longitudinal beam 30232.

Exemplarily, a plurality of bottom support cross beams 30231 are disposed side by side at intervals in the width direction of the cold source enclosure 3020, and each bottom support cross beam 30231 extends along the length direction of the cold source enclosure 3020. A plurality of bottom support longitudinal beams 30232 are disposed side by side at intervals in the length direction of the cold source enclosure 3020, and each bottom support longitudinal beam 30232 extends along the width direction of the cold source enclosure 3020. Each bottom support cross beam 30231 and the plurality of bottom support longitudinal beams 30232 over which it is lapped may be fixedly connected by fasteners, or may be fixedly connected by welding.

In the embodiment of the present application, a spacing between two adjacent bottom support cross beams 30231 and a spacing between two adjacent bottom support longitudinal beams 30232 may be correspondingly set according to actual situations, which is not specifically limited in the embodiment of the present application.

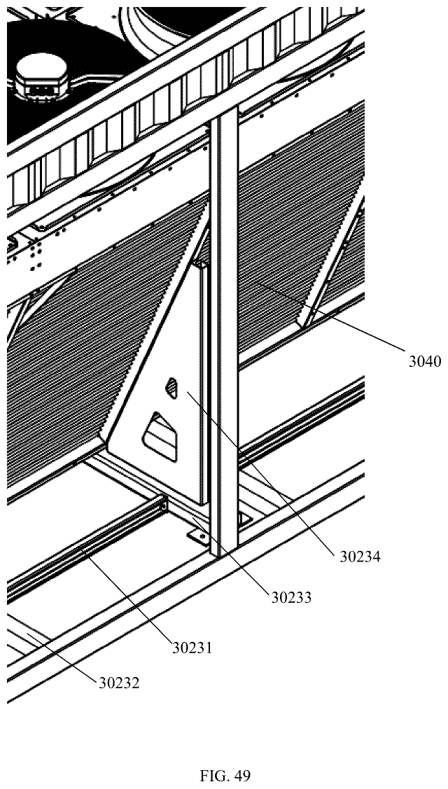

In an implementation, as shown in FIG. 49, the bottom beam frame 3023 further includes at least one bottom structural reinforcement longitudinal beam 30233, each bottom structural reinforcement longitudinal beam 30233 being connected to an upper side of the at least one bottom support crossbeam 30231. The cold source device 3040 is supported on a plurality of bottom structural reinforcement longitudinal beams 30233.

Exemplarily, a width dimension of the bottom structural reinforcement longitudinal beam 30233 is greater than a width dimension of the bottom support longitudinal beam 30232. The bottom structural reinforcement longitudinal beam 30233 has a cross-sectional shape similar to the Chinese character “ [symbol] ”, with an end of the bottom structural reinforcement longitudinal beam 30233 provided with a fixed lug, two fixed lugs being provided and formed by extending along the horizontal direction from two sides of the bottom structural reinforcement longitudinal beam 30233 in the width direction. The fixed lugs are fixed to the top wall of the computing device enclosure 3010 by fasteners. A bottom of the bottom structural reinforcement longitudinal beam 30233 is further provided with a limiting groove. A plurality of limiting grooves are provided corresponding to the number of bottom support cross beams 30231, and the bottom support cross beams 30231 are embedded in the corresponding limiting grooves.

Exemplarily, the at least one bottom structural reinforcement longitudinal beam 30233 and the at least one bottom support longitudinal beam 30232 are disposed alternately and apart in the second horizontal direction, with the at least one bottom support longitudinal beam 30232 present between two adjacent bottom structural reinforcement longitudinal beams 30233.

Optionally, a top of the bottom structural reinforcement longitudinal beam 30233 is provided with a support plate 30234 having a support side wall for supporting an outer side wall face of the cold source device 3040.

Exemplarily, a plane where the support plate 30234 is located is disposed perpendicular to the length direction of the cold source enclosure 3020. A bottom of the support plate 30234 is fixedly connected to an upper side wall of the bottom structural reinforcement longitudinal beam 30233. A lower end of the support plate 30234 and the upper side wall of the bottom structural reinforcement longitudinal beam 30233 may be fixedly connected by fasteners.

Further, a plurality of bottom structural reinforcement longitudinal beams 30233 are disposed at intervals in the length direction of the cold source enclosure 3020. Correspondingly, a plurality of support plates 30234 are disposed at intervals in the length direction of the cold source enclosure 3020, and the support side wall of each support plate 30234 supports the outer side wall face of the cold source device 3040 at intervals in the length direction of the cold source enclosure 3020.

Optionally, the outer side wall face of the cold source device 3040 has a preset included angle with the horizontal plane, and an outer contour of the support plate 30234 is in the shape of a right triangle, with the support side wall forming a hypotenuse of the right triangle.

Exemplarily, the preset included angle between the outer side wall face of the cold source device 3040 and the horizontal plane is 45° to 75°, and an angle between the support side wall of the support plate 30234 and the horizontal plane is equal to the preset included angle between the outer side wall face of the cold source device 3040 and the horizontal plane, so that the support side wall of the support plate 30234 can form support for the outer side wall face of the cold source device 3040. An outer side wall of the support plate 30234 extends along the vertical direction, a lower side wall of the support plate 30234 extends along the horizontal direction, and an inner side wall of the support plate 30234 forms the support side wall. It can be understood that in a projection of the support side wall, an outer contour of the support plate 30234 is defined jointly by the outer side wall, lower side wall, and inner side wall of the support plate 30234.

Optionally, the bottom structural reinforcement longitudinal beam 30233 is provided with two support plates 30234, which are disposed oppositely in the length direction of the bottom structural reinforcement longitudinal beam 30233. The support side walls of the two support plates 30234 are used for supporting the two oppositely disposed outer side wall faces of the cold source device 3040 respectively.

Exemplarily, the bottom structural reinforcement longitudinal beam 30233 extends along the width direction of the cold source enclosure 3020, and the bottom structural reinforcement longitudinal beam 30233 is provided with two support plates 30234 disposed apart in its length direction, the support side walls of the two support plates 30234 being disposed oppositely. The cold source device 3040 has two outer side wall faces that are disposed oppositely in the width direction of the cold source enclosure 3020, and a spacing between the two outer side wall faces gradually increases in a direction from bottom to top, so that the two outer side wall faces of the cold source device 3040 form a “V” shape in a longitudinal vertical plane, and the support side walls of the two support plates 30234 on each bottom structural reinforcement longitudinal beam 30233 are respectively support the two outer side wall faces of the cold source device 3040.

With the above implementation, by providing the plurality of bottom structural reinforcement longitudinal beams 30233, the support effect for the cold source device 3040 is improved, which is conducive to enhancing the stability of the cold source device 3040 and alleviating the problem of local stress concentration of the cold source device 3040 on the bottom beam frame 3023.

An embodiment of the present application further provides a cold source container. The cold source container may include an enclosure structure of the above embodiment of the present application and at least one cold source device that is deployed in the enclosure structure.

An embodiment of the present application further provides a data center 3001. As shown in FIG. 40, the data center 3001 of the embodiment of the present application includes a plurality of computing devices 3030, a cold source device 3040, and an enclosure structure of the above embodiment of the present application.

In an implementation, the data center 3001 further includes a computing device enclosure 3010, in which the plurality of computing devices are deployed. The computing device enclosure 3010 may be provided below the cold source enclosure 3020, or may be provided on a side of the cold source enclosure 3020 in the horizontal direction.

An embodiment of the present application further provides a data center. The data center includes an accommodating space for accommodating a computing device, the accommodating space having a cable mounting region and a pipeline mounting region, which are disposed apart in a first horizontal direction, the cable mounting region is used for mounting a cable, and the pipeline mounting region is used for mounting a cooling pipeline that is connected between a cooling apparatus of the computing device and a cold source device for allowing a cooling working medium to flow.

In the following description of the specification of the present application, the first horizontal direction may be a width direction of the accommodating space, and a second horizontal direction may be a length direction of the accommodating space, which will not be repeatedly defined below.

In the embodiment of the present application, the accommodating space may be defined by any device or facility. For example, the accommodating space may be defined by a factory building, or may be defined by the computing device enclosure of the enclosure structure in the above embodiment of the present application. Other devices or facilities included in the data center of the embodiment of the present application, such as mounting brackets, computing devices, cold source devices, and the like, may be the same or similar devices or facilities included in an enclosure structure of the above embodiment of the present application and in the data center having the enclosure structure.

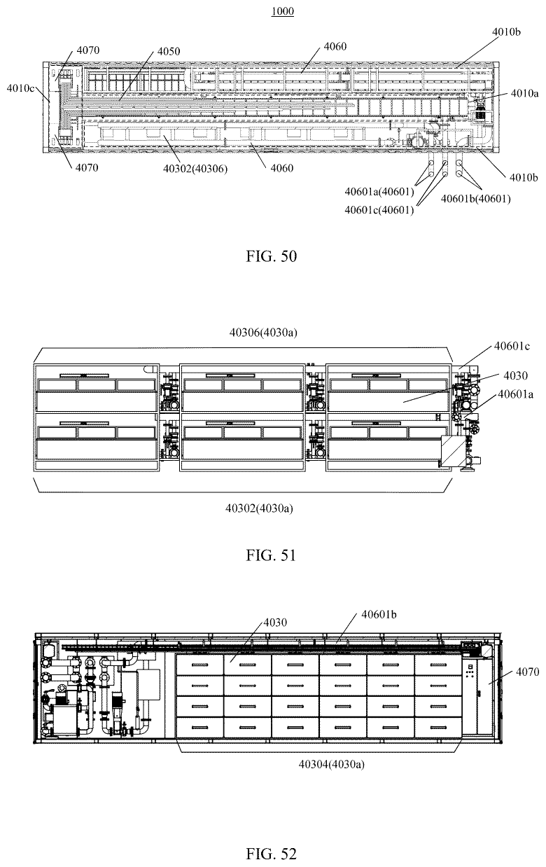

As a seventh aspect of the embodiments of the present application, an embodiment of the present application provides a pipeline structure 1000 for a data center. As shown in FIG. 50, the pipeline structure 1000 of the embodiment of the present application includes an accommodating space 4001a for accommodating a computing device 4030, the accommodating space 4001a having a cable 4050 and a cooling pipeline 4060, which are disposed separately.

In the embodiment of the present application, the accommodating space 4001a may be defined by any device or facility. For example, the accommodating space 4001a may be defined by a factory building, or may be defined by a computing device 4030 enclosure of an enclosure structure of the following embodiment of the present application.

In the embodiment of the present application, the cable 4050 is used for providing electrical power to the computing device 4030 in the data center, and the cooling pipeline 4060 is used for providing a cooling working medium to a cooling apparatus of the computing device 4030. The cooling working medium is used for exchanging heat with a server module of the computing device 4030, so as to implement cooling of the server module. Exemplarily, the computing devices 4030 are disposed in a row in the accommodating space to form a computing device row. By disposing the computing devices in a row, this facilitates a layout of the cable 4050 and the cooling pipeline 4060 in the accommodating space, thereby enhancing the utilization rate of the accommodating space.

In the embodiment of the present application, the cable 4050 and the cooling pipeline 4060 are disposed separately, which means that they are isolated in physical space. For example, the cable 4050 and the cooling pipeline 4060 are disposed separately in a height direction and/or a width direction of the accommodating space, or the cable 4050 and the cooling pipeline 4060 may be disposed apart in a vertical direction, or may be disposed apart in a horizontal direction, or may be disposed apart in both the vertical and horizontal directions.

In an implementation, a height of an arrangement position of the cable 4050 is greater than a height of an arrangement position of the cooling pipeline 4060, which can avoid a leaked liquid from the cooling pipeline 4060 from drenching onto the cable.

In an implementation, the computing devices are arranged in a row in the accommodating space to form a computing device row, an arrangement direction of the computing device row being perpendicular to the height direction and/or width direction of the accommodating space. By disposing the computing devices in a row, this facilitates a layout of the cable 4050 and the cooling pipeline 4060 in the accommodating space, thereby enhancing the utilization rate of the accommodating space.

The pipeline structure 1000 for the data center according to the embodiment of the present application can implement isolation of liquid and power supply to the data center in physical space, avoiding water and electricity contact caused by leakage in the cooling pipeline 4060, thereby decreasing the probability of safety hazards.

In an implementation, the cable 4050 and the cooling pipeline 4060 are disposed separately in a first direction.

In the embodiment of the present application, the first direction may be a horizontal direction, which, for example, may be the length direction of the accommodating space 4001a, or may be the width direction of the accommodating space 4001a. The cable 4050 and the cooling pipeline 4060 are disposed separately in the first direction, which means that there is no region where the cable 4050 and the cooling pipeline 4060 are in contact in the first direction.

In one example, the cable 4050 and the cooling pipeline 4060 extend along the length direction of the accommodating space 4001a respectively, and the cable 4050 and the cooling pipeline 4060 are spaced apart by a preset distance in the width direction of the accommodating space 4001a.

In another example, the cable 4050 and the cooling pipeline 4060 extend along the width direction of the accommodating space 4001a respectively, and the cable 4050 and the cooling pipeline 4060 are spaced apart by a preset distance in the length direction of the accommodating space 4001a.

It should be noted that in the two examples described above, the cable 4050 and the cooling pipeline 4060 may be disposed side by side in the vertical direction, or may be disposed in a staggered manner in the vertical direction, which may be correspondingly disposed by those skilled in the art according to actual situations.

With the above implementation, it is conducive to improving the space utilization rate of the accommodating space 4001a.

In an implementation, the computing devices 4030 are disposed in a row in the accommodating space 4001a along a second direction to form a computing device row 4030a, and the cable 4050 and/or the cooling pipeline 4060 are arranged along an extension direction of the computing device row 4030a, the second direction being perpendicular to the first direction.

In the embodiment of the present application, the first direction and the second direction are two horizontal directions that are perpendicular to each other. For example, the first direction may be the width direction of the accommodating space 4001a, and the second direction may be the length direction of the accommodating space 4001a.

Exemplarily, a plurality of computing devices 4030 are arranged into at least one computing device row 4030a, and the plurality of computing devices 4030 in each computing device row 4030a are arranged along the length direction of the accommodating space 4001a. The extension direction of the computing device row 4030a may be understood as an arrangement direction of the plurality of computing devices 4030 included in the computing device row 4030a, which may specifically be the length direction of the accommodating space 4001a. At least one of the cable 4050 and the cooling pipeline 4060 is arranged along the extension direction of the computing device row 4030a.

In one example, the cable 4050 is arranged along the length direction of the accommodating space 4001a, and the cooling pipeline 4060 is arranged along a direction at a small included angle to the length direction of the accommodating space 4001a.

In another example, the cooling pipeline 4060 is arranged along the length direction of the accommodating space 4001a, and the cable 4050 is arranged along a direction at a small included angle to the length direction of the accommodating space 4001a.

In still another example, the cooling pipeline 4060 and the cable 4050 are arranged along the length direction of the accommodating space 4001a respectively.

With the above implementation, the rationality of the layout of the cable 4050 and/or the cooling pipeline 4060 within the accommodating space 4001a is improved, thereby facilitating connection between the cable 4050 and/or the cooling pipeline 4060 and the computing devices 4030, and improving the convenience of inspection or maintenance.

In an implementation, the computing device row 4030a includes a first device row end and a second device row end which are opposite along the length direction, and an extension direction of the cable 4050 is from the first device row end to the second device row end.

It can be understood that the plurality of computing devices 4030 in the computing device row 4030a are arranged in the second direction that is the length direction of the computing device row 4030a, and the first device row end and the second device row end are two ends of the computing device row 4030a in the second direction. The extension direction of the cable 4050 refers to a direction of electrical power transmission of the cable 4050, namely a direction of the cable 4050 from an electrical power input end to an electrical power output end.

Exemplarily, a power distribution cabinet 4070 of the data center may be disposed close to the first device row end of the computing device row 4030a, and located on a side of the first device row end away from the second device row end. The electrical power input end of the cable 4050 is connected to the power distribution cabinet 4070, and the electrical power output end of the cable 4050 is connected to a corresponding computing device 4030, so as to conduct electrical power from an output end of the power distribution cabinet 4070 to the computing device 4030.

With the above implementation, by setting the extension direction of the cable 4050 from the first device row end to the second device row end, this facilitates electrical connection of the cable 4050 to each computing device 4030 in the computing device row 4030a, thereby improving the convenience of electrical power connection to the computing devices 4030 and being conducive to enhancing the rationality of routing of the cable 4050.

In an implementation, the computing device row 4030a includes a first device row end and a second device row end which are opposite along the length direction, and an extension direction of the cooling pipeline 4060 is from the second device row end to the first device row end.

It can be understood that the plurality of computing devices 4030 in the computing device row 4030a are arranged in the second direction that is the length direction of the computing device row 4030a, and the first device row end and the second device row end are two ends of the computing device row 4030a in the second direction. The extension direction of the cooling pipeline 4060 refers to a flow guide direction of the cooling pipeline 4060, namely a direction of the cooling pipeline 4060 from a cooling working medium input end to a cooling working medium output end.

Exemplarily, a power module of the data center is used for providing power to the flow of the cooling working medium between the cooling apparatus and the cooling pipeline 4060. The power module may be disposed close to the second device row end of the computing device row 4030a, and located on a side of the second device row end away from the first device row end. The cooling working medium input end of the cooling pipeline 4060 is connected with the power module, and the cooling working medium output end of the cooling pipeline 4060 is connected with the cooling apparatus of each computing device 4030 in the computing device row 4030a, so as to transport the cooling working medium to the cooling apparatus of each computing device 4030.

According to the above implementation, by disposing the extension direction of the cooling pipeline 4060 from the second device row end to the first device row end so that the extension direction of the cooling pipeline 4060 is disposed opposite to the extension direction of the cable 4050, the power distribution cabinet 4070 connected to the electrical power input end of the cable 4050 and the power module connected with the cooling working medium input end of the cooling pipeline 4060 can thus be disposed apart in the second direction, thereby further improving the water and electricity isolation effect of the data center and further enhancing the security performance of the data center.

In an implementation, a height of an arrangement position of the cable 4050 is greater than a height of an arrangement position of the cooling pipeline 4060.

In the embodiment of the present application, the height of the arrangement position of the cable 4050 is greater than the height of the arrangement position of the cooling pipeline 4060, which may be understood as a positional height of a lowermost point on the cable 4050 being greater than a positional height of an uppermost point on the cooling pipeline 4060.

With the above implementation, in a case where leakage occurs in the cooling pipeline 4060, the cooling working medium can be avoided from spilling on the cable 4050, thereby further improving safety performance.

In an implementation, the cooling pipeline 4060 includes at least one pipeline set 40601 connected between the cold source device and the computing device row 4030a, the pipeline set 40601 including a main liquid supply pipeline and a main liquid return pipeline.

It can be understood that the main liquid supply pipeline and the main liquid return pipeline are connected between the cooling apparatus of the computing device 4030 and the cold source device respectively, the main liquid supply pipeline is used for transporting a low-temperature cooling working medium output from the cold source device to the cooling apparatus of the computing device 4030, and the main liquid return pipeline is used for transporting a high-temperature cooling working medium output from the computing device to the cold source device. With the main liquid supply pipeline and the main liquid return pipeline, circulation of the cooling working medium is implemented between the cooling apparatus of the computing device 4030 and the cold source device.

Optionally, the pipeline set 40601 further includes a plurality of branch liquid supply pipelines connected with the computing device row 4030a and the cold source device, each branch liquid supply pipeline connected between the cooling apparatus of a corresponding computing device 4030 in the computing device row 4030a and the main liquid supply pipeline.

Exemplarily, the computing device row 4030a is disposed in a one-to-one correspondence with the pipeline set 40601, with a plurality of branch liquid supply pipelines provided in a one-to-one correspondence with the plurality of computing devices 4030 in the computing device row 4030a. The cooling apparatus of the computing device 4030 includes a cooling module for containing the cooling working medium in which the server module is immersed, and a power module for providing power for the cooling working medium to flow into the cooling module. The power module of each computing device 4030 in the computing device row 4030a is connected with the main liquid supply pipeline through a corresponding branch liquid supply pipeline, so that the cooling working medium transported in the main liquid supply pipeline is transported to the power module of each computing device 4030 in the computing device row 4030a through a corresponding one of the plurality of branch liquid supply pipelines.

Optionally, the pipeline set 40601 further includes a plurality of branch liquid return pipelines connected with the computing device row 4030a and the cold source device, each branch liquid return pipeline connected between the cooling apparatus of a corresponding computing device 4030 in the computing device row 4030a and the main liquid return pipeline.

Exemplarily, the cooling pipeline includes a connection port, at which a leakage detection apparatus is disposed. Exemplarily, the leakage detection apparatus may include a leakage sensor, a humidity sensor, a liquid level sensor, or the like, which is not limited in the present application.

Exemplarily, the cooling pipeline includes connection ports including connection ports between the main liquid supply pipeline and/or the main liquid return pipeline and branch pipelines, connection ports between the main liquid supply pipeline and/or the main liquid return pipeline and the cold source device, connection ports between the branch pipelines and the cooling apparatus, and the like, the branch pipelines including the branch liquid supply pipelines and/or branch liquid outlet pipelines.

Exemplarily, the cable includes a plurality of power supply lines extending along the computing device row and connected to the computing devices in the computing device row.

Exemplarily, the plurality of power supply lines are connected to the computing devices in the computing device row through power distribution units. Exemplarily, a power supply line is connected to a power distribution unit including a plurality of sockets, into which power supply lines of servers in the computing devices is plugged to implement power supply.

Exemplarily, the computing device row 4030a is disposed in a one-to-one correspondence with the pipeline set 40601, with a plurality of branch liquid return pipelines provided in a one-to-one correspondence with the plurality of computing devices 4030 in the computing device row 4030a. The cooling apparatus of the computing device 4030 includes a cooling module for containing the cooling working medium in which the server module is immersed, and a power module for providing power for the cooling module to discharge the cooling working medium. The power module of each computing device 4030 in the computing device row 4030a is connected with the main liquid return pipeline through a corresponding branch liquid return pipeline, so that the cooling working medium discharged out of the power module of each computing device 4030 in the computing device row 4030a is transported to the main liquid return pipeline through a corresponding one of the plurality of branch liquid return pipelines.

By providing the branch liquid return pipelines and the main liquid return pipeline, the pipeline connection of the main liquid supply pipeline and main liquid return pipeline with the cooling apparatus of each computing device 4030 in the computing device row 4030a can be implemented while it is guaranteed that the main liquid supply pipeline and the main liquid return pipeline extend along the length direction of the computing device row 4030a.

Optionally, provided are a plurality of cold source devices, one computing device row 4030a, and a plurality of pipeline sets 40601 that are connected with the plurality of cold source devices in a one-to-one correspondence.

Exemplarily, the plurality of pipeline sets 40601 are provided in a one-to-one correspondence with the cold source devices, each pipeline set 40601 connected with a corresponding cold source device.

In one example, the plurality of computing devices 4030 in the computing device row 4030a are divided into a plurality of computing device 4030 sets which correspond to the plurality of cold source devices one by one. Each cold source device is connected with the cooling apparatus of a corresponding computing device 4030 set through a respective pipeline set 40601.

In another example, each cold source device is connected with the cooling apparatus of each computing device 4030 in the computing device row 4030a through a corresponding pipeline set 40601. In other words, any cold source device can implement cooling of the cooling working medium within the cooling apparatus of each computing device 4030 in the computing device row 4030a.

Optionally, provided are one cold source device, a plurality of computing device rows 4030a, and a plurality of pipeline sets 40601 that are connected with the plurality of computing device rows 4030a in a one-to-one correspondence.

Exemplarily, two computing device rows 4030a may be provided, which are arranged apart in the width direction of the accommodating space 4001a, and a plurality of computing devices 4030 in each computing device row 4030a are arranged side by side along the length direction of the accommodating space 4001a. Two pipeline sets 40601 are provided respectively corresponding to the two computing device rows 4030a, each pipeline set 40601 connected to the cold source device and each cooling apparatus in a corresponding computing device row 4030a.

More specifically, the pipeline set 40601 includes a main liquid supply pipeline, a main liquid return pipeline, a plurality of branch liquid supply pipelines, and a plurality of branch liquid return pipelines. Extension directions of the main liquid supply pipeline and the main liquid return pipeline are respectively arranged along the length direction of the accommodating space 4001a, and they are located above a corresponding computing device row 4030a. The plurality of branch liquid supply pipelines are connected between the cooling apparatuses of the plurality of computing devices 4030 in the computing device row 4030a and the main liquid supply pipeline, and the plurality of branch liquid return pipelines are connected between the cooling apparatuses of the plurality of computing devices 4030 in the computing device row 4030a to the main liquid return pipeline.

In an implementation, as shown in FIGS. 51 and 52, there are a plurality of cold source devices and a plurality of computing device rows 4030a. A first pipeline set 40601a is connected between a first cold source device and a first computing device row 40302, and a second pipeline set 40601b is connected between a second cold source device and a second computing device row 40304.

In the embodiment of the present application, the first cold source device and the second cold source device may be the same device, or may be different devices. For example, the first cold source device and the second cold source device may both be a cooling tower. For another example, the first cold source device and the second cold source device may both be a dry cooler. For still another example, the first cold source device and the second cold source device may be a cooling tower and a dry cooler, respectively.

Exemplarily, the first computing device row 40302 and the second computing device row 40304 are respectively disposed close to two sides of the accommodating space 4001a in its width direction, and the first computing device row 40302 and the second computing device row 40304 are respectively arranged along the length direction of the accommodating space 4001a.

The first pipeline set 40601a is located above the first computing device row 40302, with a main liquid supply pipeline and a main liquid return pipeline of the first pipeline set 40601a respectively connected to the first cold source device and connected with the cooling apparatuses of a plurality of computing devices 4030 in the first computing device row 40302 through a plurality of branch liquid supply pipelines and a plurality of branch liquid return pipelines. The second pipeline set 40601b is located above the second computing device row 40304, with a main liquid supply pipeline and a main liquid return pipeline of the second pipeline set 40601b respectively connected to the second cold source device and connected with the cooling apparatuses of a plurality of computing devices 4030 in the second computing device row 40304 through a plurality of branch liquid supply pipelines and a plurality of branch liquid return pipelines.

The computing power or cooling needs of the computing devices 4030 in the first computing device row 40302 and the second computing device row 40304 may be the same or different. For example, the number or specifications of the server modules of first computing devices 4030 included in the first computing device row 40302 may be the same as or different from the number or specifications of the server modules of second computing devices 4030 included in the second computing device row 40304. The specific arrangement of the first and second cold source devices may be correspondingly made according to the computing power or cooling needs of the first computing device row 40302 and the second computing device row 40304 respectively, which is not specifically limited in the embodiments of the present application.

Optionally, a third pipeline set 40601c is connected between the first cold source device and the second cold source device and a third computing equipment row 40306.

Exemplarily, the first computing device row 40302 and the second computing device row 40304 are respectively disposed close to two sides of the accommodating space 4001a in the first direction, and the first pipeline set 40601a and the first computing device row 40302, as well as the second pipeline set 40601b and the second computing device row 40304, are correspondingly disposed in the vertical direction respectively.

Further, third computing devices 4030 are stacked with the first computing device row 40302 or the second computing device row 40304 in the vertical direction, and the third pipeline set 40601c is disposed corresponding to the third computing device row 40306 in the vertical direction.

In one example, the third computing device row 40306 is stacked with the first computing device row 40302 in the vertical direction. For example, the third computing device row 40306 may be located above or below the first computing device row 40302, so that the third computing device row 40306 and the first computing device row 40302 are located together on a side of the accommodating space 4001a in its width direction, and the second computing device row 40304 is located on the other side of the accommodating space 4001a in its width direction. The third pipeline set 40601c may be provided above the third computing device row 40306. Such arrangement allows the first pipeline set 40601a and the third pipeline set 40601c to be located on a side of the accommodating space 4001a in the first direction, and the second pipeline set 40601b to be located on the other side of the accommodating space 4001a in the first direction, thereby reserving a space between the first pipeline set 40601a and the third pipeline set 40601c and the second pipeline set 40601b to mount the cable 4050, and then implementing separate arrangement of the cable 4050 and the cooling pipeline 4060 in the first direction.

In another example, the third computing device row 40306 is stacked with the second computing device row 40304 in the vertical direction. For example, the third computing device row 40306 may be located above or below the second computing device row 40304, so that the first computing device row 40302 is located on a side of the accommodating space 4001a in its width direction, and the third computing device row 40306 and the second computing device row 40304 are together located on the other side of the accommodating space 4001a in its width direction. The third pipeline set 40601c may be provided above the third computing device row 40306. Such arrangement allows the first pipeline set 40601a to be located on a side of the accommodating space 4001a in the first direction, and the second pipeline set 40601b and the third pipeline set 40601c to be located on the other side of the accommodating space 4001a in the first direction, thereby reserving a space between the first pipeline set 40601a and the second pipeline set 40601b and the third pipeline set 40601c to mount the cable 4050, and then implementing separate arrangement of the cable 4050 and the cooling pipeline 4060 in the first direction.

In an implementation, the accommodating space 4001a has a cable mounting region 4010a and a pipeline mounting region 4010b, which are disposed apart in a first direction, the cable mounting region 4010a is used for mounting the cable 4050, and the pipeline mounting region 4010b is used for mounting the cooling pipeline 4060 that is connected between the cooling apparatus of the computing device 4030 and the cold source device for allowing the cooling working medium to flow.

In the following description of the specification of the present application, the first direction may be the width direction of the accommodating space 4001a, and a second direction may be the length direction of the accommodating space 4001a, which will not be repeatedly defined below.

In the embodiment of the present application, the cooling apparatus may employ immersion liquid cooling as the cooling method to cool the server module, in which the server module is directly immersed in the cooling working medium so as to directly conduct heat generated by the server module to the cooling working medium.

Exemplarily, the cooling apparatus includes a cooling housing and a powertrain. The inside of the cooling housing is used for accommodating the cooling working medium, and the computing device 4030 includes at least one server module which is directly immersed in the cooling working medium. The cooling pipeline 4060 is provided between the cooling apparatus and the cold source device of the data center for allowing the cooling working medium to flow in a circulating manner between the two, and the powertrain is used for providing power for the cooling working medium to flow within the cooling pipeline 4060. It can be understood that after the cooling working medium within the cooling housing absorbs the heat generated by the server module, the high-temperature cooling working medium flows to the cold source device through the cooling pipeline 4060. The cold source device cools the high-temperature cooling working medium to reduce the temperature of the cooling working medium, and the low-temperature cooling working medium flows back to the cooling housing through the cooling pipeline 4060 so as to implement circulation.

In the embodiment of the present application, there may be a plurality of computing devices 4030 which may be integrally deployed in an enclosed cavity of the accommodating space 4001a. For example, the plurality of computing devices 4030 may be arranged in two rows inside the accommodating space 4001a, each row including computing devices disposed at multiple layers stacked along the vertical direction, the plurality of computing devices 4030 at each layer arranged along the horizontal direction. The computing device 4030 may include at least one server module that consists of a plurality of server units.

Exemplarily, the cable mounting region 4010a and the pipeline mounting region 4010b are disposed apart in the width direction of the accommodating space 4001a. The cable mounting region 4010a and the pipeline mounting region 4010b extend in the length direction of the accommodating space 4001a, so as to mount the cable 4050 and the cooling pipeline 4060 respectively, which are disposed along the length direction of the accommodating space 4001a. It can be understood that there may be a plurality of cables 4050 disposed corresponding to a plurality of computing devices 4030 for connecting a power distribution cabinet 4070 and a corresponding computing device 4030, so as to transmit electrical power distributed by the power distribution cabinet 4070 to the corresponding computing device 4030. The cooling pipeline 4060 is connected between the computing device 4030 and the cold source device for allowing the cooling working medium to flow in a circulating manner between the cooling apparatus of the computing device 4030 and the cold source device. Further, the plurality of computing devices 4030 may be disposed side by side along the length direction of the accommodating space 4001a. Based on this, the piping mounting region 4010b is adapted to extend along the length direction of the accommodating space 4001a, so that the cooling pipeline 4060 mounted in the pipeline mounting region 4010b can transport the cooling working medium to the cooling apparatus of each computing device 4030.

The pipeline structure 1000 for the data center according to the embodiment of the present application can implement isolation of liquid and power supply to the data center in physical space, avoiding water and electricity contact caused by leakage in the cooling pipeline 4060, thereby decreasing the probability of safety hazards.

In an implementation, as shown in FIG. 50, two pipeline mounting regions 4010b are provided, which are located on two sides of the cable mounting region 4010a in the first direction.

Exemplarily, the two pipeline mounting regions 4010b are respectively disposed close to two side walls of the accommodating space 4001a disposed oppositely in the width direction, and a certain spacing is reserved for the two pipeline mounting regions 4010b in the width direction of the accommodating space 4001a, so that the cable mounting region 4010a can be arranged between the two pipeline mounting regions 4010b.

In one example, the plurality of computing devices 4030 are arranged in two rows in the width direction of the accommodating space 4001a, each row including a plurality of computing devices 4030 arranged side by side along the length direction of the accommodating space 4001a. The two pipeline mounting regions 4010b are disposed respectively corresponding to the two rows of computing devices 4030, and a cooling pipeline 4060 mounted on each pipeline mounting region 4010b is respectively connected with cooling apparatuses of a plurality of computing devices 4030 in a corresponding row.

In an implementation, the cable mounting region 4010a is disposed close to a top wall of the accommodating space 4001a and located above the pipeline mounting region 4010b.

Exemplarily, the cable mounting region 4010a and the pipeline mounting region 4010b are respectively disposed close to the top wall of the accommodating space 4001a, so as to form clearance for a plurality of computing devices 4030 close to a bottom wall of the accommodating space 4001a. The cable mounting region 4010a is disposed closer to the top wall of the accommodating space 4001a than the pipe mounting region 4010b, so that the cable 4050 mounted in the cable mounting region 4010a is positioned in the vertical direction above the cooling pipeline 4060 mounted in the pipeline mounting region 4010b.

Such arrangement can avoid the leaked cooling working medium from the cooling pipeline 4060 from splashing onto the cable 4050 when leakage occurs in the cooling pipeline 4060, thereby implementing physical isolation between the cooling pipeline 4060 and the cable 4050 in the vertical direction and further improving safety.

In an implementation, the inside of the accommodating space 4001a further has a power distribution cabinet mounting region 4010c for mounting the power distribution cabinet 4070. The power distribution cabinet mounting region 4010c is disposed apart from the pipeline mounting region 4010b and the cable mounting region 4010a in the second direction that is perpendicular to the first direction. The power distribution cabinet 4070 is used for distributing electrical power to the computing device 4030, the cold source device and other powered facilities of the data center.

Exemplarily, the inside of the accommodating space 4001a further has a computing device 4030 mounting region for mounting the computing device 4030. The power distribution cabinet mounting region 4010c and the computing device 4030 mounting region are disposed side by side in the length direction of the accommodating space 4001a. More specifically, the computing device 4030 mounting region is arranged on a side of the enclosed cavity in the length direction of the accommodating space 4001a, and the power distribution cabinet mounting region 4010c is arranged on the other side of the enclosed cavity in the length direction of the accommodating space 4001a.

More specifically, the power distribution cabinet mounting region 4010c and the cable mounting region 4010a are connected in the length direction of the accommodating space 4001a, so that the cable 4050 mounted in the cable mounting region 4010a can extend to the power distribution cabinet mounting region 4010c and be electrically connected with the power distribution cabinet 4070 mounted in the power distribution cabinet mounting region 4010c. The power distribution cabinet mounting region 4010c and the pipeline mounting region 4010b are spaced apart in the length of the accommodating space 4001a, so as to implement isolation between the power distribution cabinet 4070 and the cooling pipeline 4060 mounted in the pipeline mounting region 4010b in physical space.

In an implementation, the inside of the accommodating space 4001a is provided with a mounting bracket for mounting the cooling pipeline 4060, the computing device 4030, and the cable 4050. In other words, at least one of the pipeline mounting region 4010b, the computing device 4030 mounting region, and the cable mounting region 4010a may be defined by the mounting bracket.

Exemplarily, the mounting bracket may be fixedly connected with a wall body of the accommodating space 4001a by fasteners or welding, which is not specifically defined in the embodiments of the present application.

Optionally, the mounting bracket includes a first bracket for mounting the cooling pipeline 4060, and a second bracket for mounting the computing device 4030 and the cooling pipeline 4060. The first bracket and the second bracket are disposed apart in the first direction.

Exemplarily, the first bracket defines a first cooling pipeline mounting region 4010b, and the second bracket defines a computing device 4030 mounting region and a second cooling pipeline mounting region 4010b. The computing device 4030 mounting region and the second cooling pipeline mounting region 4010b are correspondingly disposed in the vertical direction, and the first cooling pipeline mounting region 4010b and the second cooling pipeline mounting region 4010b are disposed apart in the width direction of the accommodating space 4001a.

In a specific example, the first bracket is fixedly connected to the top wall of the accommodating space 4001a. The first bracket includes a first connecting beam and a first bearing beam. Two first connecting beams are provided and have upper ends fixedly connected to the top wall of the accommodating space 4001a. Two ends of the first bearing beam are respectively connected to lower ends of the two first connecting beams. The cooling pipeline 4060 is borne on an upper wall face of the first bearing beam.

The second bracket is fixedly connected to the bottom wall or side wall of the accommodating space 4001a. The second bracket includes a structural vertical beam fixedly connected to the bottom wall or side wall of the accommodating space 4001a, and a second bearing beam including a plurality of second bearing cross beams and a plurality of second bearing longitudinal beams, the second bearing cross beams extending along the length direction of the accommodating space 4001a and connected to a plurality of structural vertical beams, the plurality of second bearing longitudinal beams extending along the width direction of the accommodating space 4001a, and the plurality of second bearing longitudinal beams arranged side by side along the length direction of the accommodating space 4001a and connected to two oppositely disposed second bearing cross beams. The computing device 4030 is borne on the plurality of second bearing longitudinal beams.

Further, the first bracket and the second bracket are respectively disposed close to two sides of the accommodating space 4001a in the first direction.

Exemplarily, the first bracket is disposed close to a side of the enclosed cavity located in the width direction of the accommodating space 4001a, and the second bracket is disposed close to the other side of the enclosed cavity located in the width direction of the accommodating space 4001a. The cable mounting region 4010a is formed between the first bracket and the second bracket.

Further, the first brackets are in two rows disposed apart in the first direction, each row including a plurality of first brackets disposed side by side along the second direction.

Exemplarily, the first brackets are in two rows disposed apart in the width direction of the accommodating space 4001a, each row including a plurality of first brackets arranged side by side along the length direction of the accommodating space 4001a. The two rows of first brackets define corresponding pipeline mounting regions 4010b respectively. The cooling pipeline 4060 includes a liquid supply pipeline and a liquid return pipeline. A pipeline mounting region 4010b defined by one row of first brackets is used for mounting the liquid supply pipeline, and a pipeline mounting region 4010b defined by the other row of first brackets is used for mounting the liquid return pipeline. A plurality of first computing devices 4030 are integrally deployed on lower sides of two first brackets. The liquid supply pipeline is used for transporting the cooling working medium to a cooling apparatus of each first computing device 4030, and the liquid return pipeline is used for transporting the cooling working medium within a cooling apparatus of each first computing device 4030 to the cold source device.

Further, the second bracket includes a pipeline mounting layer and a device mounting layer, which are disposed apart in the vertical direction. The pipeline mounting layer is located above the device mounting layer for mounting the cooling pipeline 4060, and the device mounting layer is used for mounting the computing device 4030.

Exemplarily, the second bracket defines two computing device 4030 mounting regions, which are disposed apart in the vertical direction. Each computing device 4030 mounting region includes a pipeline mounting layer and a device mounting layer, which are disposed apart in the vertical direction, the pipeline mounting layer being located above the device mounting layer. The device mounting layer extends along the length direction of the accommodating space 4001a, so as to mount a plurality of computing devices 4030 arranged side by side along the length direction of the accommodating space 4001a. The pipeline mounting layer is used for mounting cooling pipelines 4060 that are respectively connected with cooling apparatuses of the plurality of computing devices 4030 on the corresponding device mounting layer.

Exemplarily, the powertrain may include a pump body, a liquid supply flow path and a liquid return flow path, the liquid supply flow path being connected with the liquid supply pipeline of the cooling pipeline 4060, the liquid return flow path being connected with the liquid return pipeline of the cooling pipeline 4060, and the pump body is used for providing power to the cooling working medium within the liquid supply flow path or the liquid return flow path. The cooling housing and the powertrain are integrated in the horizontal direction and adjoin each other in the length direction of the accommodating space 4001a. The cooling housing and the powertrain are jointly borne on the device mounting layer of the second bracket.

Optionally, the mounting bracket further includes a cable 4050 mounting bracket fixed to the top wall of the accommodating space 4001a and used for mounting the cable 4050. The cable 4050 mounting bracket is located between the first bracket and the second bracket in the first direction.

Exemplarily, the cable 4050 mounting bracket is suspended from the top wall of the enclosure. The cable mounting region 4010a is defined by the cable 4050 mounting bracket for mounting a plurality of cables connected between the power distribution cabinet 4070 and the computing devices 4030. The plurality of computing devices 4030 integrally deployed within the accommodating space 4001a may be designed side by side along the length direction of the accommodating space 4001a. Correspondingly, the cable 4050 mounting bracket extends in the length direction of the accommodating space 4001a, so as to mount the plurality of cables 4050 extending along the length direction of the accommodating space 4001a.

In a specific example, a plurality of first computing devices 4030 and a plurality of second computing devices 4030 are integrally deployed inside the accommodating space 4001a. The plurality of first computing devices 4030 are disposed close to a side of the enclosed cavity in the width direction of the accommodating space 4001a, and the plurality of second computing devices 4030 are disposed close to the other side of the enclosed cavity in the width direction of the accommodating space 4001a. The inside of the accommodating space 4001a has two device mounting regions for mounting the plurality of first computing devices 4030 and the plurality of second computing devices 4030 respectively.

Two power distribution cabinets 4070 are further integrally deployed inside the accommodating space 4001a, one of which is disposed side by side with the plurality of first computing devices 4030 in the length direction of the accommodating space 4001a for distributing electrical power to the plurality of first computing devices 4030, and the other of which is disposed side by side with the plurality of second computing devices 4030 in the length direction of the accommodating space 4001a for distributing electrical power to the plurality of second computing devices 4030. The inside of the accommodating space 4001a further has a power distribution cabinet mounting region 4010c for mounting the two power distribution cabinets 4070. The two device mounting regions are disposed side by side and apart in the width direction of the accommodating space 4001a, and the power distribution cabinet mounting region 4010c and the two device mounting regions are disposed side by side and apart in the length direction of the accommodating space 4001a.

The cable 4050 mounting bracket is located between the first bracket and the second bracket in the width direction of the accommodating space 4001a, and the defined cable mounting region 4010a is located between the two device mounting regions for mounting the plurality of cables 4050 between the two power distribution cabinets 4070 and the corresponding plurality of computing devices 4030.

Optionally, the first bracket and the second bracket are respectively disposed close to two sides of the accommodating space 4001a in the first direction.

Optionally, the first brackets are in two rows disposed apart in the first direction, each row including a plurality of first brackets disposed side by side along the second direction.

Optionally, the second bracket includes a pipeline mounting layer and a device mounting layer, which are disposed apart in the vertical direction. The pipeline mounting layer is located above the device mounting layer for mounting the cooling pipeline 4060, and the device mounting layer is used for mounting the computing device 4030.

In an implementation, the mounting bracket further includes a cable 4050 mounting bracket provided to the top wall of the accommodating space 4001a and used for mounting the cable 4050. The cable 4050 mounting bracket is located between the first bracket and the second bracket in the first direction.

Optionally, the mounting bracket further includes a bottom support frame body, which has a preset gap with the bottom wall of the accommodating space 4001a.

Exemplarily, the bottom support frame body is used for supporting the power distribution cabinets 4070, the computing devices 4030 and other devices deployed within the accommodating space 4001a. The preset gap between the bottom support frame body and the bottom wall of the accommodating space 4001a may be 10 cm to 20 cm. It can be understood that in a case where leakage occurs in the cooling pipeline 4060, the leaked cooling working medium may converge to a space between the bottom support frame body and the bottom wall of the accommodating space 4001a, which can prevent, to some extent, the leaked cooling working medium from flowing to the power distribution cabinets 4070 and other devices borne on the bottom support frame body, thereby further enhancing electrical safety.

Further, the bottom support frame body includes a plurality of first support beams disposed at intervals in the first direction and a plurality of second support beams disposed at intervals in the second direction, the second support beams being lapped over the plurality of first support beams.

Exemplarily, the plurality of first support beams are disposed side by side at intervals in the width direction of the accommodating space 4001a, and each first support beam extends along the length direction of the accommodating space 4001a. The plurality of second support beams are disposed side by side at intervals in the length direction of the accommodating space 4001a, and each second support beam extends along the width direction of the accommodating space 4001a. Each second support beam is lapped over the plurality of first support beams, and the second support beam and the first support beams may be fixedly connected by fasteners, or may be fixedly connected by welding.

In an implementation, at least one of two side walls of the accommodating space 4001a disposed oppositely in the first direction is provided with an air inlet, and at least one of the two side walls of the accommodating space 4001a disposed oppositely in the first direction is provided with an air outlet that is disposed apart from the air inlet in the second direction.

Exemplarily, two side walls of the accommodating space 4001a disposed oppositely in the width direction are respectively provided with an air inlet for guiding air into the inside of the accommodating space 4001a. The two side walls of the accommodating space 4001a disposed oppositely in the width direction are respectively provided with an air outlet, and two air outlets may be provided on each side wall, which are respectively located on two sides of the air inlet in the length direction of the accommodating space 4001a. It can be understood that the air outlets are used for guiding the air inside the accommodating space 4001a to the outside.

With the above implementation, the airflow inside the accommodating space 4001a can be improved, thereby further enhancing the cooling effect inside the accommodating space 4001a.

Optionally, the air inlet is provided with an intake fan; and/or, the air outlet is provided with an exhaust fan.

Exemplarily, the air inlet and the air outlet are provided with an intake fan and an exhaust fan respectively. A flow guide direction of the intake fan of the air inlet is disposed towards the inside of the accommodating space 4001a, and a flow guide direction of the exhaust fan of the air outlet is disposed towards the outside of the accommodating space 4001a, so as to improve the air exchange efficiency inside the accommodating space 4001a.

Optionally, the air inlet is provided with an air intake grille; and/or, the air outlet is provided with an air exhaust grille.

Exemplarily, the air inlet and the air outlet are provided with an air intake grille and an air exhaust grille respectively. The air intake grille and the air exhaust grille respectively include: a plurality of flow guide plates arranged at intervals along the horizontal direction, each extending along the vertical direction; and two mounting plates, two ends of each flow guide plate being rotatably connected to the two mounting plates. It can be understood that the flow guide plates are rotatable to open and closed positions, and when the plurality of flow guide plates are rotated to the open position, a flow guide gap is formed between two adjacent flow guide plates, so that air can flow through the air inlet or the air outlet; and when the plurality of flow guide plates are rotated to the closed position, two adjacent flow guide plates are spliced with each other, so that air cannot flow through the air inlet or the air outlet.

In an implementation, either of the two side walls of the accommodating space 4001a disposed oppositely in the first direction is provided with an electrical power access window; and/or, either of the two side walls of the accommodating space 4001a disposed oppositely in the first direction is provided with a pipeline access window.

Exemplarily, one of the two side walls of the accommodating space 4001a disposed oppositely in the width direction thereof is provided with an electrical power access window. The electrical power access window is used for mounting a cable connection device which is used for connecting to external electrical power input and transport electrical power to the power distribution cabinet 4070 inside the accommodating space 4001a.

In an implementation, the inner wall of the accommodating space 4001a is provided with a fireproof board, which employs a thermal insulation material.

Exemplarily, the fireproof board may specifically be a rock wool board. It can be understood that the rock wool board, also known as rock wool thermal insulation decorative board, is an inorganic fiber board made from basalt as the main raw material and processed by high-temperature melting, which has the characteristics of being lightweight, having a low thermal conductivity, absorbing heat, and being non-combustible.

With the above implementation, the thermal insulation performance of the accommodating space 4001a can be improved, which is conducive to keeping a constant temperature in the internal space of the accommodating space 4001a, and also provides a certain degree of fire resistance.

In an implementation, the top of the accommodating space 4001a is provided with a lightning protection apparatus.

Exemplarily, the lightning protection apparatus includes a lightning arrester, a down conductor, and a grounding apparatus. The lightning arrester employs a metal material, which, for example, may be a metal rod for receiving lightning strikes. The down conductor is a metal conductor connected between the lightning arrester and the grounding apparatus.

With the above implementation, various electrical devices inside the accommodating space 4001a can be protected against lightning strikes, further enhancing the safety and reliability of the data center.

As another aspect of the embodiments of the present application, an embodiment of the present application further provides a data center including the pipeline structure of any one of the above implementations of the present application.

In an implementation, the data center further includes a computing device enclosure, in which the pipeline structure is deployed.

In the description of this specification, it should be understood that the terms “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential” and the like indicate orientations or positional relationships based on the orientations or positional relationships shown in the drawings, and are only for the convenience of describing the present application and simplifying the description, and do not indicate or imply that a device or element as mentioned must have a particular orientation, or be constructed and operated in a particular orientation, and therefore should not be understood as a limitation on the present application.

In addition, the terms “first” and “second” are used for descriptive purposes only and should not be understood as indicating or implying relative importance or implicitly stating the number of technical features as indicated. Thus, a feature defined by “first” or “second” may explicitly or implicitly include one or more of the features. In the description of this present application, the term “plurality” means two or more than two, unless otherwise clearly specifically defined.

In the present application, unless otherwise clearly specified and defined, the terms “mount”, “connect with”, “connect”, “fix” and the like should be understood in a broad sense. For example, it is possible to be a fixed connection, a detachable connection, or an integration; it is possible to be a mechanical connection, an electrical connection, or a communication connection; it is possible to be a direct connection, or an indirect connection through an intermediate medium, or an internal communication between two elements or an interaction relationship between two elements. For those skilled in the art, the specific meanings of the above terms in the present application can be understood as a specific case may be.

In the present application, unless otherwise clearly specified and defined, a first feature being “on” or “under” a second feature may include a case that the first and second features are in direct contact, or a case that the first and second features are not in direct contact but are in contact through an additional feature between them. Moreover, a first feature being “on”, “above” and “over” a second feature includes a case that the first feature is directly above and obliquely above the second feature, or simply represents that the first feature is higher in level than the second feature. A first feature being “under”, “below” and “beneath” a second feature includes a case that the first feature is directly below and obliquely below the second feature, or simply represents that the first feature is lower in level than the second feature.

The disclosure above provides many different embodiments or instances to achieve the different structures of the present application. In order to simplify the disclosure of the present application, the parts and settings of particular instances are described above. Certainly, they are only examples, and their purpose is not to limit the present application. In addition, in the present application, reference numerals and/or reference letters can be repeated in different instances, and such repetition is for the purpose of simplification and clarity, which itself does not indicate the relationships between the various implementations and/or settings discussed.

Described above are only specific implementations of the present application, but the scope of protection of the present application is not limited thereto. Any technicians familiar with this technical field can readily envisage various changes or substitutions within the technical scope disclosed in the present application, all of which should be included in the scope of protection of the present application. Therefore, the scope of protection of the present application should be based on the scope of protection of the attached claims.

What is claimed is:

1. A liquid-cooled data center, comprising:
a liquid-cooled device; and
a cold source device connected to the liquid-cooled device for cooling the liquid-cooled device.

2. The liquid-cooled data center according to claim 1, further comprising:
a connecting pipeline that connects the liquid-cooled device and the cold source device.

3. The liquid-cooled data center according to claim 1, further comprising:
an enclosure for deploying the liquid-cooled device and/or the cold source device; and
a connecting pipeline that connects the liquid-cooled device and the cold source device deployed within the enclosure.

4. The liquid-cooled data center according to claim 1, further comprising:
a computing device deployed in the liquid-cooled device;
a connecting pipeline connected between the liquid-cooled device and the cold source device to form a cooling circulation pipeline; and
an enclosure for deploying the liquid-cooled device and/or the cold source device, so as to integrate the liquid-cooled device and/or the cold source device into the enclosure.

5. The liquid-cooled data center according to claim 1, wherein the liquid-cooled device comprises at least one cooling apparatus for cooling a server module as loaded, and the cold source device is used for exchanging heat with a cooling working medium in the at least one cooling apparatus.

6. The liquid-cooled data center according to claim 5, wherein the cold source device comprises a first cold source device and a second cold source device, the first cold source device and/or the second cold source device being connected to the at least one cooling apparatus;
wherein the liquid-cooled device comprises a first cooling apparatus and a second cooling apparatus;
the first cold source device is connected to the first cooling apparatus, and the second cold source device is connected to the second cooling apparatus; or, the first cold source device and the second cold source device are connected to the first cooling apparatus, and the first cold source device or the second cold source device is connected to the second cooling apparatus.

7. The liquid-cooled data center according to claim 5, wherein the liquid-cooled device comprises a plurality of cooling apparatuses, and the cold source device comprises a plurality of cold source devices; at least one of the plurality of cooling apparatuses is connected to at least two of the plurality of cold source devices.

8. The liquid-cooled data center according to claim 6, wherein a first circulation flow path for circulation flow of the cooling working medium is provided between the first cold source device and the first cooling apparatus, a second circulation flow path for circulation flow of the cooling working medium is provided between the second cold source device and the second cooling apparatus, and a third circulation flow path for circulation flow of the cooling working medium is provided among the first cold source device, the second cold source device and a third cooling apparatus;
wherein the cold source device comprises a heat exchange assembly; and the first cold source device and the second cold source device both comprise a first heat exchange assembly and a second heat exchange assembly, the first heat exchange assembly of the first cold source device is used for cooling the cooling working medium in the first cooling apparatus, the first heat exchange assembly of the second cold source device is used for cooling the cooling working medium in the second cooling apparatus, and the second heat exchange assemblies of the first cold source device and the second cold source device are used for jointly cooling the cooling working medium in the third cooling apparatus;
wherein the first cold source device further comprises a first heat exchanger for performing heat exchange between a liquid medium output from the first heat exchange assembly of the first cold source device and the cooling working medium in the first circulation flow path; the second cold source device further comprises a second heat exchanger for performing heat exchange between a liquid medium output from the first heat exchange assembly of the second cold source device and the cooling working medium in the second circulation flow path; and the second heat exchange assemblies of the first cold source device and the second cold source device are respectively in communication with the third circulation flow path.

9. The liquid-cooled data center according to claim 8, wherein the first heat exchange assembly and second heat exchange assembly of the first cold source device cool the cooling working medium through the liquid medium, and the first heat exchange assembly and second heat exchange assembly of the second cold source device cool the cooling working medium through a gaseous medium.

10. The liquid-cooled data center according to claim 1, wherein a heat exchange assembly of the cold source device comprises:
a pipeline module comprising an input pipeline for inputting a cooling working medium to be cooled, an output pipeline for outputting the cooled cooling working medium, and a connecting pipeline connected between the input pipeline and the output pipeline;
wherein the heat exchange assembly of the cold source device comprises:
a first heat exchange module, input and output ends of the first heat exchange module being in communication with the connecting pipeline respectively for cooling the cooling working medium through a gaseous medium;
wherein the first heat exchange module comprises a heat exchange coil for flow of the cooling working medium, so that heat exchange takes place between the cooling working medium and the gaseous medium.

11. The liquid-cooled data center according to claim 10, wherein the heat exchange assembly of the cold source device comprises:
a second heat exchange module, input and output ends of the second heat exchange module being in communication with the connecting pipeline respectively for cooling the cooling working medium through a liquid medium;
wherein the connecting pipeline is provided with a valve assembly for causing the cooling working medium to flow through at least one of the first heat exchange module and the second heat exchange module;
wherein the second heat exchange module comprises a condenser, an expansion valve, a liquid storage tank, a heat exchange unit, a compressor, and a circulation pipeline, the circulation pipeline is used for circulation flow of the liquid medium among the condenser, the expansion valve, the liquid storage tank, the heat exchange unit, and the compressor, and heat exchange between the liquid medium and the cooling working medium is taken place at the heat exchange unit.

12. The liquid-cooled data center according to claim 11, wherein the connecting pipeline comprises an intermediate pipeline, a first liquid inlet pipeline, a first liquid outlet pipeline, a second liquid inlet pipeline, and a second liquid outlet pipeline; wherein input and output ends of the intermediate pipeline are respectively connected to the input pipelines and the output pipelines, the first liquid inlet pipeline is connected between the input end of the first heat exchange module and the intermediate pipeline, the first liquid outlet pipeline is connected between the output end of the first heat exchange module and the intermediate pipeline, the second liquid inlet pipeline is connected between the input end of the second heat exchange module and the intermediate pipeline, and the second liquid outlet pipeline is connected between the output end of the second heat exchange module and the intermediate pipeline.

13. The liquid-cooled data center according to claim 12, wherein the valve assembly comprises:
a first valve assembly comprising a first liquid inlet valve provided in the first liquid inlet pipeline, a first liquid outlet valve provided in the first liquid outlet pipeline, and a first on-off valve provided in the intermediate pipeline; and
a second valve assembly comprising a second liquid inlet valve provided in the second liquid inlet pipeline, a second liquid outlet valve provided in the second liquid outlet pipeline, and a second on-off valve provided in the intermediate pipeline.

14. The liquid-cooled data center according to claim 11, further comprising:
a gaseous medium cooling module for cooling the gaseous medium and guiding the cooled gaseous medium to the first heat exchange module;
wherein the gaseous medium cooling module comprises a wet curtain having flow guide holes that make inside and outside of the cold source device in communication, a wet curtain spray pipe for spraying cooling water to the wet curtain, and a wet curtain water tray provided below the wet curtain to receive the cooling water.

15. The liquid-cooled data center according to claim 14, further comprising:
a control apparatus for controlling open and closed states of the valve assembly according to an outdoor ambient temperature to allow the cooling working medium to flow through at least one of the first heat exchange module and the second heat exchange module, and controlling a working state of the gaseous medium cooling module;
wherein the control apparatus is configured to: control the valve assembly to allow the cooling working medium to flow through the first heat exchange module if the outdoor ambient temperature meets a first preset temperature range; control the valve assembly to allow the cooling working medium to flow through the first heat exchange module and control the gaseous medium cooling module to start if the outdoor ambient temperature meets a second preset temperature range; and control the valve assembly to allow the cooling working medium to flow sequentially through the first heat exchange module and the second heat exchange module and control the gaseous medium cooling module to start if the outdoor ambient temperature meets a third preset temperature range.

16. The liquid-cooled data center according to claim 1, further comprising:
an enclosure, inside which at least one of the liquid-cooled devices is integrally deployed; or inside which at least one of the liquid-cooled devices and at least one of the cold source devices are integrally deployed;
wherein the enclosure comprises a first container body and a second container body, at least one of the liquid-cooled devices is integrally deployed inside the first container body, and at least one of the cold source devices is integrally deployed inside the second container body; and
wherein the first container body and the second container body are detachably connected.

17. The liquid-cooled data center according to claim 16, wherein the first container body and the second container body are detachably connected in a horizontal direction;
wherein an interlocking structure is provided between adjoining top walls and/or side walls of the first container body and the second container body.

18. The liquid-cooled data center according to claim 16, wherein the first container body and the second container body are detachably connected in a vertical direction;
wherein an upper side of the first container body is provided with a first mounting fit member, and a lower side of the second container body is provided with a second mounting fit member, the first mounting fit member and the second mounting fit member are connected by interlocking;
the first mounting fit member and the second mounting fit member are fixedly connected by fasteners.

19. The liquid-cooled data center according to claim 16, wherein a ladder is provided between bottom and top ends of the second container body.

20. The liquid-cooled data center according to claim 16, wherein the first container body defines an enclosed cavity, and the second container body employs a framework structure to define an open cavity; and
wherein the first container body is provided with a pipeline window for allowing a cooling pipeline to pass through to connect the cold source device in the second container body with the liquid-cooled device in the first container body.
